(19) United States
(12) Patent Application Publication
(10) Pub. No.: US 2023/0345756 A1
(43) Pub. Date: Oct. 26, 2023

(54) ORGANIC ELECTROLUMINESCENT DEVICE AND DISPLAY APPARATUS

(71) Applicants: KunShan Go-Visionox Opto-Electronics Co., Ltd, Kunshan (CN); TSINGHUA UNIVERSITY, Beijing (CN)

(72) Inventors: Minghan CAI, Kunshan (CN); Lian DUAN, Kunshan (CN); Guomeng LI, Kunshan (CN); Feixia LI, Kunshan (CN); Jun LIU, Kunshan (CN); Mengzhen LI, Kunshan (CN); Hongyu WANG, Kunshan (CN)

(73) Assignees: KunShan Go-Visionox Opto-Electronics Co., Ltd, Kunshan (CN); TSINGHUA UNIVERSITY, Beijing (CN)

(21) Appl. No.: 18/342,043

(22) Filed: Jun. 27, 2023

Related U.S. Application Data
(63) Continuation of application No. PCT/CN2022/084857, filed on Apr. 1, 2022.

(30) Foreign Application Priority Data
Jun. 30, 2021 (CN) 2021107407216

(51) Int. Cl. H10K 50/18

(52) U.S. Cl. CPC H10K 50/181; H10K 2101/20

(57) ABSTRACT

An organic electroluminescent device and a display apparatus, where the organic electroluminescent device includes an anode functional layer, a first electron blocking layer, a second electron blocking layer, a light-emitting layer and a cathode functional layer; the first electron blocking layer includes a red light electron blocking layer and a green light electron blocking layer, which are disposed side by side, and the second electron blocking layer is a blue light electron blocking layer; a HOMO energy level of a red light electron blocking material in the red light electron blocking layer and a HOMO energy level of a green light electron blocking material in the green light electron blocking layer are both lower than a HOMO energy level of a blue light electron blocking material in the blue light electron blocking layer.

### CROSS-REFERENCE TO RELATED APPLICATIONS

The present application is a continuation of International Application No. PCT/CN2022/084857, filed on Apr. 1, 2022, which claims priority to Chinese Patent Application No. 202110740721.6, filed with the China National Intellectual Property Administration on Jun. 30, 2021, and entitled “ORGANIC ELECTROLUMINESCENT DEVICE AND DISPLAY APPARATUS”. The entire contents of the aforementioned applications are hereby incorporated in the present application by reference.

### TECHNICAL FIELD

The present application relates to an organic electroluminescent device and a display apparatus, belonging to the technical field of organic electroluminescence.

### BACKGROUND

An organic electroluminescent device is a device that is driven by current to achieve the purpose of light emission. Specifically, the organic electroluminescent device includes a cathode, an anode, a light-emitting layer located between the cathode and the anode and other functional layer. When a voltage is applied, electrons from the cathode and holes from the anode will each migrate to the light-emitting layer and are combined to generate excitons, which then emit light with different wavelengths according to the characteristic of the light-emitting layer.

In recent years, thermally activated delayed fluorescence (Thermally Activated Delayed Fluorescence, TADF) materials have been widely used in light-emitting materials of the organic electroluminescent device. TADF materials can utilize both singlet excitons with a generation probability of 25% and triplet excitons with a generation probability of 75% to obtain high luminous efficiency. Specifically, due to small energy level difference (AEST) between singlet (S₁) and triplet (T₁) of TADF molecules, triplet excitons may return to singlet through reverse intersystem crossing (Reverse Intersystem Crossing, RISC), forming singlet excitons and then emitting light, thereby improving the radioluminescence efficiency of excitons.

However, in the existing thermally activated delayed fluorescence devices, the driving voltage of the organic electroluminescent device is usually high due to the deep highest occupied molecular orbital (HOMO) energy level of TADF materials.

### SUMMARY

The present application provides an organic electroluminescent device, whose driving voltage can be effectively reduced by improving an internal structure thereof, especially a structure of an electron blocking layer, so that the service life of the organic electroluminescent device can be prolonged to a certain extent, so as to reduce the power consumption of the organic electroluminescent device.

The present application provides an organic electroluminescent device, including an anode functional layer, a first electron blocking layer, a second electron blocking layer, a light-emitting layer and a cathode functional layer, where the anode functional layer includes a first region and a second region, which are disposed adjacent to each other, the first electron blocking layer is disposed in the first region of the anode functional layer, the second electron blocking layer is disposed in the second region of the anode functional layer and on a side of the first electron blocking layer away from the anode functional layer, the light-emitting layer is disposed on a side of the second electron blocking layer away from the anode functional layer, and the cathode functional layer is disposed on a side of the light-emitting layer away from the anode functional layer;
the anode functional layer at least includes an anode layer, and the cathode functional layer at least includes a cathode layer;
the first electron blocking layer includes a red light electron blocking layer and a green light electron blocking layer, which are disposed side by side, and the second electron blocking layer is a blue light electron blocking layer;
the light-emitting layer includes a red light-emitting unit, a green light-emitting unit and a blue light-emitting unit, which are disposed side by side, and the red light-emitting unit and/or the green light-emitting unit include a host material, a TADF sensitizing agent and a narrow-spectrum boron-containing dye;
the red light electron blocking layer and the red light-emitting unit are provided correspondingly in a laminated manner, and the green light electron blocking layer and the green light-emitting unit are provided correspondingly in a laminated manner;
HOMO_{R} of a red light electron blocking material in the red light electron blocking layer, HOMO_{G} of a green light electron blocking material in the green light electron blocking layer and HOMO_{B} of a blue light electron blocking material in the blue light electron blocking layer meet the following requirements:
HOMO_{B}<HOMO_{R}, HOMO_{B}<HOMO_{G}, and HOMO_{G}≤HOMO_{R}
HOMO_{R} is a highest occupied molecular orbital energy level of the red light electron blocking material in the red light electron blocking layer, HOMO_{G} is a highest occupied molecular orbital energy level of the green light electron blocking material in the green light electron blocking layer, and HOMO_{B} is a highest occupied molecular orbital energy level of the blue light electron blocking material in the blue light electron blocking layer.

Optionally, HOMO_{R}, HOMO_{G} and HOMO_{B} satisfy the following requirements:
0<HOMO_{R}−HOMO_{B}≤0.4 eV, and/or, 0<HOMO_{G}−HOMO_{B}≤0.4 eV.

The present application also provides a display apparatus which includes any one of the organic electroluminescent devices described above.

In the organic electroluminescent device of the present application, structures of the electron blocking layers between the anode and the light-emitting layer are defined, and the red light electron blocking layer, the green light electron blocking layer and the blue light electron blocking layer are disposed in layers, so that the blue light electron blocking layer is closer to the light-emitting layer than the red light electron blocking layer and the green light electron blocking layer, and an energy level step is introduced in a path of the holes transporting from the anode to the light-emitting layer, thereby ensuring that more holes are injected into the light-emitting layer, effectively reducing the problem of too high driving voltage of the organic electroluminescent device due to including a TADF material, and benefitting to prolonging the service life of the organic electroluminescent device while reducing the energy consumption of the organic electroluminescent device.

### BRIEF DESCRIPTION OF DRAWINGS

FIG. 1 is a structural schematic view of an organic electroluminescent device of the present application.

### DETAILED DESCRIPTION OF EMBODIMENTS

In order to make the object, technical solutions and advantages of the present application more clear, the technical solutions in the embodiments of the present application will be described clearly and completely in the following in connection with the drawings of the present application. Obviously, the described embodiments are part of the embodiments of the present application, but not all embodiments. Based on the embodiments in the present application, all other embodiments obtained by those ordinary skilled in the art without creative work belong to the protection scope of the present application.

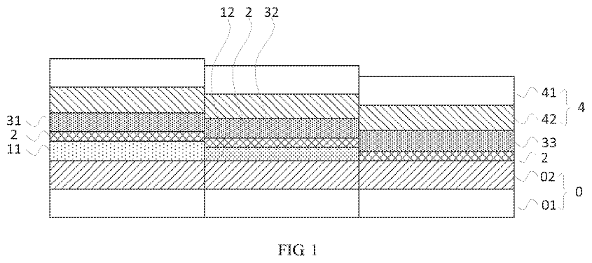

A first aspect of the present application provides an organic electroluminescent device. As shown in FIG. 1, the organic electroluminescent device includes an anode functional layer 0, a first electron blocking layer, a second electron blocking layer 2, a light-emitting layer and a cathode functional layer 4, which are sequentially deposited on a substrate, where the anode functional layer 0 at least includes an anode layer 01 and the cathode functional layer 4 at least includes a cathode layer 41.

Specifically, the substrate, the anode layer 01 and the cathode layer 41 may be made of materials commonly used in the art. For example, the substrate may be made of glass or polymer material with excellent mechanical strength, thermal stability, water resistance and transparency; a material of the anode layer 01 may be transparent conductive oxide materials such as indium tin oxide (ITO), indium zinc oxide (IZO), tin dioxide (SnO₂), zinc oxide (ZnO) and any combination thereof; and a material of the cathode layer 41 may be a metal or an alloy, such as magnesium (Mg), silver (Ag), aluminum (Al), aluminum-lithium (Al—Li), calcium (Ca), magnesium-indium (Mg—In), magnesium-silver (Mg—Ag) and any combination thereof.

Most of TADF materials have some defects when used as a sensitizing agent. For example, due to the deep HOMO energy level of the TADF materials, it is difficult for the holes from the anode to complete the injection into the light-emitting layer, which leads to the high driving voltage of the organic electroluminescent device, thereby shortening the service life of the organic electroluminescent device.

In view of this, the present application reduces the driving voltage of the organic electroluminescent device by defining the functional layer between the anode functional layer 0 and the cathode functional layer 4.

In the following, the first electron blocking layer, the second electron blocking layer 2 and the light-emitting layer, which are located between the anode functional layer 0 and the cathode functional layer 4, of the present application are described in detail.

The first electron blocking layer includes a red light electron blocking layer 11 and a green light electron blocking layer 12, which are disposed side by side, and the first electron blocking layer is disposed on a surface of the anode functional layer 0 away from the substrate, and the surface of the anode functional layer 0 includes a first region and a second region, which are disposed adjacent to each other, where the red light electron blocking layer 11 and the green light electron blocking layer 12 may be disposed in the same layer, and are disposed in the first region of the anode functional layer 0, and the second electron blocking layer 2 is disposed in the second region of the anode functional layer 0 and on a side of the first electron blocking layer away from the anode functional layer 0. The second electron blocking layer 2 of the present application is a blue light electron blocking layer. In sequence, the light-emitting layer is disposed on a surface of the second electron blocking layer 2 away from the anode functional layer 0, and the cathode functional layer 4 is disposed on a surface of the light-emitting layer away from the anode functional layer 0. In the present application, the arrangement area of each functional layer is not specifically limited, as a preferred embodiment, an orthographic projection of a (N+1)th functional layer on a plane where the anode functional layer 0 is located covers an orthographic projection of a Nth functional layer on the plane where the anode functional layer 0 is located, where the Nth functional layer is closer to the anode functional layer 0 than the (N+1)th functional layer. For example, an orthographic projection of the light-emitting layer on the plane where the anode functional layer 0 is located covers an orthographic projection of the second electron blocking layer 2 on the plane where the anode functional layer 0 is located. The “cover” here means that areas of the two orthographic projections are equal and the edges of the two orthographic projections coincide exactly, or the orthographic projection of the Nth layer is located inside the orthographic projection of the (N+1)th layer. Where HOMO_{R} of a red light electron blocking material in the red light electron blocking layer 11 is greater than HOMO_{B} of a blue light electron blocking material in the blue light electron blocking layer, HOMO_{G} of a green light electron blocking material in the green light electron blocking layer 12 is greater than HOMO_{B} of the blue light electron blocking material in the blue light electron blocking layer, and HOMO_{R} of the red light electron blocking material in the red light electron blocking layer 11 is greater than or equal to that of HOMO_{G} of the green light electron blocking material in the green light electron blocking layer 12. That is, HOMO_{B} is deeper than HOMO_{R} and HOMO_{G}, HOMO_{G} is equal to HOMO_{R} or deeper than HOMO_{R}. HOMO_{R} is a highest occupied molecular orbital energy level of the red light electron blocking material in the red light electron blocking layer, HOMO_{G} is a highest occupied molecular orbital energy level of the green light electron blocking material in the green light electron blocking layer, and HOMO_{B} is a highest occupied molecular orbital energy level of the blue light electron blocking material in the blue light electron blocking layer.

In addition, as shown in FIG. 1, the light-emitting layer of the present application includes a red light-emitting unit 31, a green light-emitting unit 32 and a blue light-emitting unit 33, which are disposed side by side, and adjacent two of the red light-emitting unit 31, the green light-emitting unit 32 and the blue light-emitting unit 33 are staggered by a certain distance in a laminated direction. Where in the laminated direction, the red light-emitting unit 31 corresponds to the red light electron blocking layer 11, and the green light-emitting unit 32 corresponds to the green light electron blocking layer 12. It can be understood that the correspondence here means that an orthogonal projection of the red light-emitting unit 31 on a plane where the red light electron blocking layer 11 is located covers the red light electron blocking layer 11, and an orthogonal projection of the green light-emitting unit 32 on a plane where the green light electron blocking layer 12 is located covers the green light electron blocking layer 12.

Of course, the arrangement manner of the red light-emitting unit 31, the green light-emitting unit 32 and the blue light-emitting unit 33 in the present application is not limited to that as shown in FIG. 1, and the red light-emitting unit 31, the green light-emitting unit 32 and the blue light-emitting unit 33 may be disposed side by side in any order. Correspondingly, the red light electron blocking layer 11 and the green light electron blocking layer 12 are adjusted in order according to the order of the red light-emitting unit 31 and the green light-emitting unit 32.

Specifically, at least one of the red light-emitting unit 31 and the green light-emitting unit 32 includes a host material, a TADF sensitizing agent and a narrow-spectrum boron-containing dye.

According to that solution provided by the present application, the driving voltage of the organic electroluminescent device with the above structure is significantly lower than that of the organic electroluminescent device containing the TADF sensitizing agent at the present stage. The specific reason for this lies in that the organic electroluminescent device of the present application includes the anode functional layer 0, the first electron blocking layer, the second electron blocking layer 2 (i.e., the blue light electron blocking layer), the light-emitting layer and the cathode functional layer 4 in the laminated direction (i.e., a direction from the anode functional layer 0 to the cathode functional layer 4), that is, there is an energy level step for transferring holes in the hole transmission path from the first electron blocking layer to the light-emitting layer, the energy level step ensures that the holes can smoothly enter the light-emitting layer from the first electron blocking layer, thereby effectively reducing the driving voltage of the organic electroluminescent device.

Specifically, for the red light-emitting unit 31, when the anode functional layer 0 outputs holes, the holes enter the red light electron blocking layer 11 in the first electron blocking layer, and since the blue light electron blocking layer is added between the red light electron blocking layer 11 and the red light-emitting unit 31, and HOMO_{B} is smaller than HOMO_{R}, the holes in the red light electron blocking layer 11 may be smoothly transferred to the blue light electron blocking layer. Compared with the red light electron blocking layer 11 with a relative shallow HOMO_{R}, the blue light electron blocking layer with a deeper HOMO energy level is more matched with the TADF sensitizing agent with a deep HOMO level in the red light-emitting unit 31, so the holes may further smoothly enter the red light-emitting unit 31 with the help of the blue light electron blocking layer, and then recombine with the electrons from the cathode functional layer 4.

Similarly, for the green light-emitting unit 32, after the anode functional layer 0 outputs the holes, the holes entering the green light electron blocking layer 12 may also be based on the same reason as above to sequentially pass through the green light electron blocking layer 12 and the blue light electron blocking layer and then enter the green light-emitting unit 32 to complete recombination with electrons.

For the blue light-emitting unit 33, when the anode functional layer 0 outputs the holes, the holes outputted by the anode functional layer 0 may pass through the blue light electron blocking layer and then enter the blue light-emitting unit 33 to recombine with the electrons.

According to the organic electroluminescent device of the present application, by limiting the arrangement of the electron blocking layers, the holes may be efficiently transported to the light-emitting layer without adding other material, which not only shortens the manufacturing process and significantly reduces the driving voltage of the organic electroluminescent device containing the TADF sensitizing agent, thereby being beneficial to reduce energy consumption and prolong the service life of the organic electroluminescent device. It should be emphasized here that reducing the driving voltage of the organic electroluminescent device as referred to in the present application means reducing the driving voltages of the red light-emitting unit 31 and the green light-emitting unit 32 in the organic electroluminescent device, respectively.

It is worth mentioning that, compared with the prior art in which a plurality of red light electron blocking layers (a plurality of green light electron blocking layers) are disposed between the anode functional layer 0 and the red light-emitting unit 31 (the green light-emitting unit 32), in the present application, the light-emitting layer may be evaporated only by evaporating one blue light electron blocking layer, which shortens the waiting period between the evaporation of the second electron blocking layer 2 and the evaporation of the light-emitting layer, reduces the interference of the external environment on the evaporation process, and improves the purity of the organic electroluminescent device. Therefore, this solution is also beneficial to improve the service life of the organic electroluminescence device, especially the service life of the blue light-emitting unit 33.

As mentioned above, the composition of at least one of the red light-emitting unit 31 and the green light-emitting unit 32 in the present application includes a host material, a TADF sensitizing agent and a narrow-spectrum boron-containing dye; while for the composition of the blue light-emitting unit 33, the composition of the blue light-emitting unit 33 in the present application includes a triplet-triplet annihilation (TTA) material and a dye.

The inventors found that when 0<HOMO_{R}−HOMO_{B}≤0.4 eV, and/or, 0<HOMO_{G}−HOMO_{B}−0.4 eV, it is helpful to realize more effective injection of the holes into the red light-emitting unit and/or the green light-emitting unit.

Further, after the holes enter the blue light electron blocking layer through the red light electron blocking layer 11, in order to play the role of the energy level step of the blue light electron blocking layer more effectively, the injection efficiency of the holes into the red light-emitting unit 31 through the blue light electron blocking layer may be further improved by matching the blue light electron blocking material of the blue light electron blocking layer with the host material of the red light-emitting unit 31. Specifically, HOMO_{B}−HOMO_{RH}≤0.4 eV, where HOMO_{RH} is HOMO energy level of the host material in the red light-emitting unit 31.

Similarly, HOMO_{GH}−HOMO_{B}≤0.4 eV is also helpful to further improve the injection efficiency of the holes into the green light-emitting unit 32 through the blue light electron blocking layer, where HOMO_{GH} is HOMO energy level of the host material in the green light-emitting unit 32.

In an embodiment, in order to avoid the increase of the driving voltages of the red light-emitting unit 31 and the green light-emitting unit 32 due to an excessive thickness of the blue light electron blocking layer, it is necessary to control the thickness of the blue light electron blocking layer to be less than or equal to 20 nm.

Further, in order to adjust the optical path of red light and/or green light, a thickness of the red light electron blocking layer 11 is greater than or equal to 20 nm, and/or a thickness of the green light electron blocking layer 12 is greater than or equal to 20 nm.

In the organic electroluminescent device of the present application, the thicknesses of the red light-emitting unit 31, the green light-emitting unit 32 and the blue light-emitting unit 33 constituting the light-emitting layer are not all the same. Where since an electron-hole recombination region of the blue light device is close to an interface between the second electron blocking layer 2 and the light-emitting layer, the thickness of the blue light-emitting unit 33 is less than or equal to 30 nm; and since the electron-hole recombination area in the red light and/or green light device is relative wide, the thickness of the red light-emitting unit 31 and/or the green light-emitting unit 32 is less than or equal to 50 nm.

In an embodiment, in the red light-emitting unit, the green light-emitting unit and the blue light-emitting unit, thicknesses of any two adjacent light-emitting units are different, so that adjacent two among the red light-emitting unit 31, the green light-emitting unit 32 and the blue light-emitting unit 33 are staggered by a certain distance in the laminated direction.

In the present application, the red light electron blocking material in the red light electron blocking layer 11, the green light electron blocking material in the green light electron blocking layer 12 and the blue light electron blocking material in the blue light electron blocking layer are not particularly limited, as long as the materials meets the above energy level requirements, for example, they may be selected from, but not limited to, phthalocyanine derivatives such as CuPc, conductive polymers or conductive dopant-containing polymers such as polyphenylene ethylene, polyaniline/dodecylbenzenesulfonic acid (Pani/DB SA), poly(3,4-ethylenedioxythiophene)/poly(4-styrene sulfonate) (PEDOT/PSS), polyaniline/camphorsulfonic acid (Pani/CSA), Polyaniline/poly (4-styrene sulfonate) (Pani/PSS) and aromatic amine derivative.

The aromatic amine derivative is selected from the following compounds represented by HT-1 to HT-37.

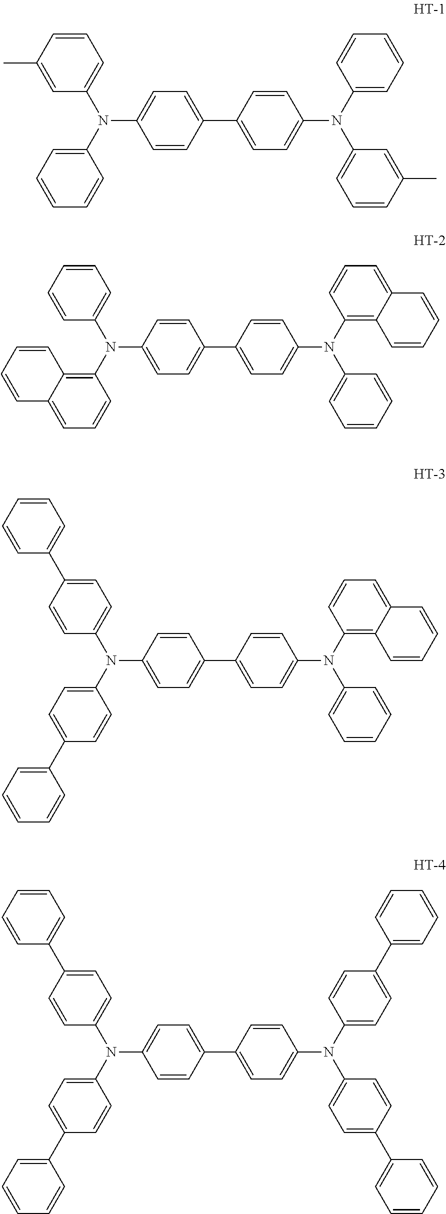

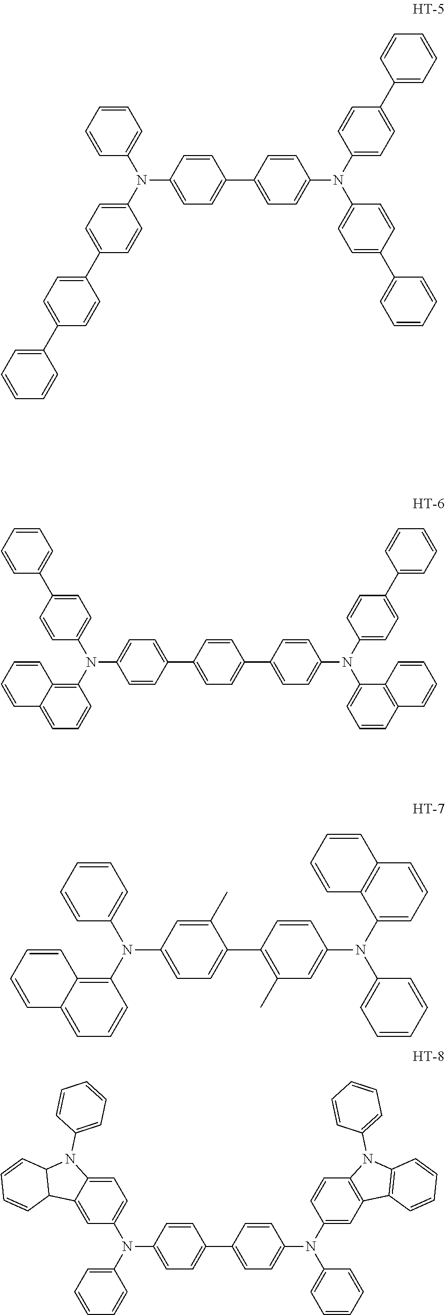 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; C1=CC2c3cc(N(c4ccccc4)c4ccc(-c5ccc(N(c6ccccc6)c6ccc7c(c6)c6ccccc6n7-c6ccccc6)cc5)cc4)ccc3N(c3ccccc3)C2C=C1]

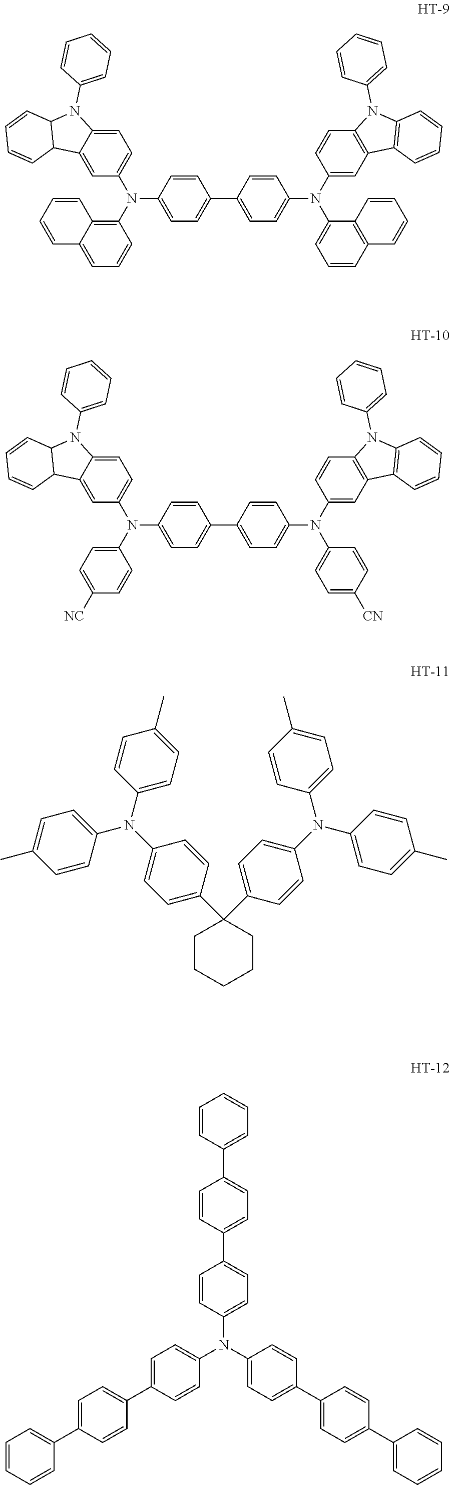

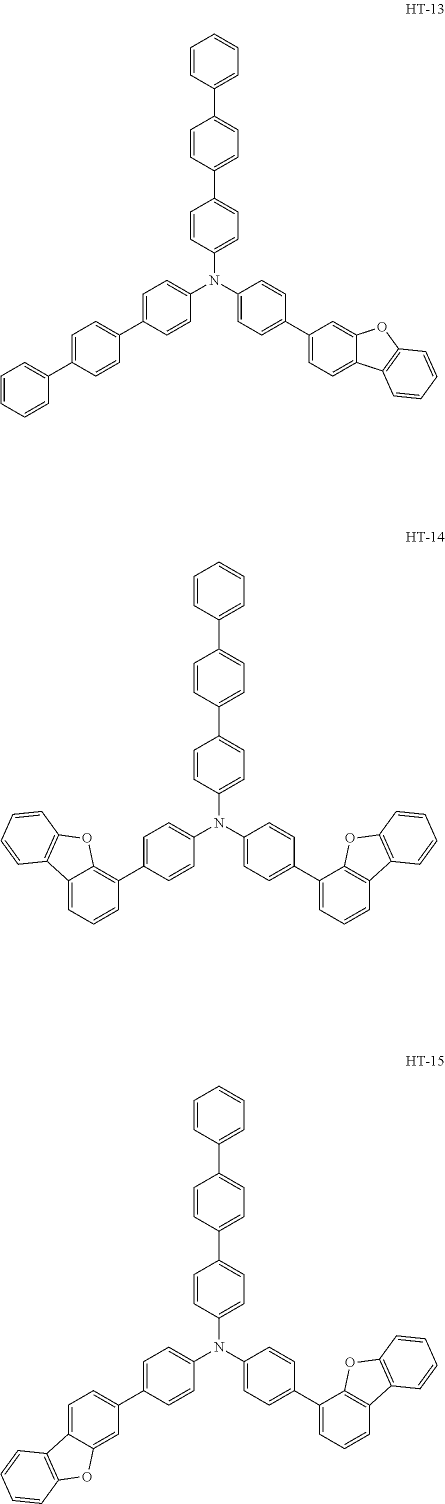 [SMILES: c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1]

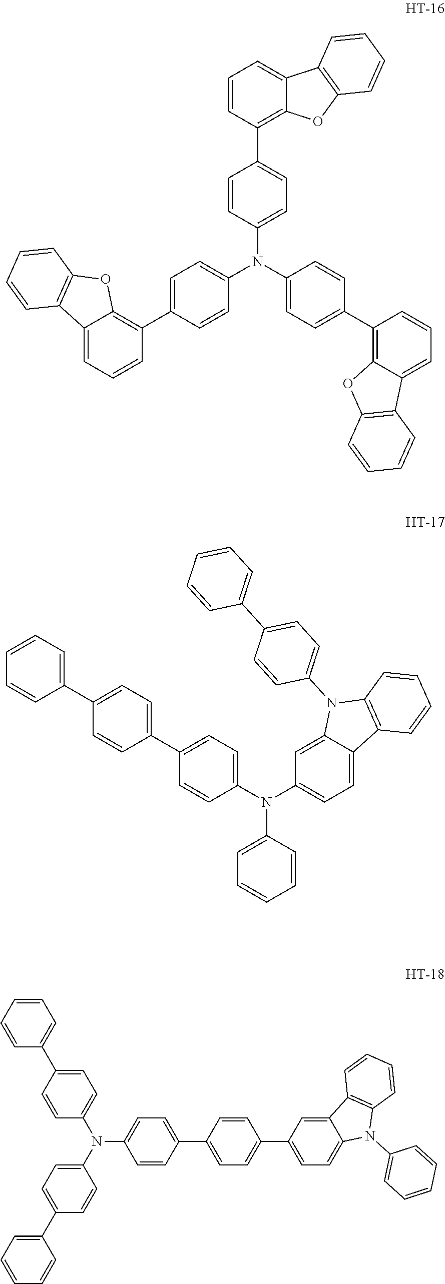 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

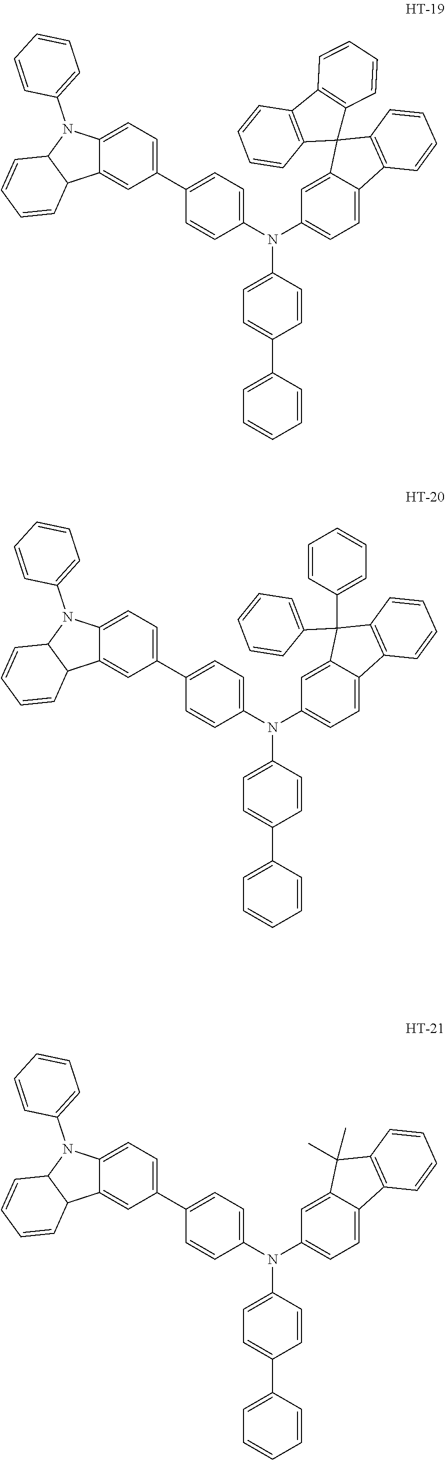 [SMILES: C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)cc3)cc21]

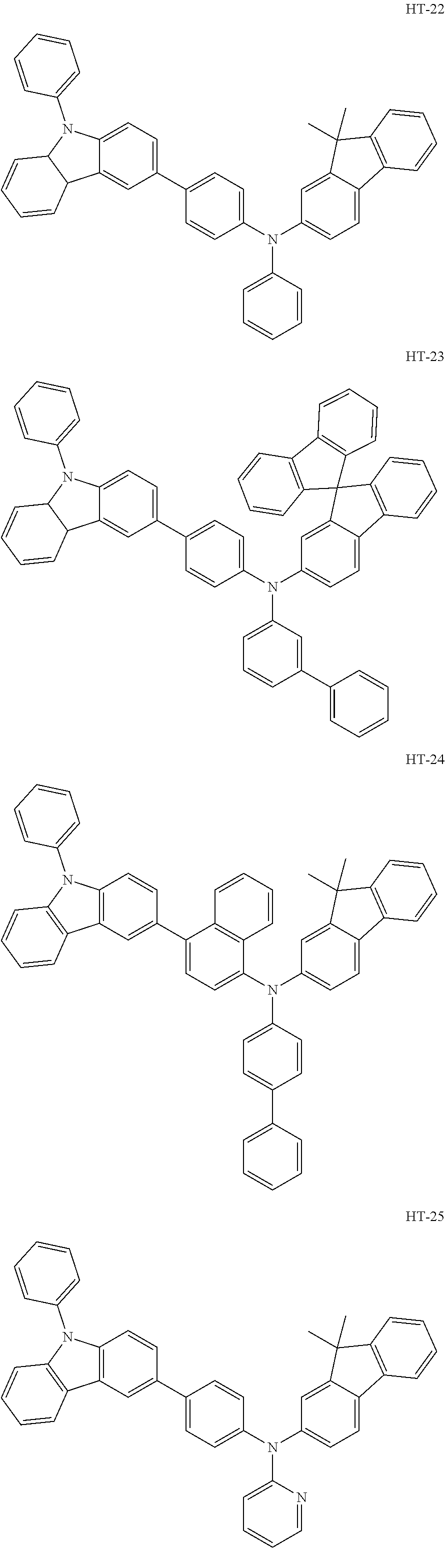 [SMILES: CC1(C)c2ccccc2-c2ccc(N(c3ccccc3)c3ccc(-c4ccc5c(c4)C4C=CC=CC4N5c4ccccc4)cc3)cc21 ; C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccccn3)cc21]

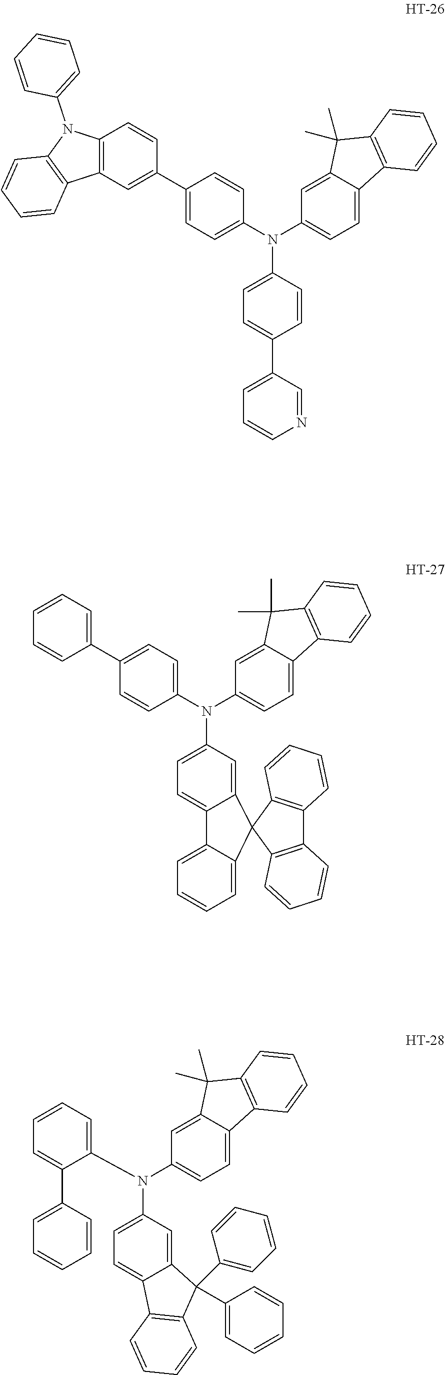 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21]

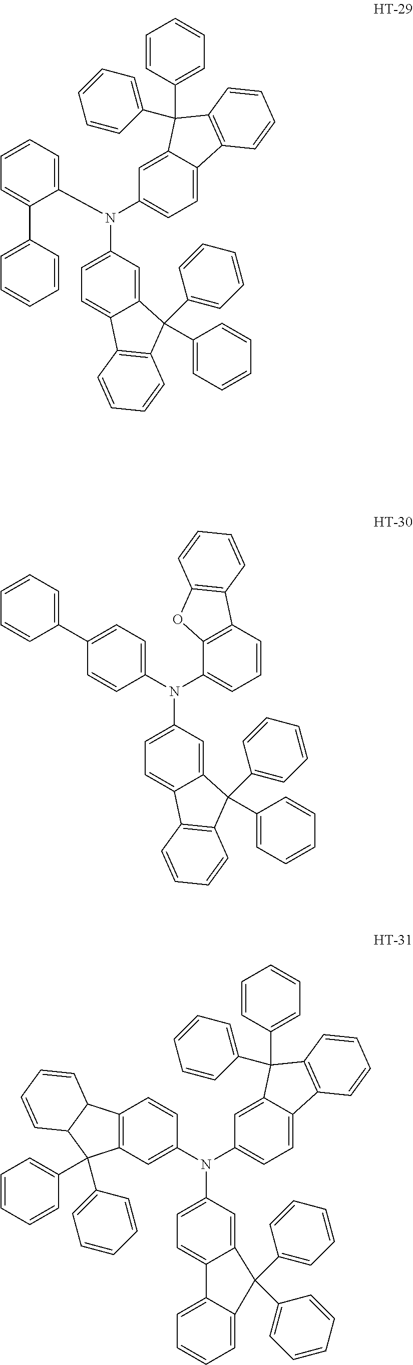 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3cccc4c3oc3ccccc34)cc2)cc1 ; C1=CC2c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3C(c3ccccc3)(c3ccccc3)C2C=C1]

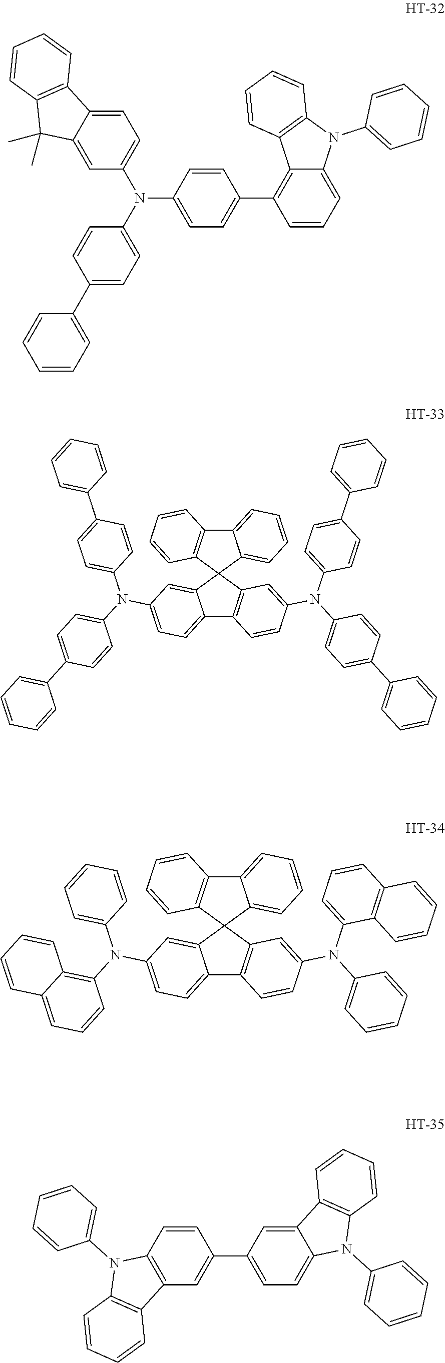 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1 ; c1ccc(-n2c3ccccc3c3cc(-c4ccc5c(c4)c4ccccc4n5-c4ccccc4)ccc32)cc1]

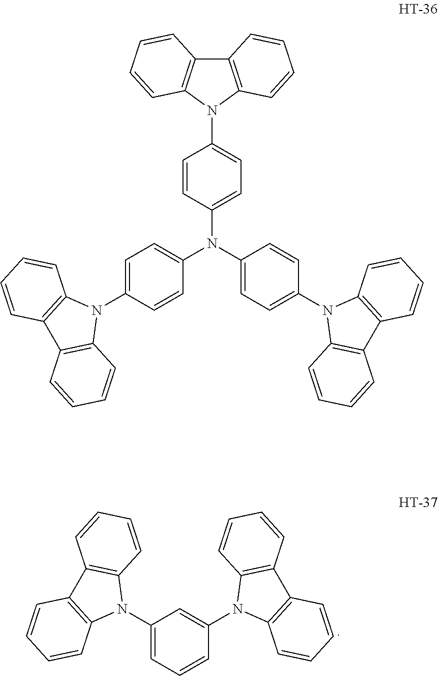 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1cc(-n2c3ccccc3c3ccccc32)cc(-n2c3ccccc3c3ccccc32)c1]

In addition, the host material in the red light-emitting unit 31 and/or the green light-emitting unit 32 may be a traditional host material, as long as they are controlled and collocated such that a first excited singlet energy level of the host material is not lower than that of the TADF sensitizing agent, and a first excited triplet energy level of the host material is not lower than that of the TADF sensitizing agent.

For example, the host material includes, but is not limited to, compounds having one of the following structures and their derivatives:

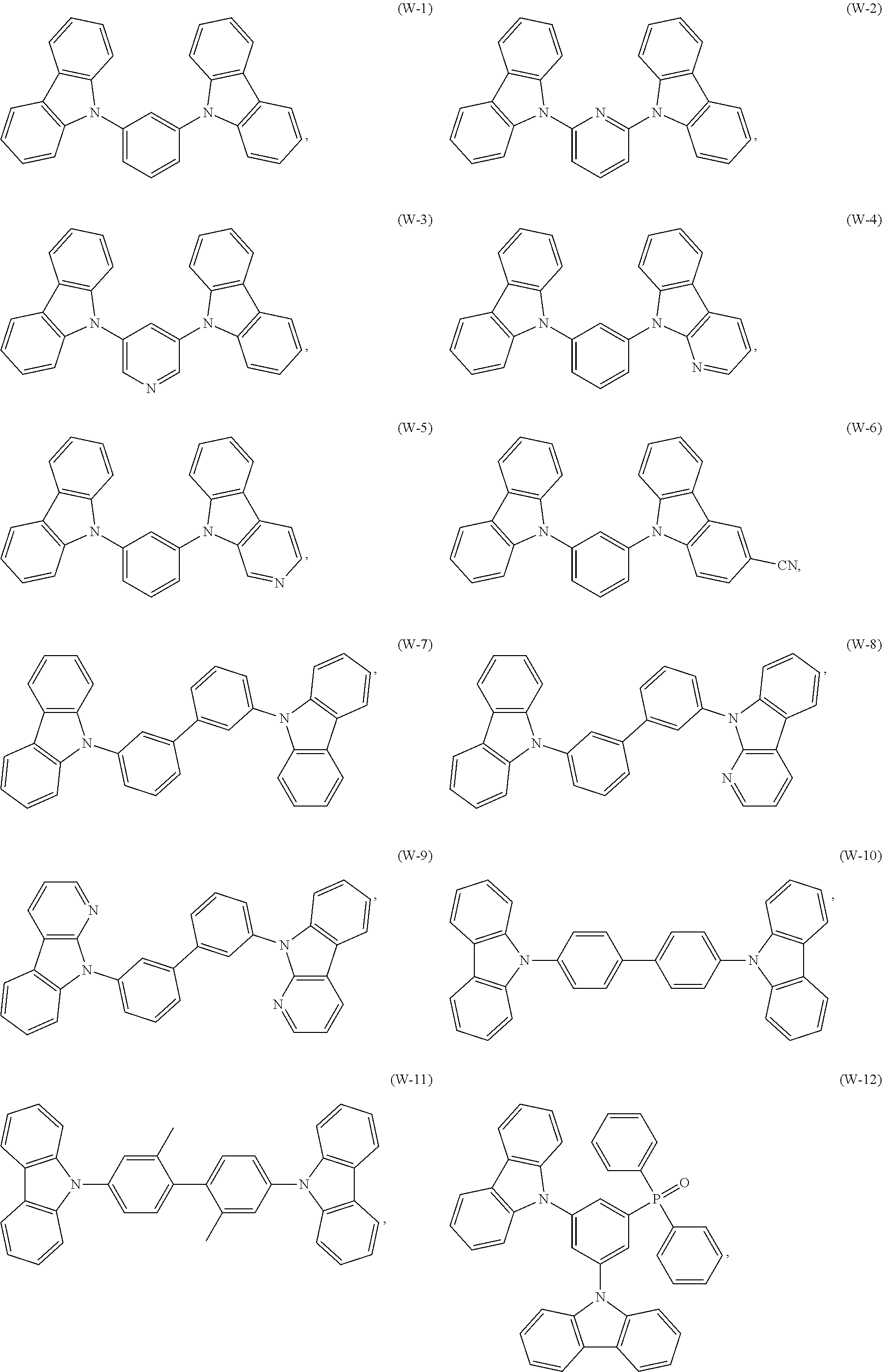

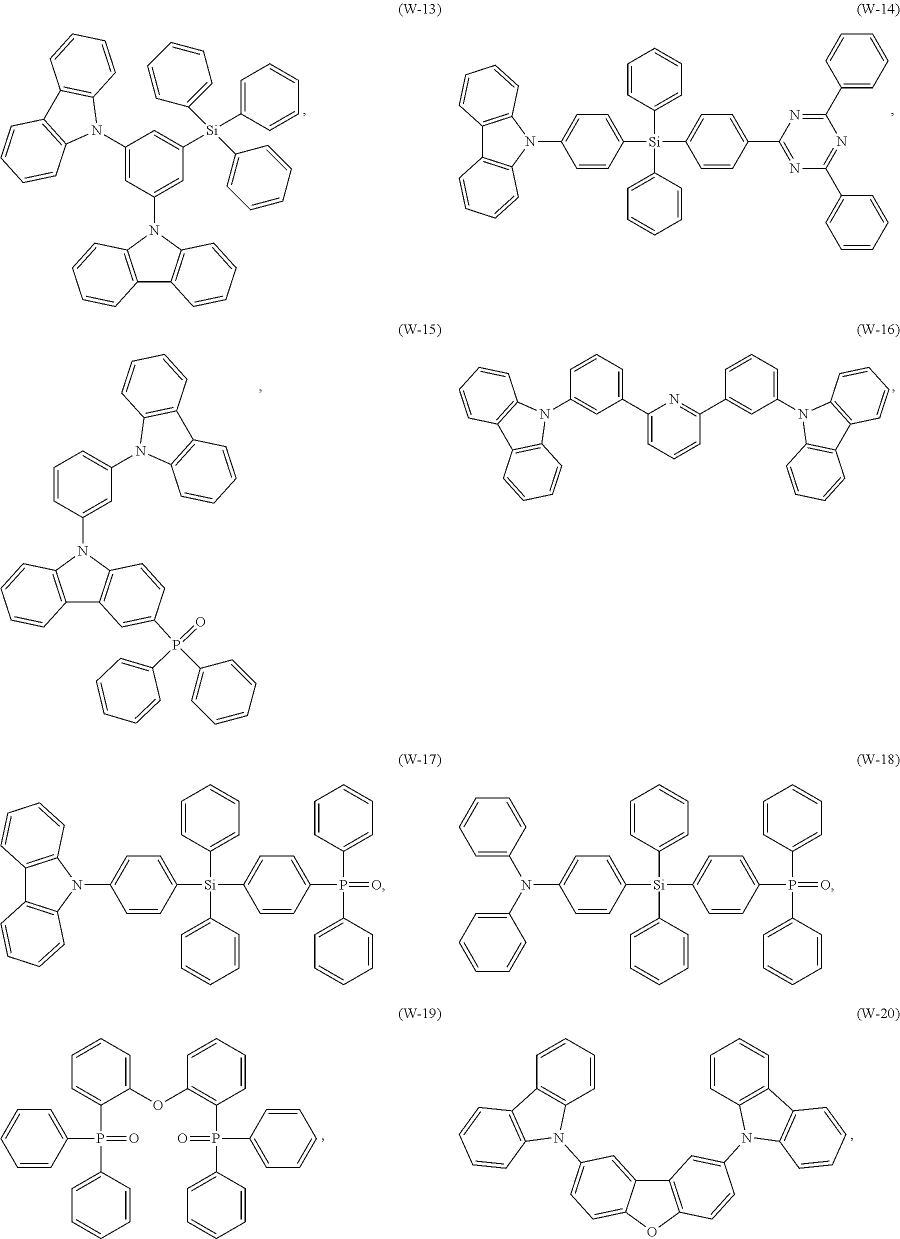

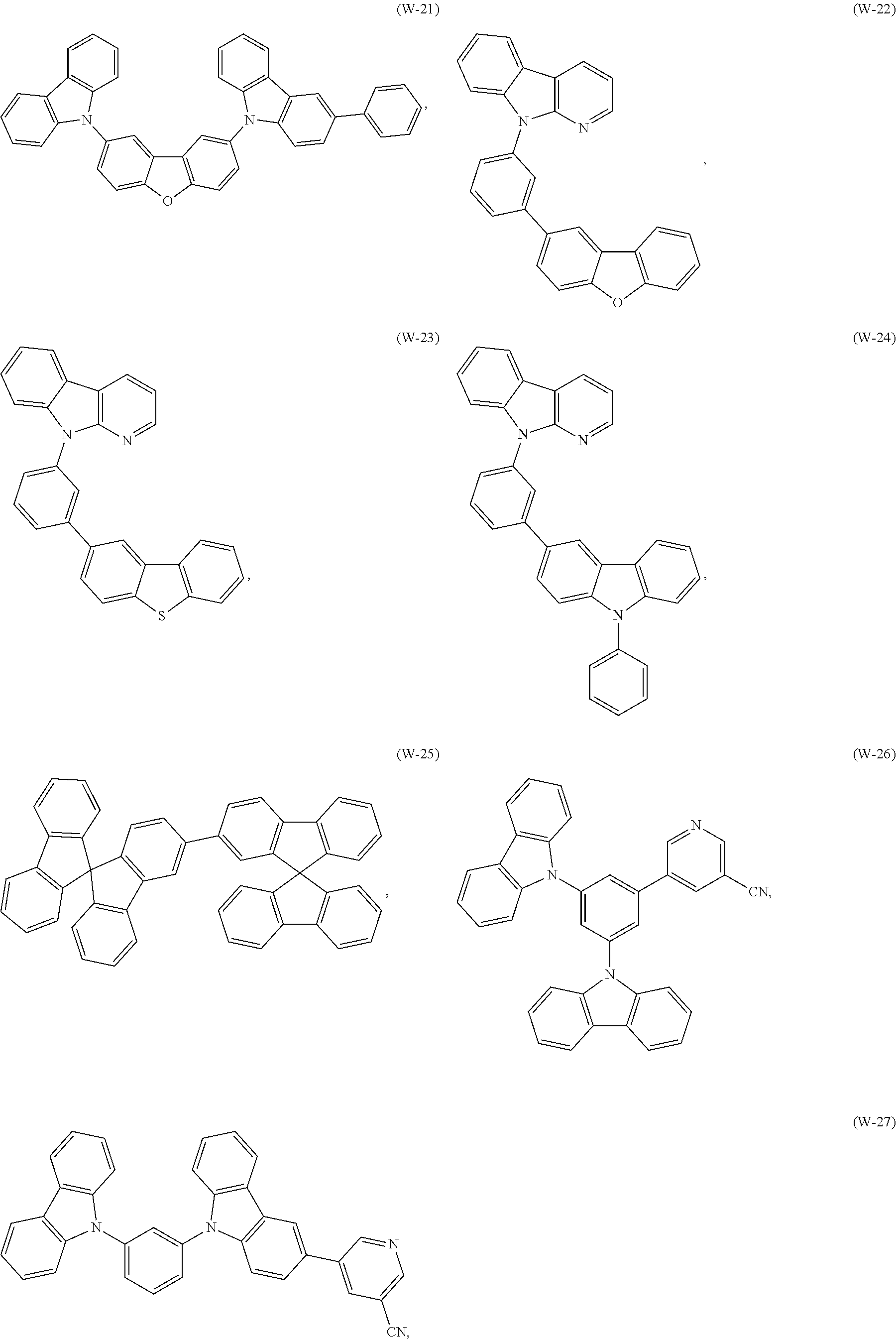

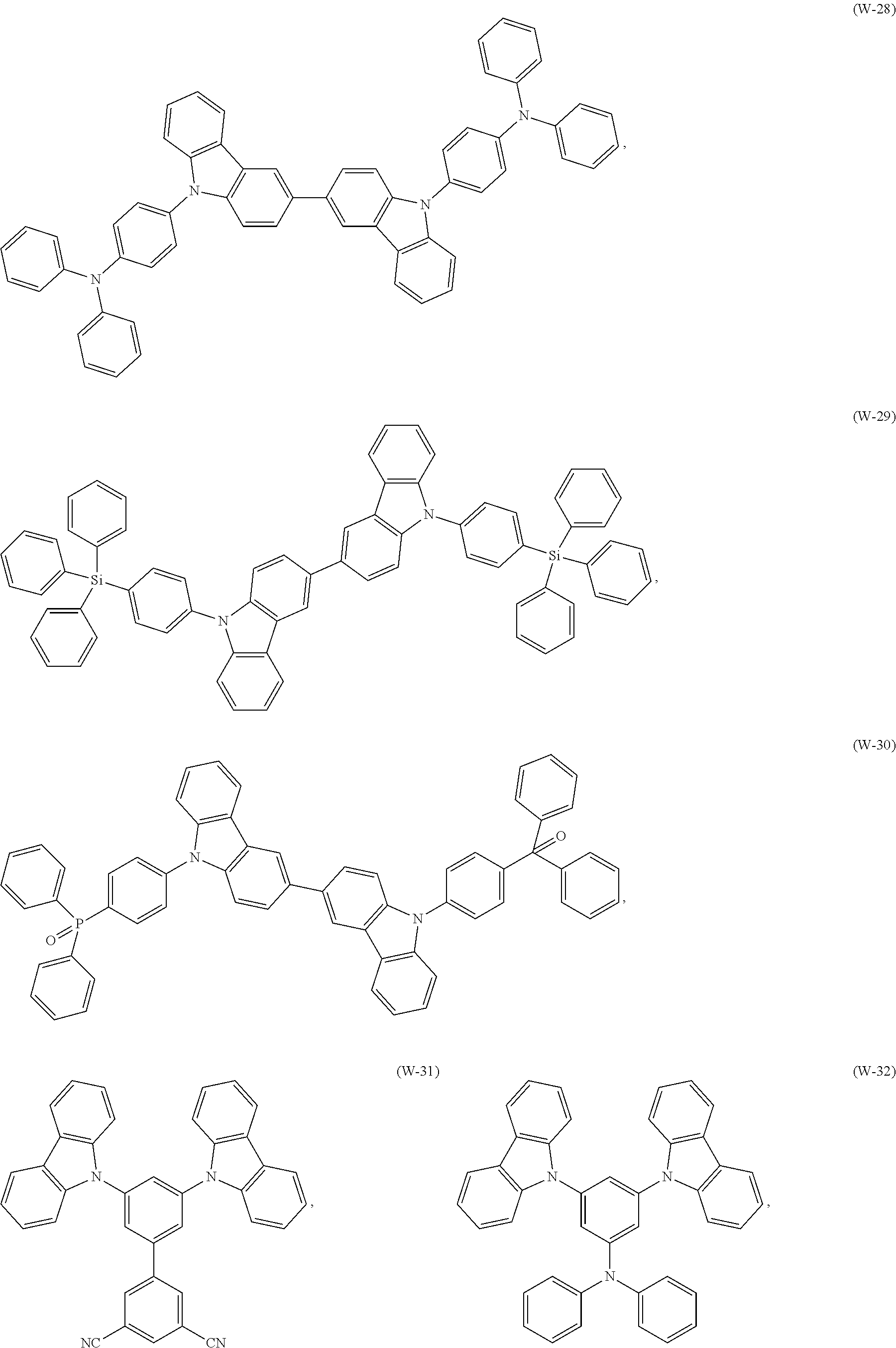

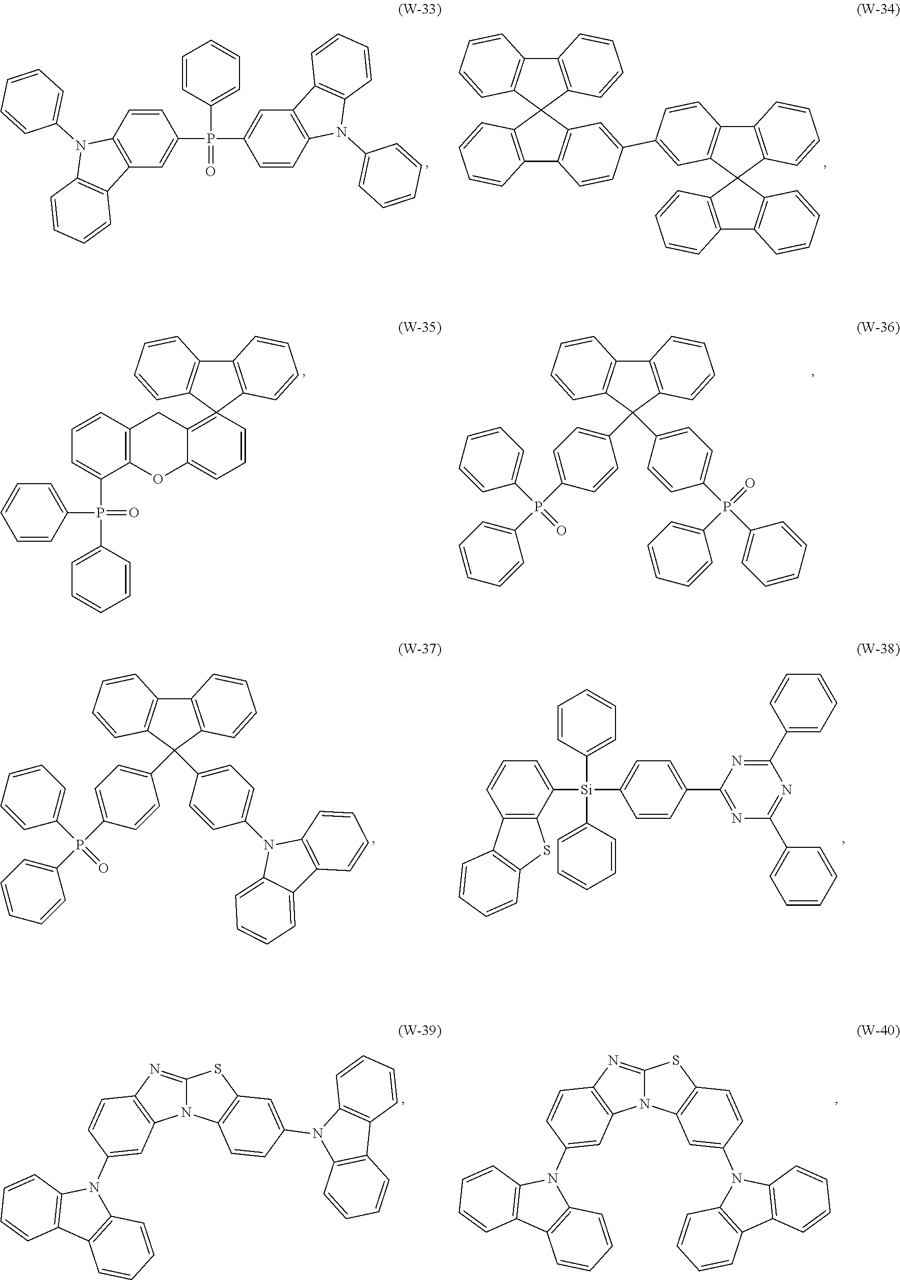

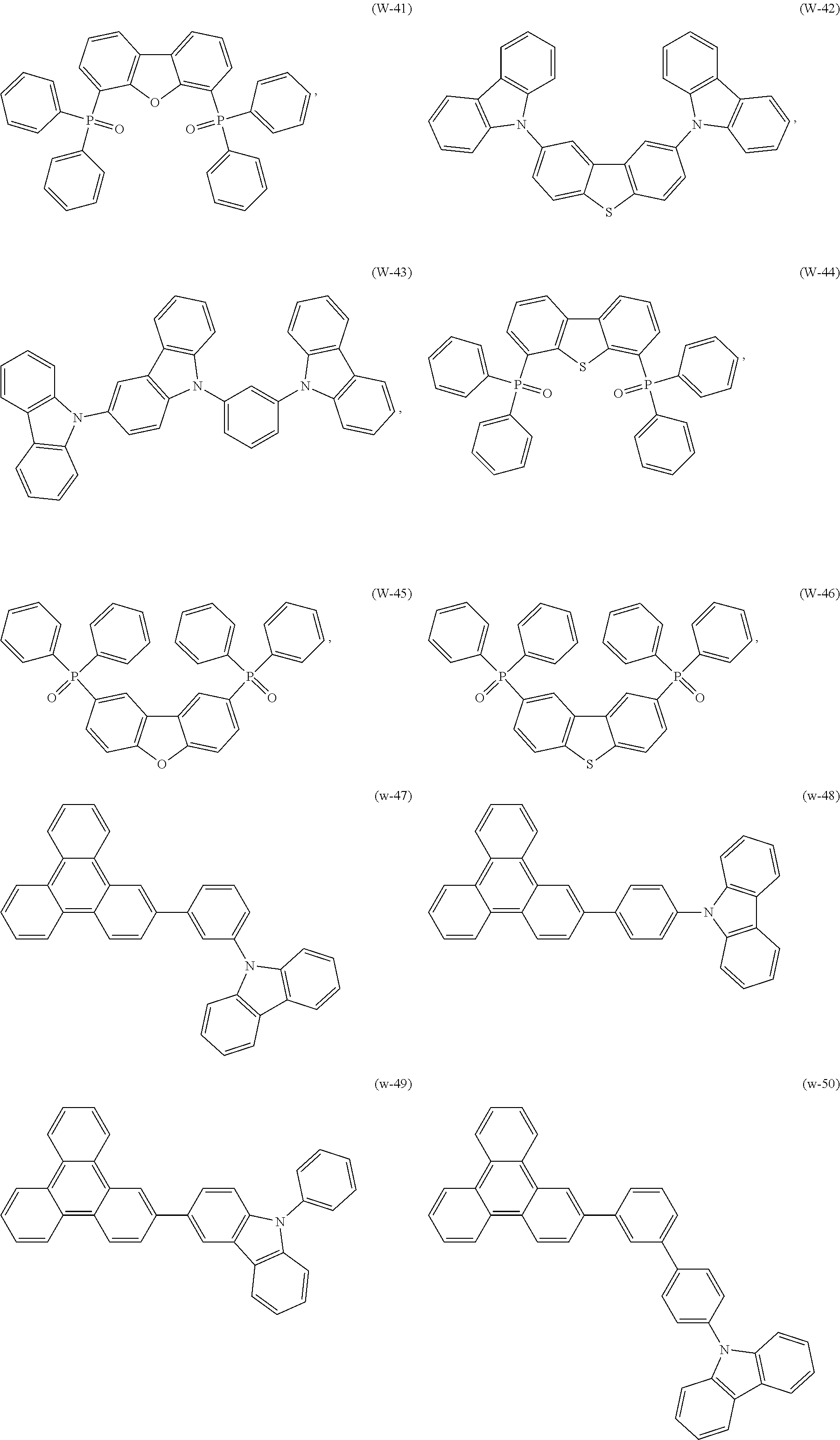

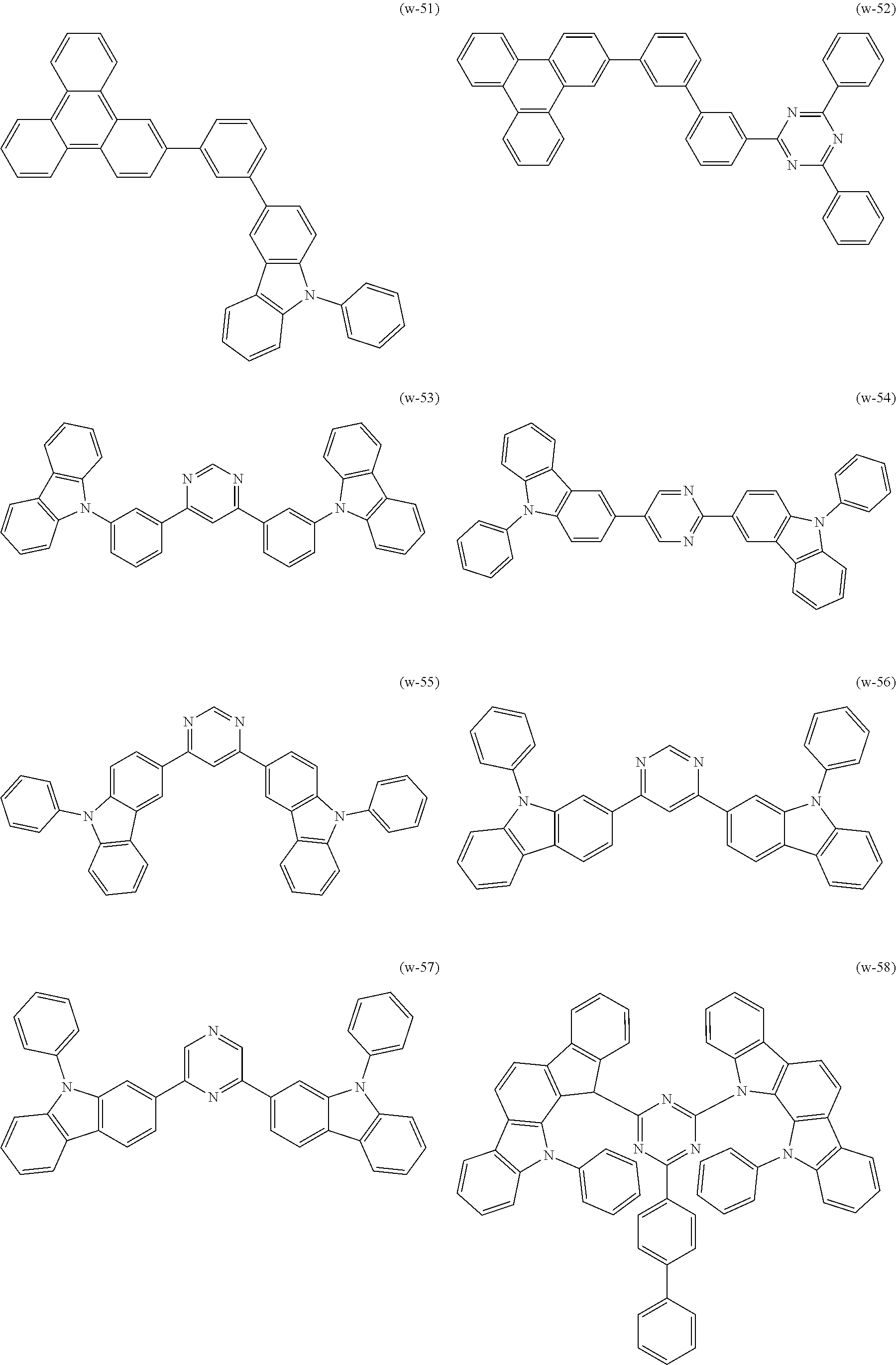

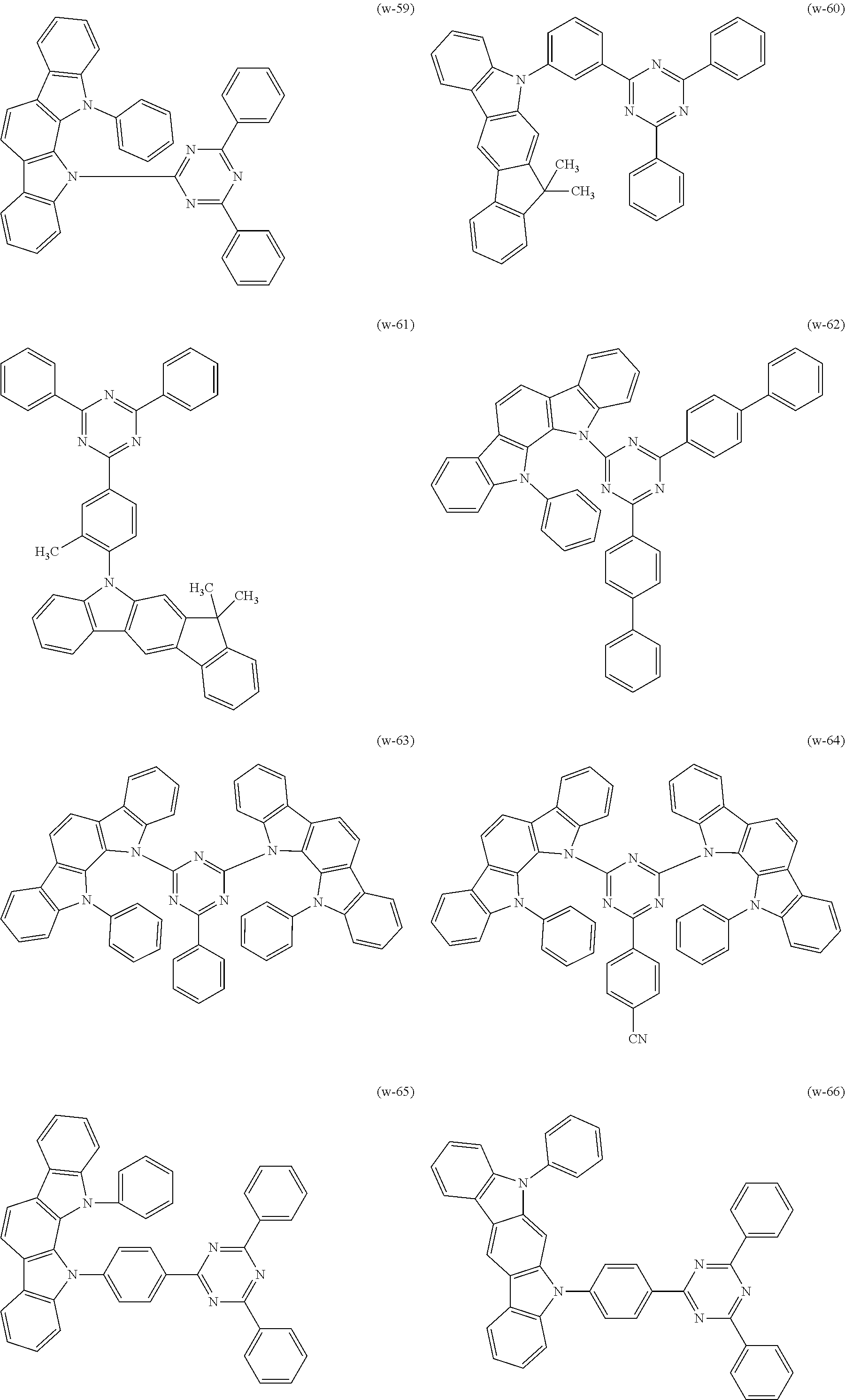

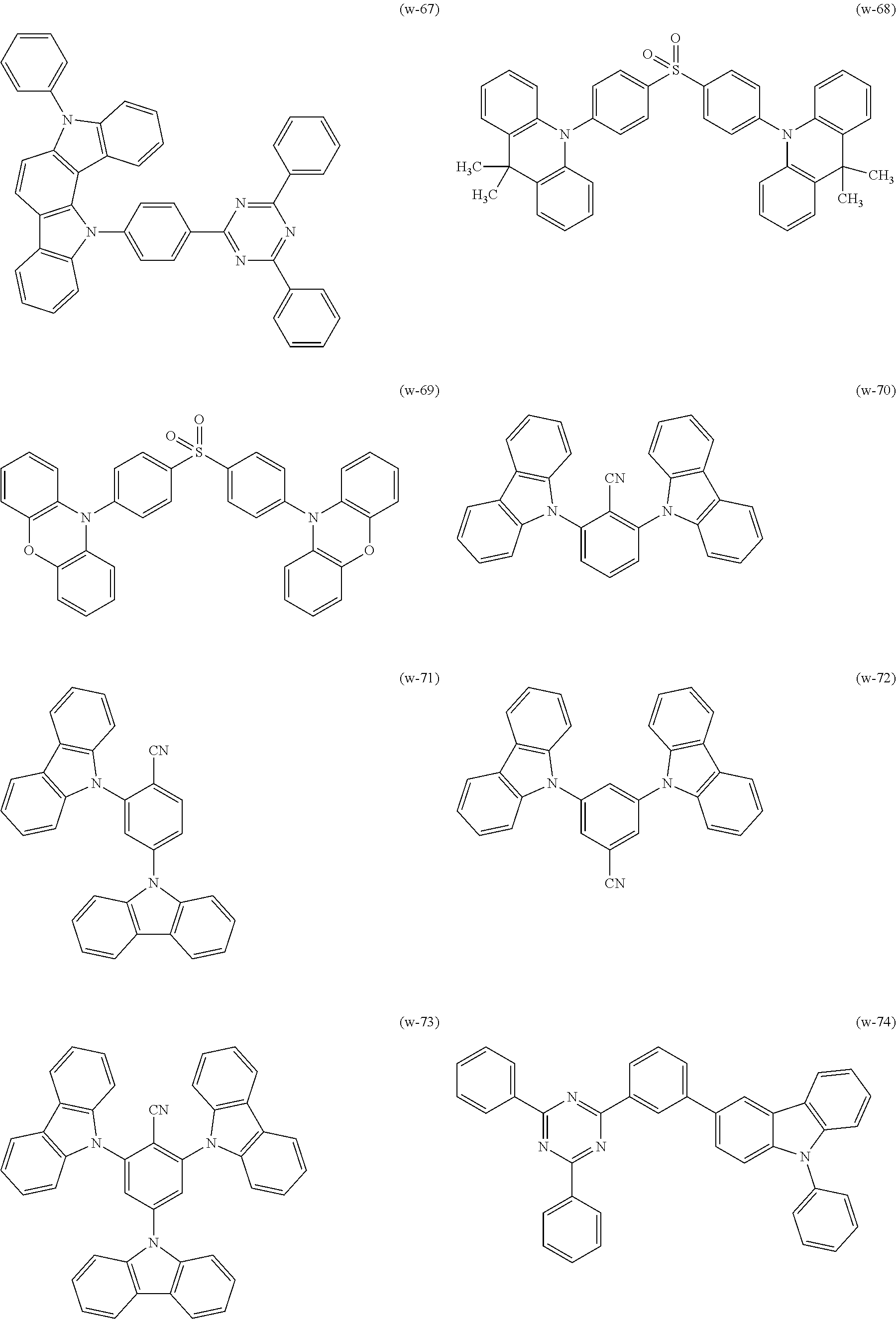

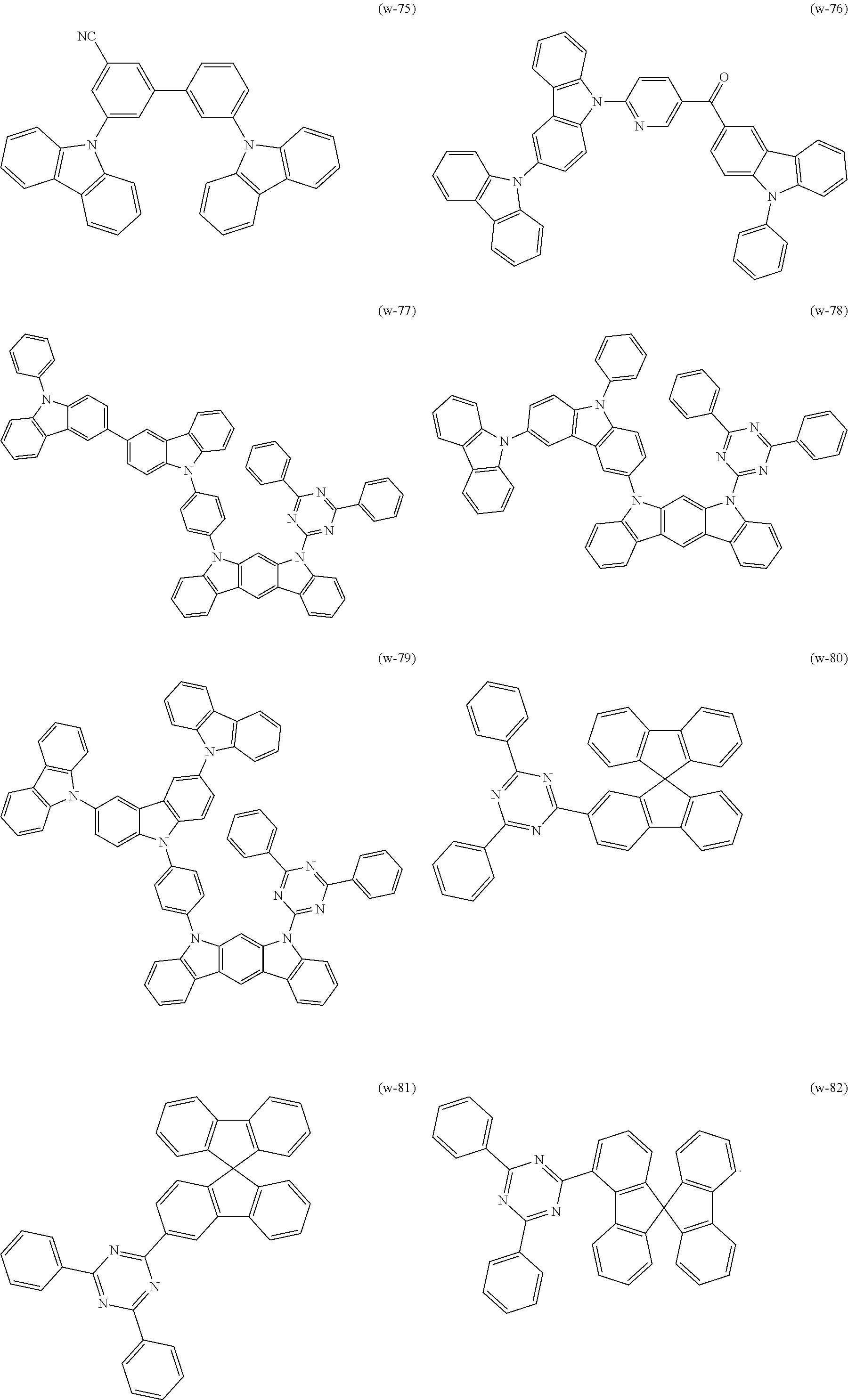

The TADF sensitizing agent in the red light-emitting unit 31 and/or the green light-emitting unit 32 is a material with ΔEst≤0.30 eV, including but not limited to the following TADF materials. For example, the TADF sensitizing agent includes, but is not limited to, compounds having one of the following structures and their derivatives:

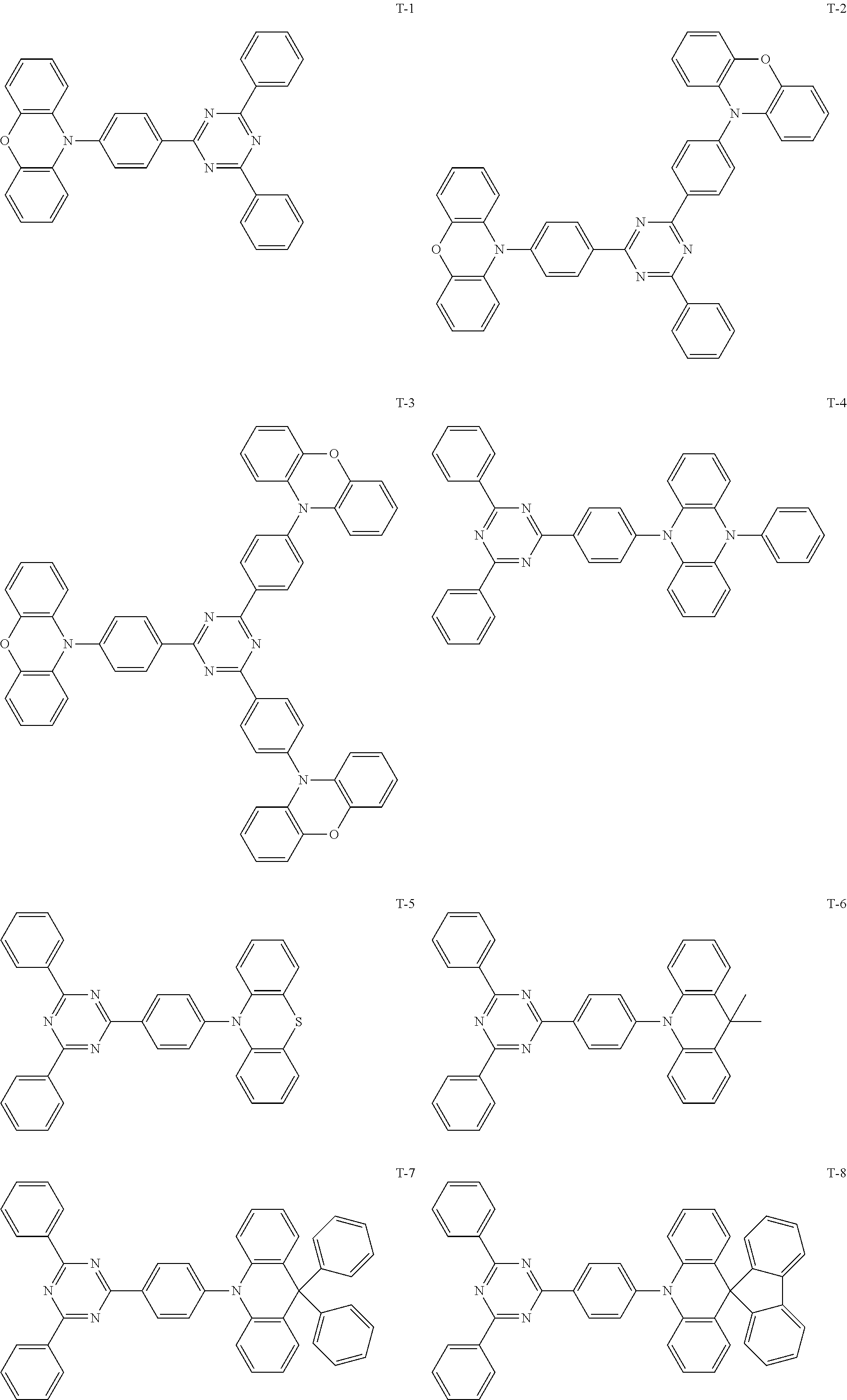

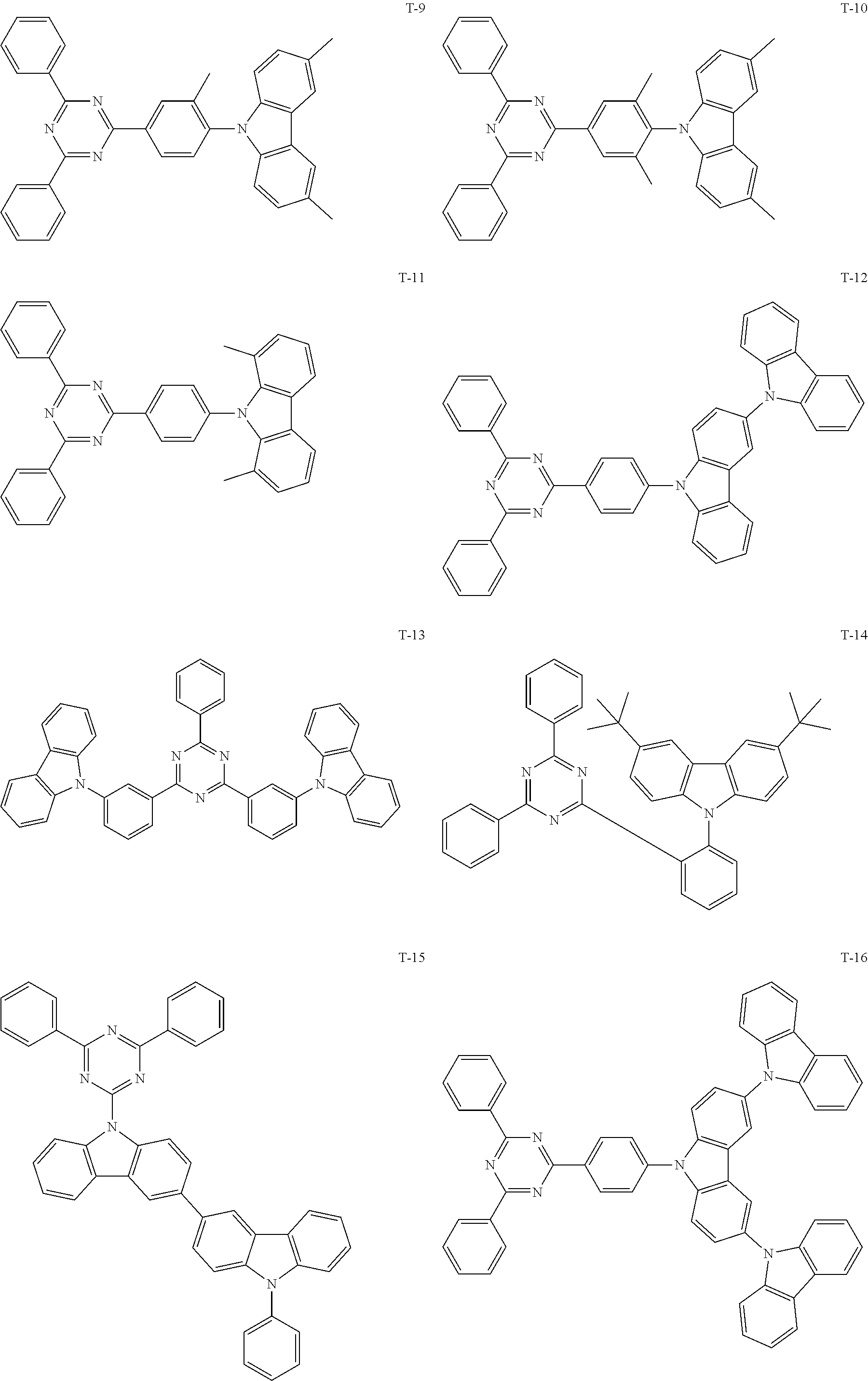

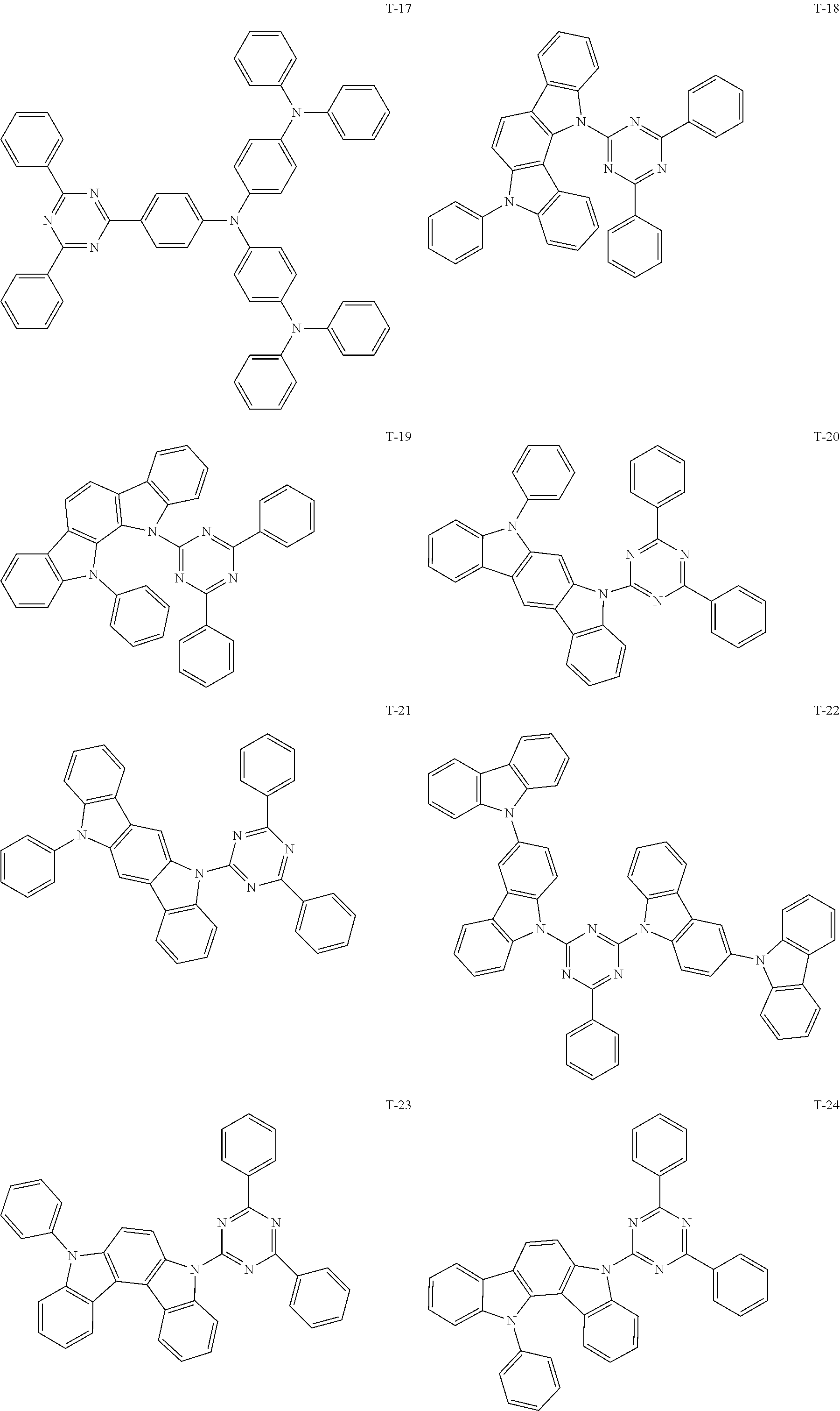

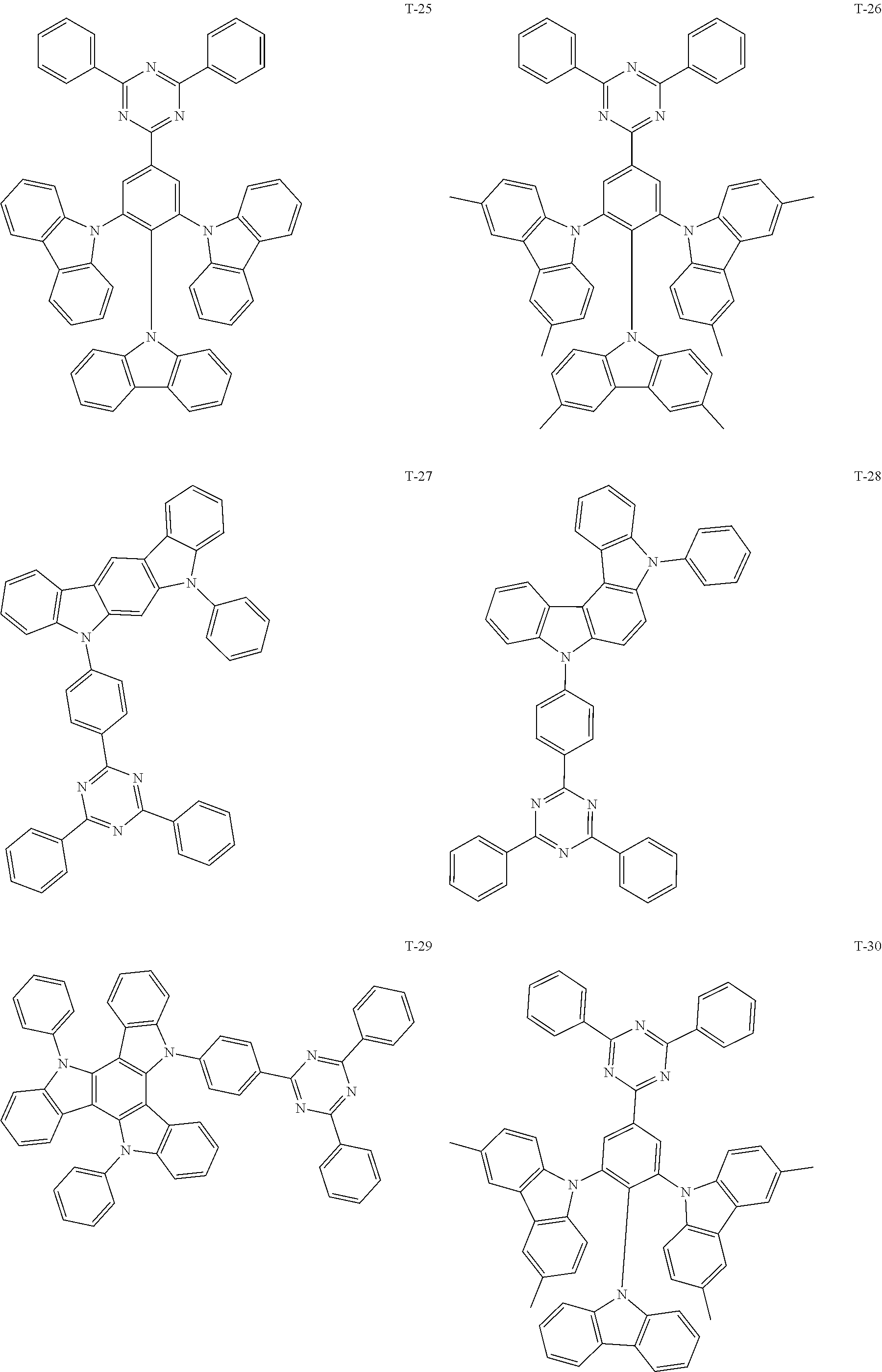

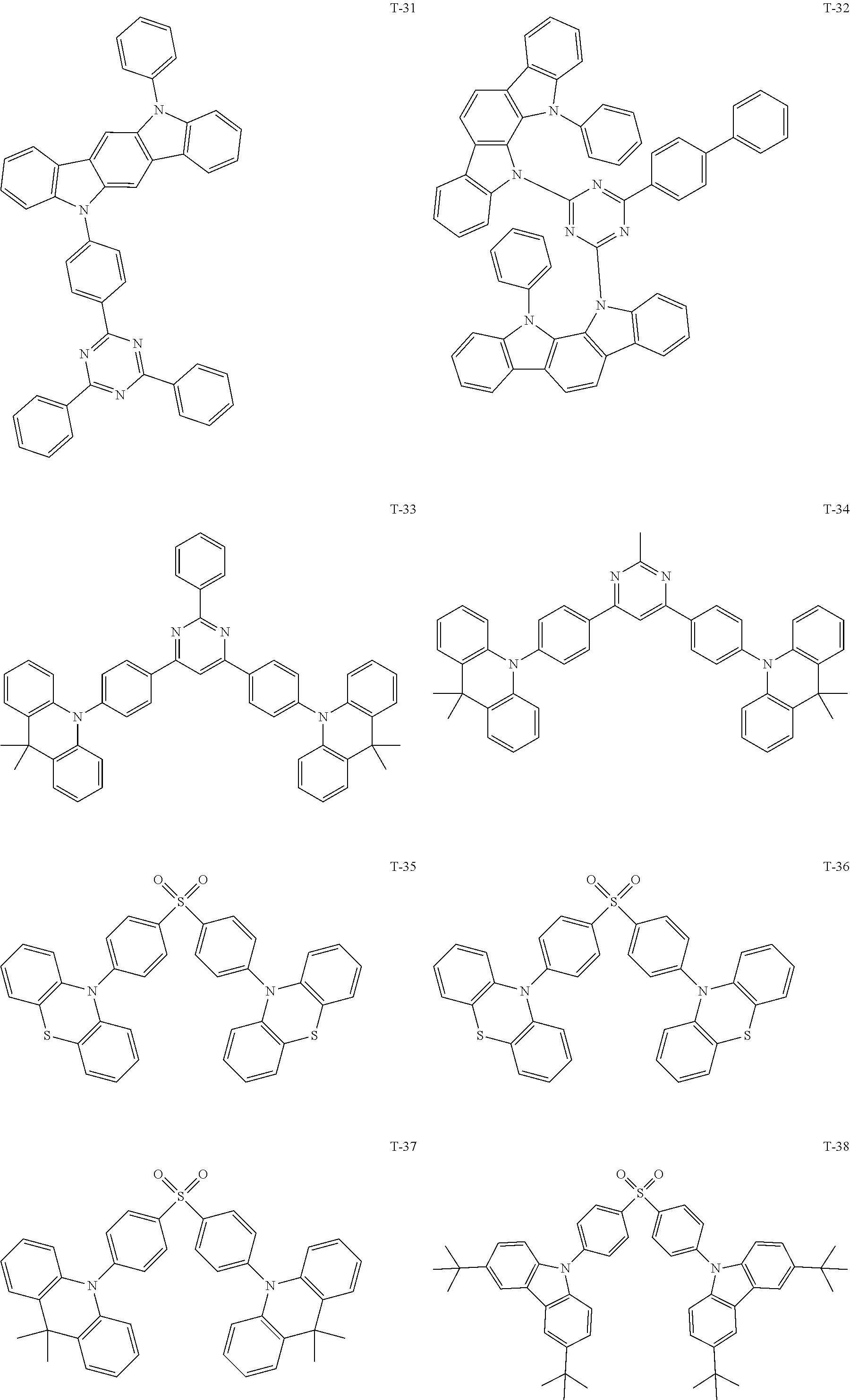

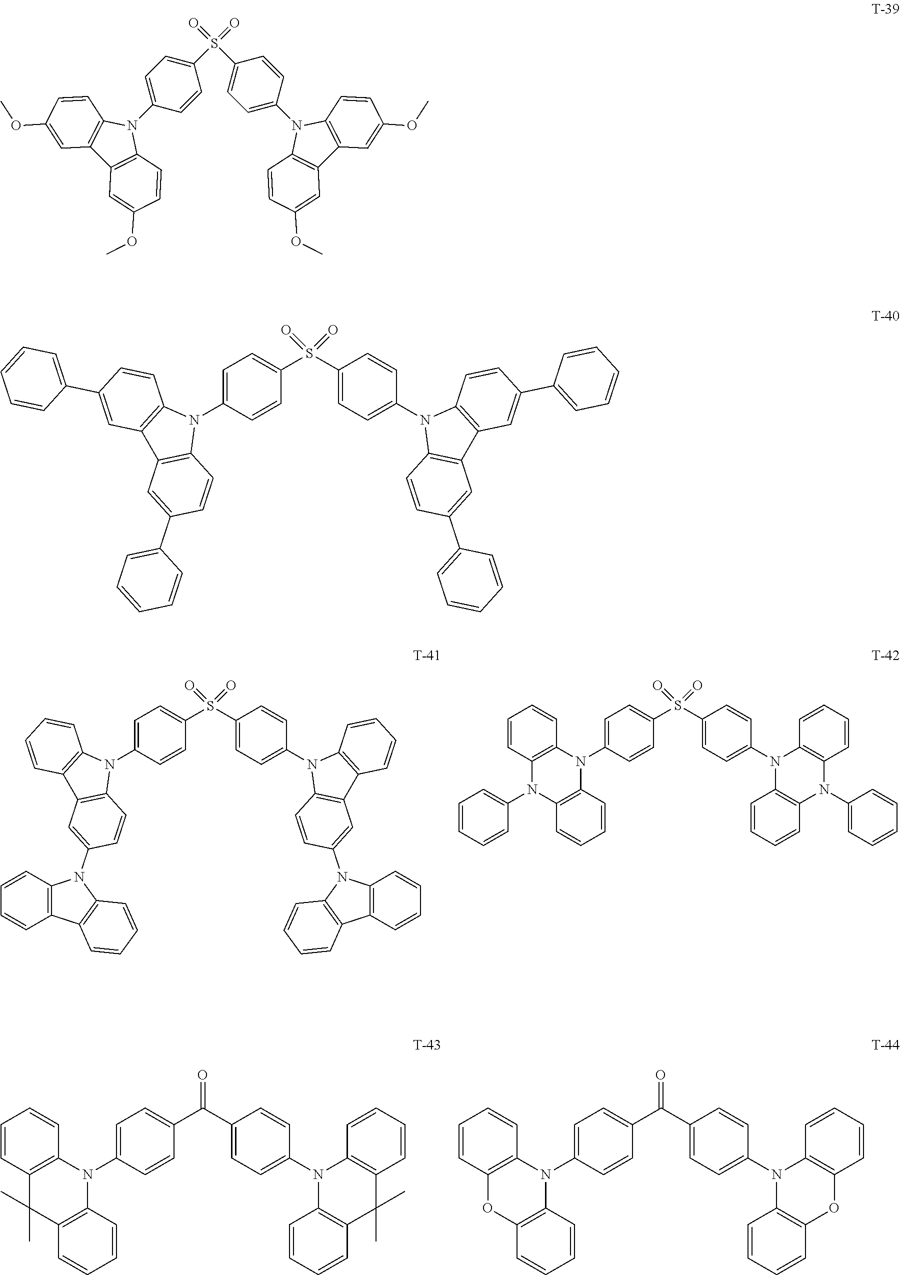

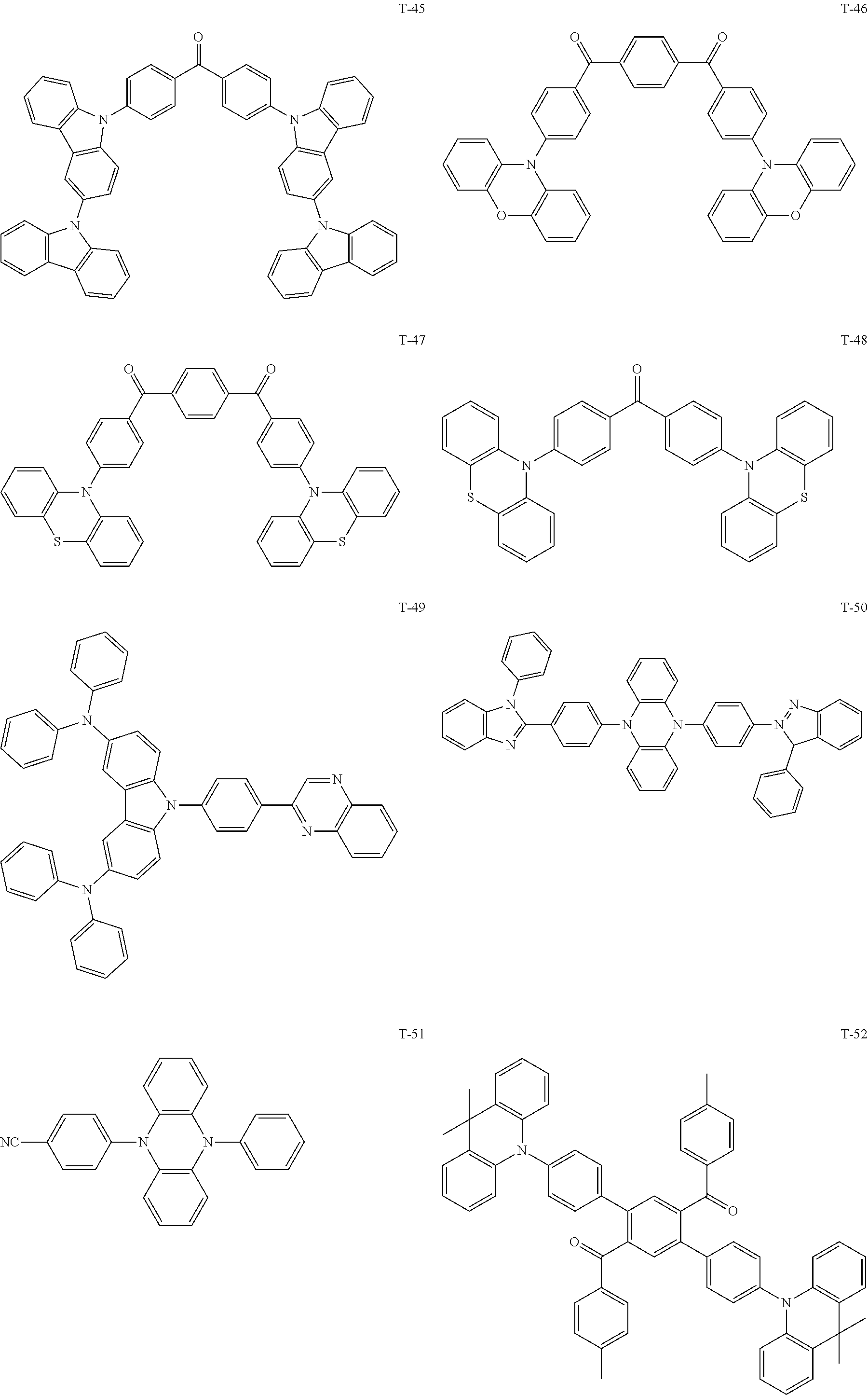

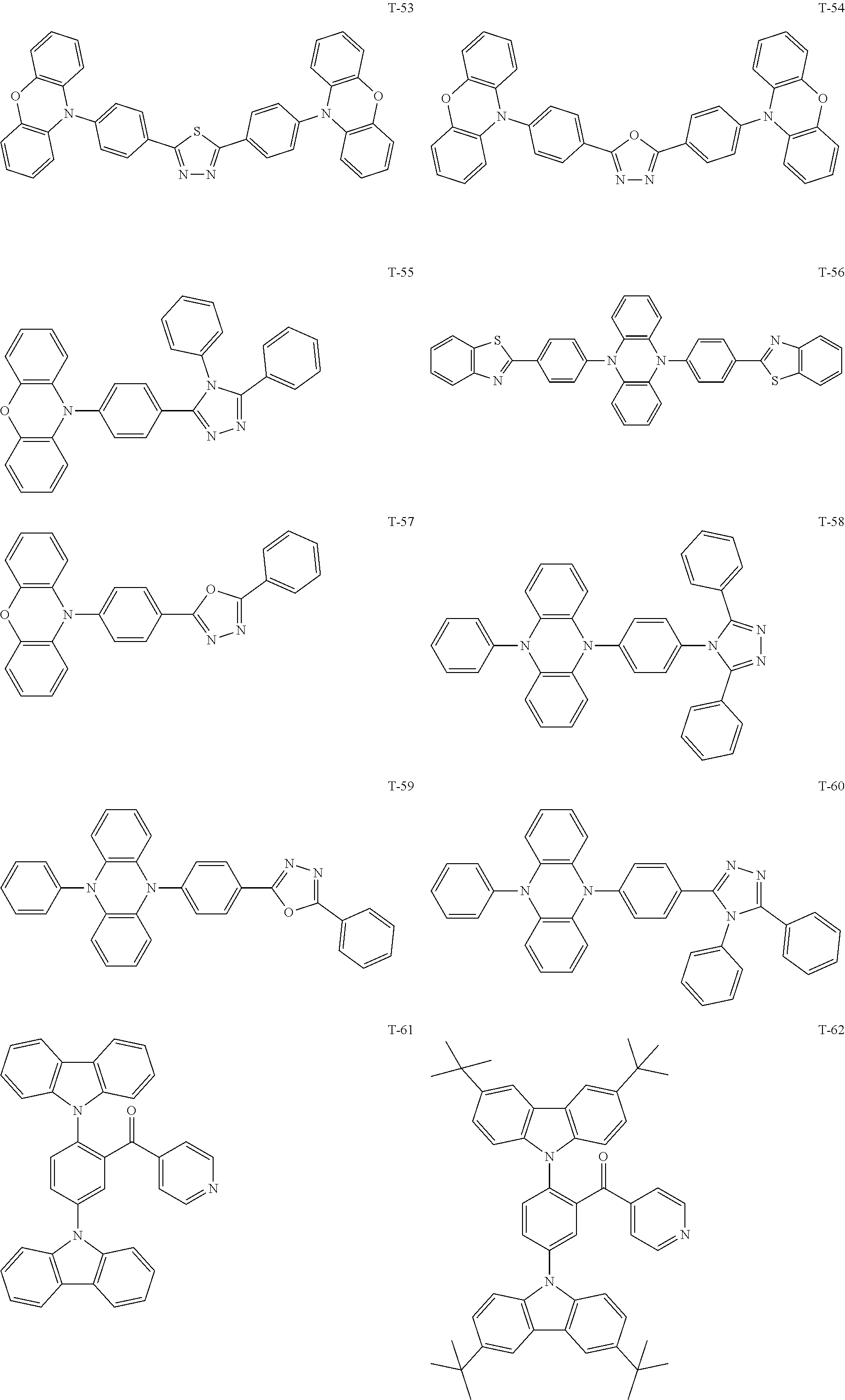

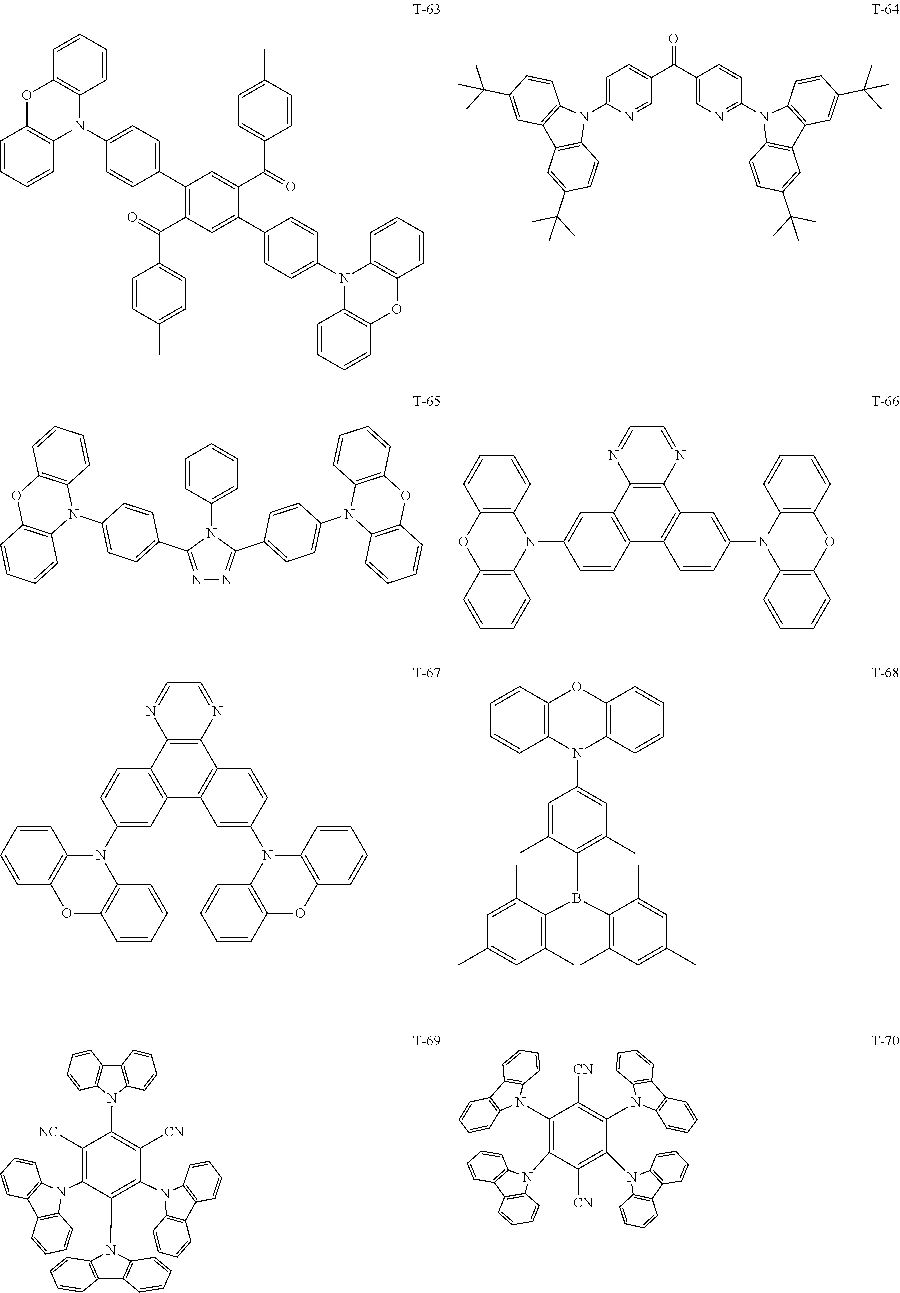

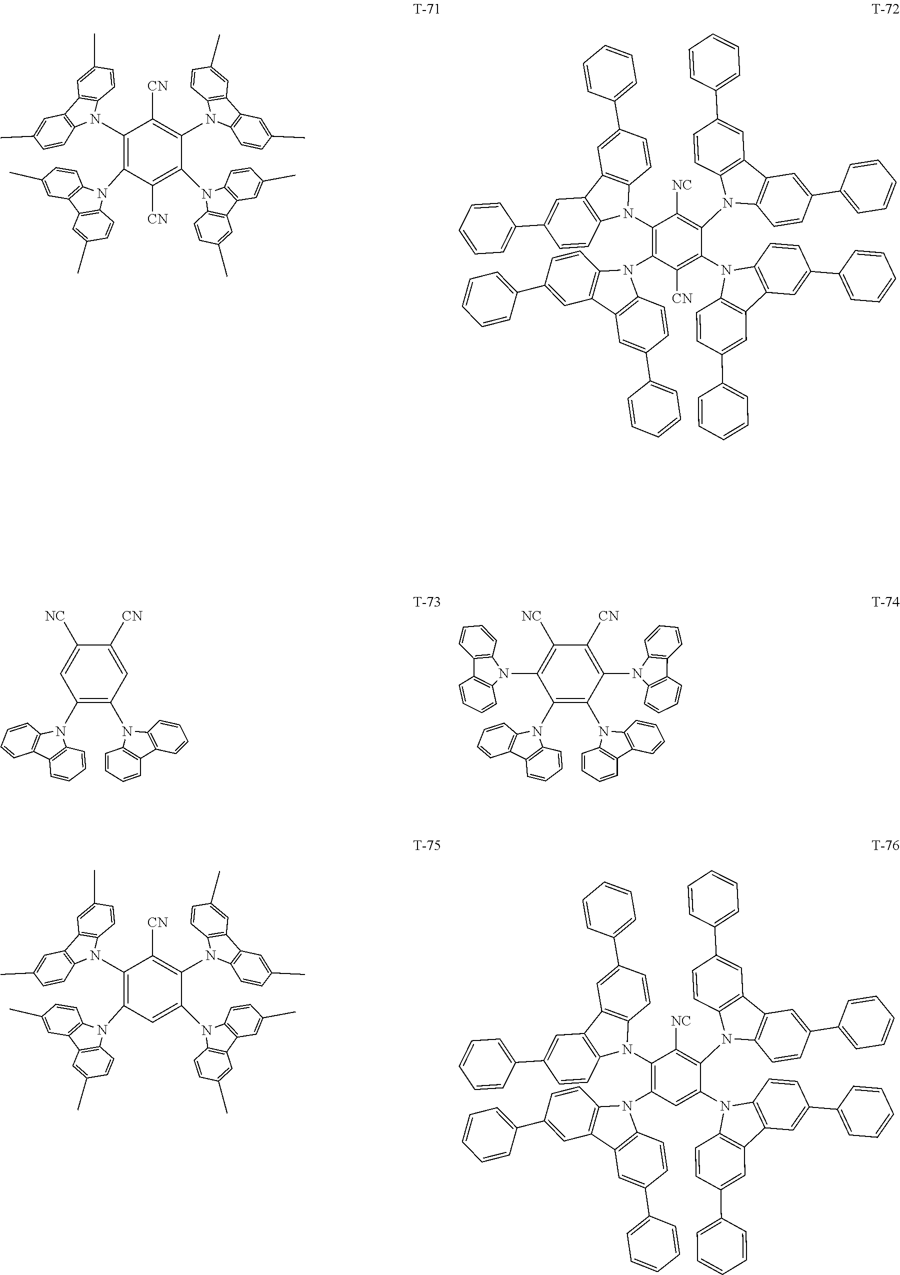

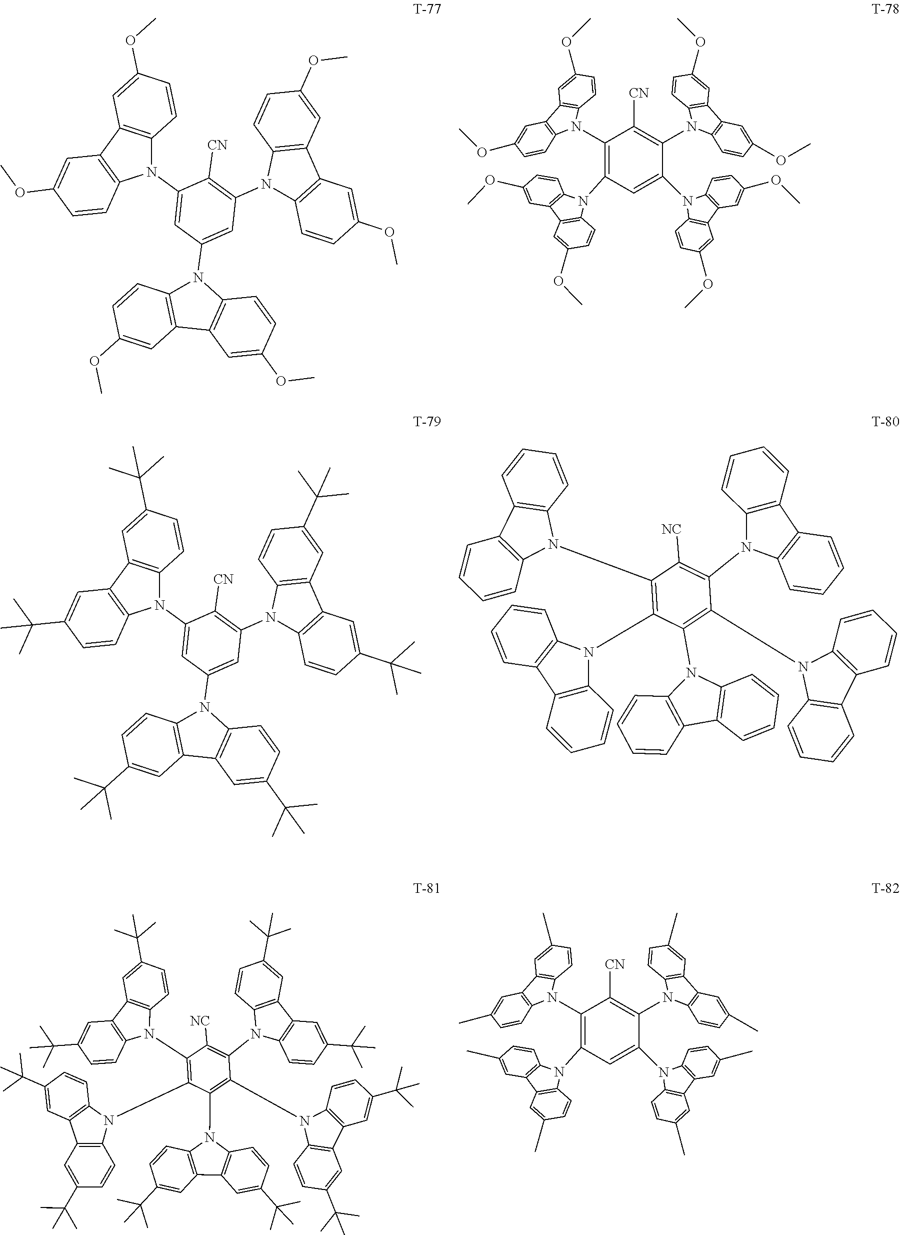

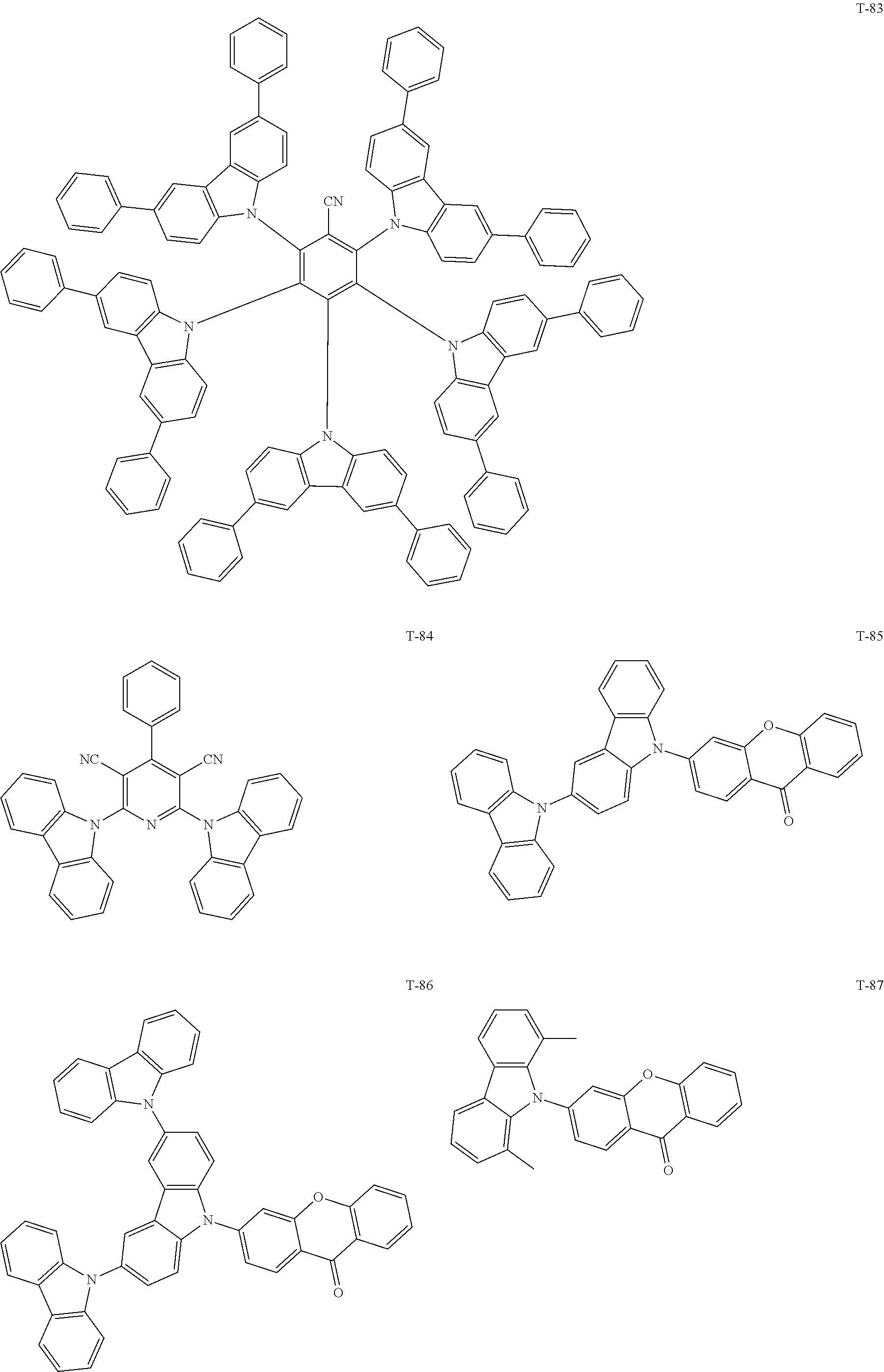

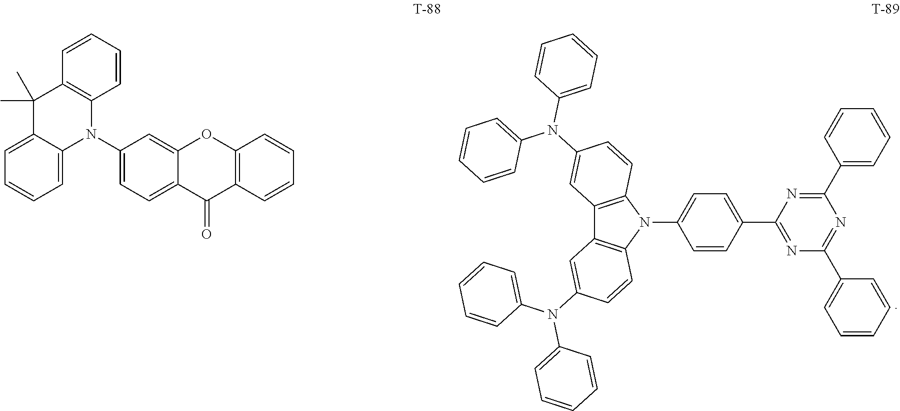 [SMILES: CC1(C)c2ccccc2N(c2ccc3c(=O)c4ccccc4oc3c2)c2ccccc21 ; c1ccc(-c2nc(-c3ccccc3)nc(-c3ccc(-n4c5ccc(N(c6ccccc6)c6ccccc6)cc5c5cc(N(c6ccccc6)c6ccccc6)ccc54)cc3)n2)cc1]

In the red light-emitting unit 31 and/or the green light-emitting unit 32, in addition to the host material and the TADF sensitizing agent, a narrow-spectrum boron-containing dye is included. When the narrow-spectrum boron-containing dye is selected, it has a more positive effect on the narrowing of the spectrum of the device and the improvement of color purity. The narrow-spectrum boron-containing material mentioned in the present application refers to a dye containing boron atoms and having a full-width half-maximum of less than 80 nm in toluene solution. It includes, but is not limited to, compounds having one of the following structures and derivatives thereof:

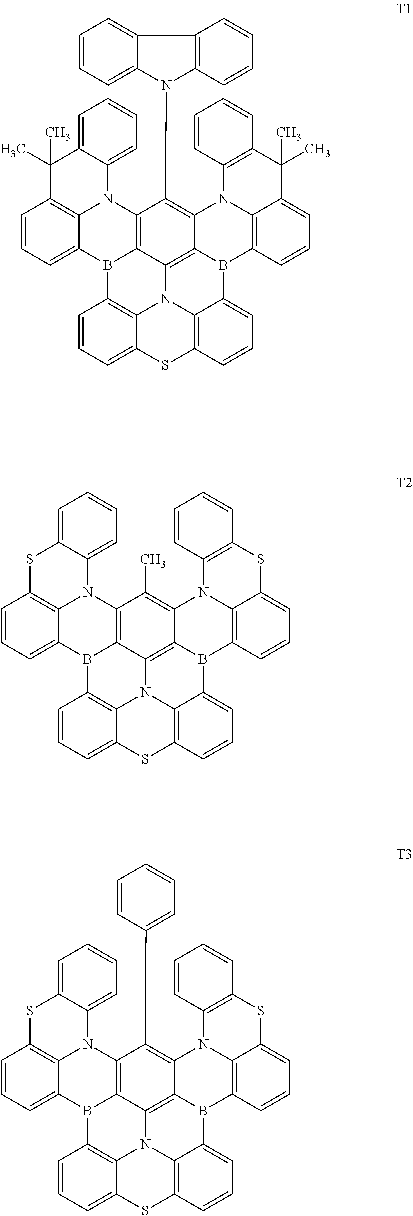 [SMILES: CC1(C)c2ccccc2N2c3c(cccc31)B1c3cccc4c3N3c5c(cccc5B5c6cccc7c6N(c6ccccc6C7(C)C)c6c5c3c1c2c6-n1c2ccccc2c2ccccc21)S4 ; Cc1c2c3c4c5c1N1c6ccccc6Sc6cccc(c61)B5c1cccc5c1N4c1c(cccc1B3c1cccc3c1N2c1ccccc1S3)S5 ; c1ccc(-c2c3c4c5c6c2N2c7ccccc7Sc7cccc(c72)B6c2cccc6c2N5c2c(cccc2B4c2cccc4c2N3c2ccccc2S4)S6)cc1]

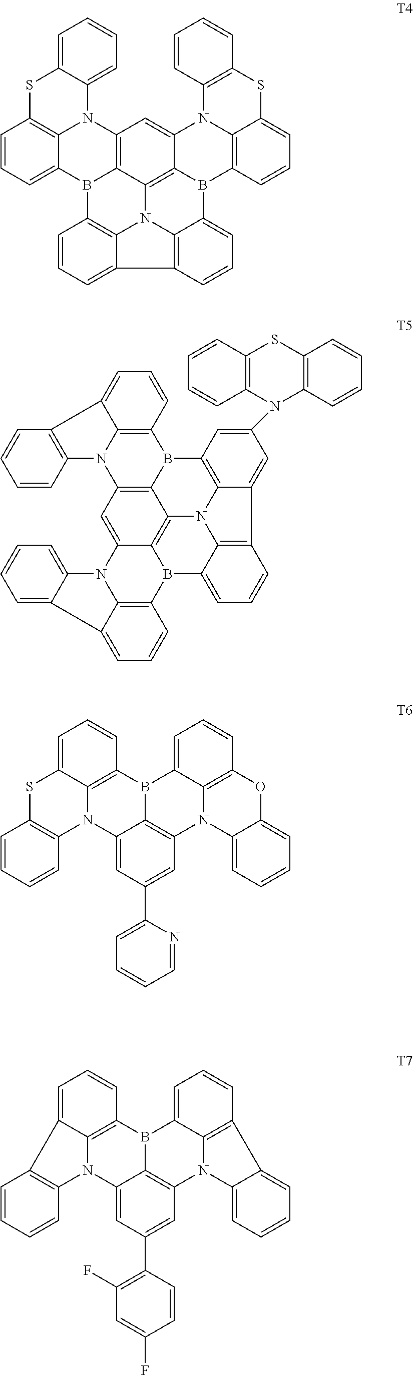 [SMILES: c1ccc2c(c1)Sc1cccc3c1N2c1cc2c4c5c1B3c1cccc3c6cccc(c6n-5c13)B4c1cccc3c1N2c1ccccc1S3 ; c1ccc2c(c1)Sc1ccccc1N2c1cc2c3c(c1)c1cccc4c1n3-c1c3c(cc5c1B2c1cccc2c6ccccc6n-5c12)-n1c2ccccc2c2cccc(c21)B34 ; c1ccc(-c2cc3c4c(c2)N2c5ccccc5Sc5cccc(c52)B4c2cccc4c2N3c2ccccc2O4)nc1 ; Fc1ccc(-c2cc3c4c(c2)-n2c5ccccc5c5cccc(c52)B4c2cccc4c5ccccc5n-3c24)c(F)c1]

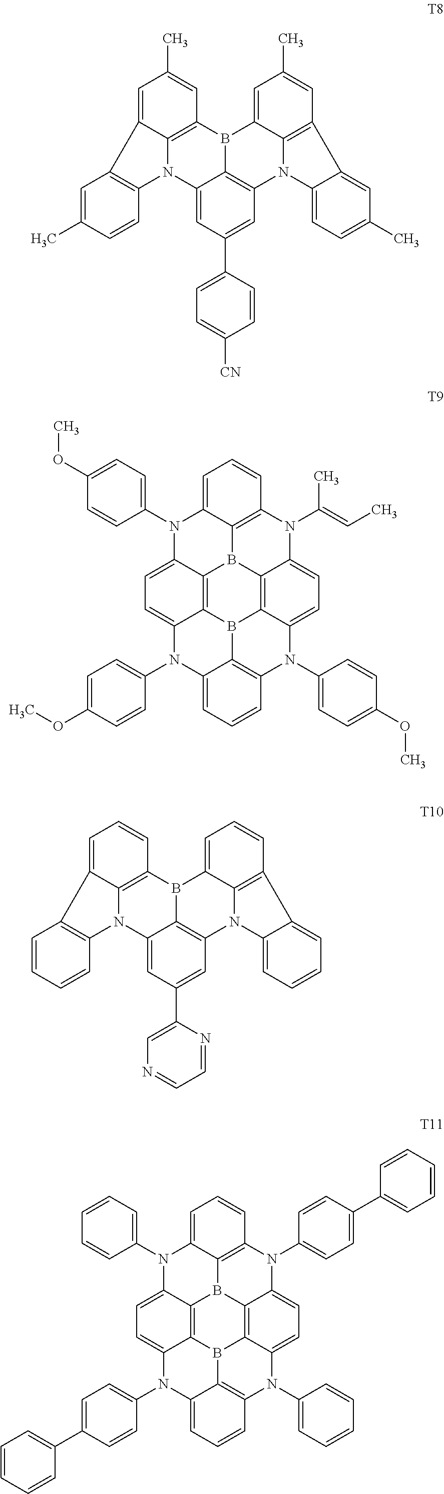

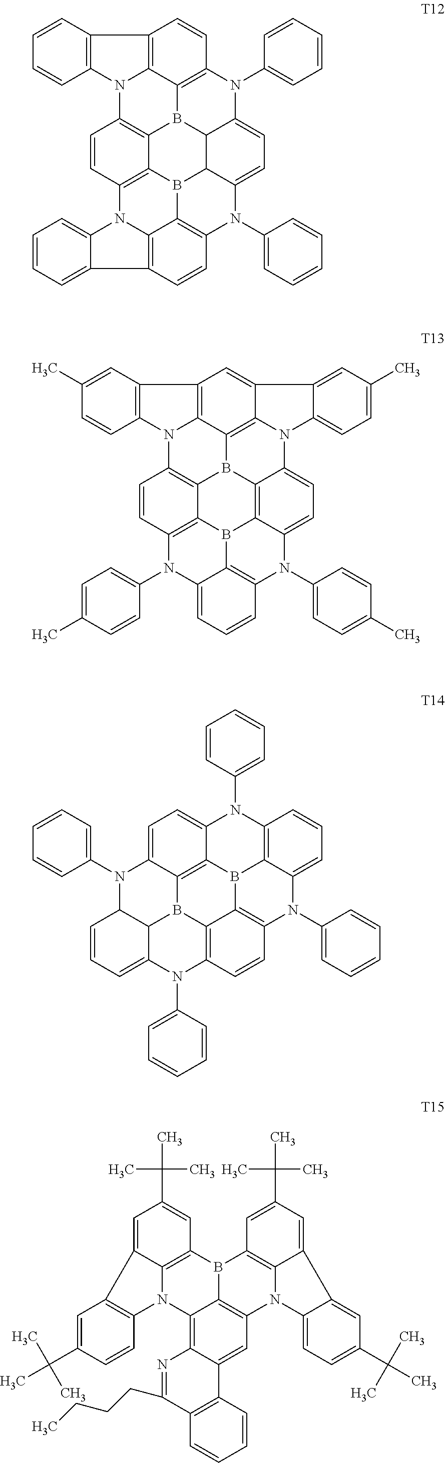

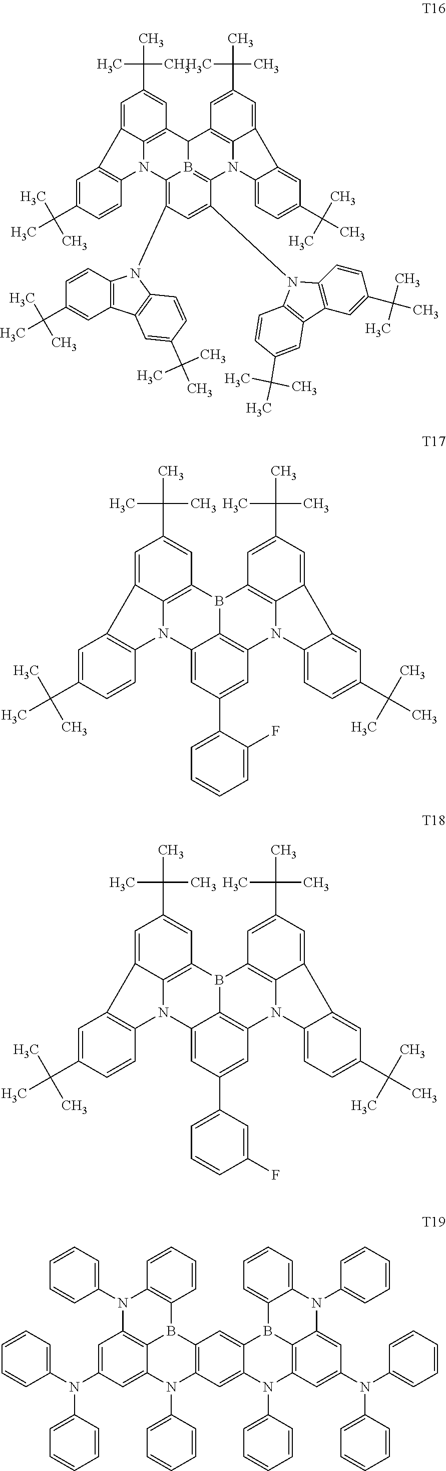

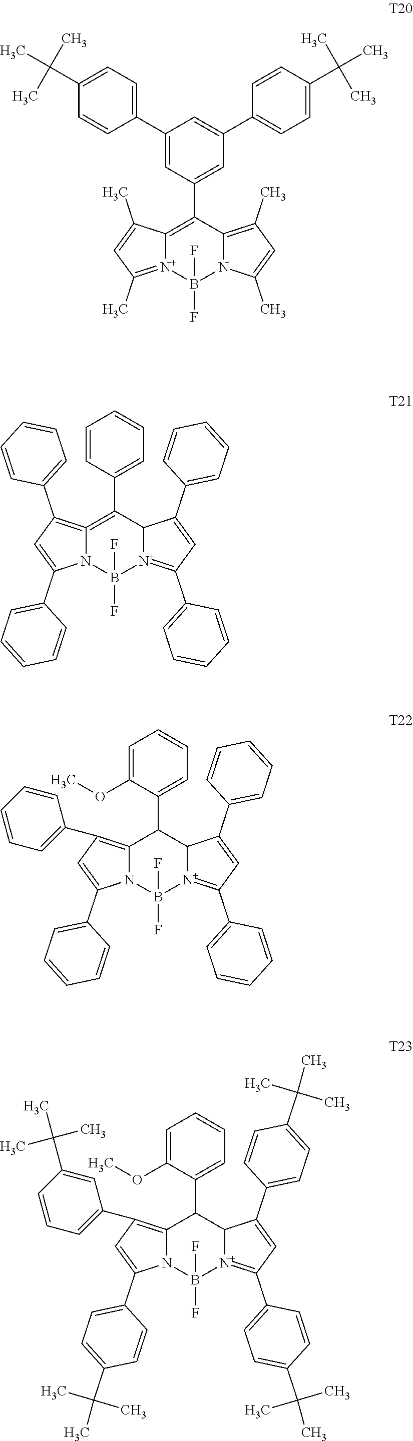

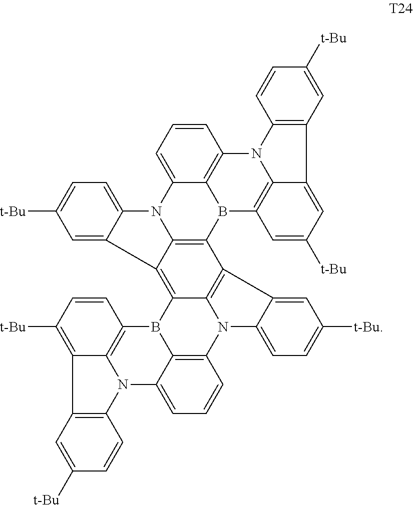 [SMILES: CC(C)(C)c1ccc2c(c1)c1cc(C(C)(C)C)cc3c1n2-c1cccc2c1B3c1c3c4cc(C(C)(C)C)ccc4n4c3c(c3c5cc(C(C)(C)C)ccc5n-2c13)B1c2c(cccc2-4)-n2c3ccc(C(C)(C)C)cc3c3c(C(C)(C)C)ccc1c32]

In one embodiment, the red light-emitting unit and/or the green light-emitting unit include, by mass percentage, 50%-90% of the host material, 9%-49% of the TADF sensitizing agent, and the balance of the narrow-spectrum boron-containing dye.

Further, the anode functional layer 0 of the organic electroluminescent device of the present application further includes a hole transport region 02. The hole transport region 02 is located between the anode layer 01 and the light-emitting layer, specifically, between the anode layer 01 and the first electron blocking layer. The hole transport region 02 may be a hole transport layer (HTL) with a single-layer structure, including a single-layer hole transport layer containing only one compound and a single-layer hole transport layer containing multiple compounds. The hole transport region 02 may also be in a two-layer structure including a hole injection layer (HIL) and a hole transport layer (HTL).

The material of the hole transport region 02 (including HIL and HTL) may be selected from the compounds shown for the red light electron blocking materials, the green light electron blocking materials and the blue light electron blocking materials mentioned above.

The hole injection layer is located between the anode layer 01 and the hole transport layer. The hole injection layer may be a single compound material or a combination of multiple compounds. For example, the hole injection layer may use one or more compounds of HT-1 to HT-34 mentioned above, or one or more compounds of HI1 to HI3 mentioned below; and also may use one or more compounds of HT-1 to HT-34 doped with one or more compounds of the following HI1 to HI3 may also be adopted. A thickness of the hole injection layer is generally 5 nm-30 nm, and a thickness of the hole transport layer is generally 5 nm-50 nm.

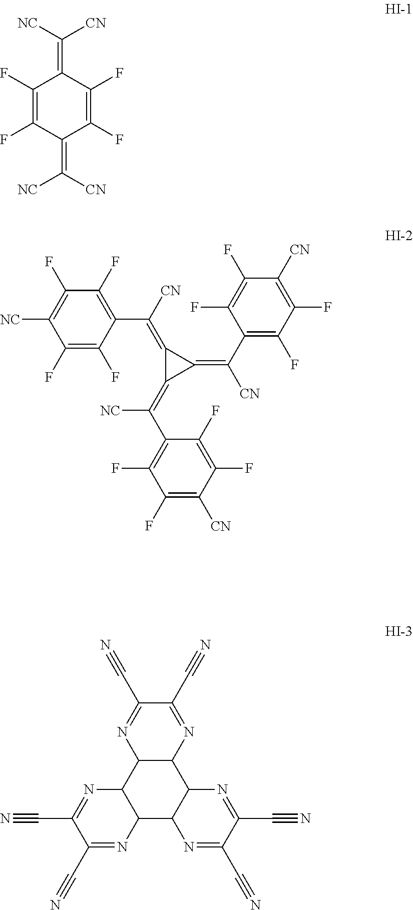 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The cathode functional layer 4 of the organic electroluminescent device of the present application further includes an electron transport region 42. The electron transport region 42 may be an electron transport layer (ETL) in a single-layer structure, and includes a single-layer electron transport layer containing only one compound and a single-layer electron transport layer containing multiple compounds. The electron transport region 42 may also be in a multilayer structure including at least two of an electron injection layer (EIL), an electron transport layer (ETL) and a hole blocking layer (HBL). Specifically, the electron transport region 42 is located between the light-emitting layer and the cathode layer 4.

The material of the electron transport layer may be selected from, but not limited to, one of ET-1 to ET-57 and PH-1 to PH-46 listed below, or a combination thereof. A thickness of the electron transport layer is generally 5 nm-50 nm.

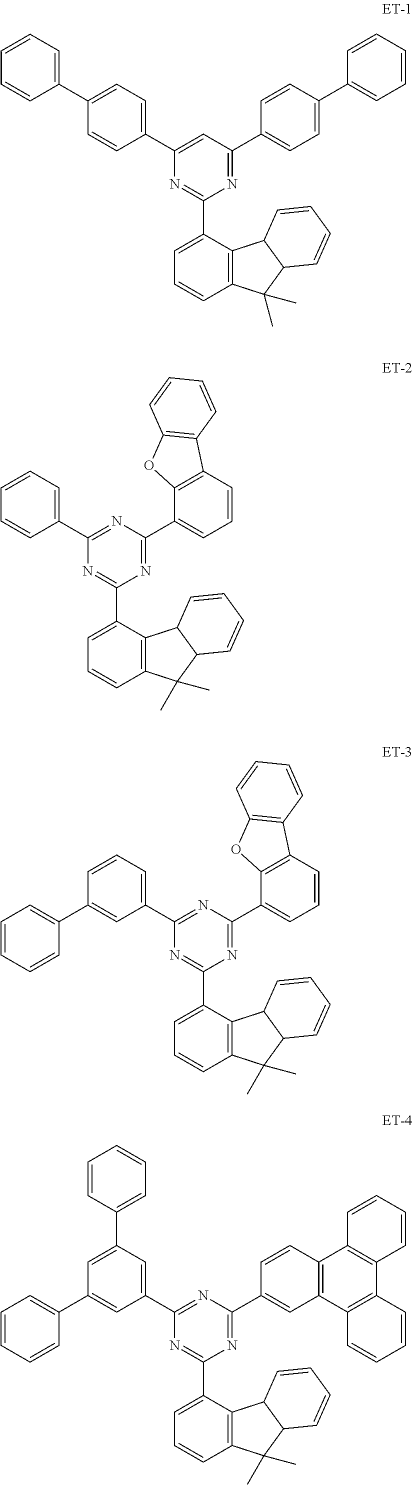 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21 ; CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21]

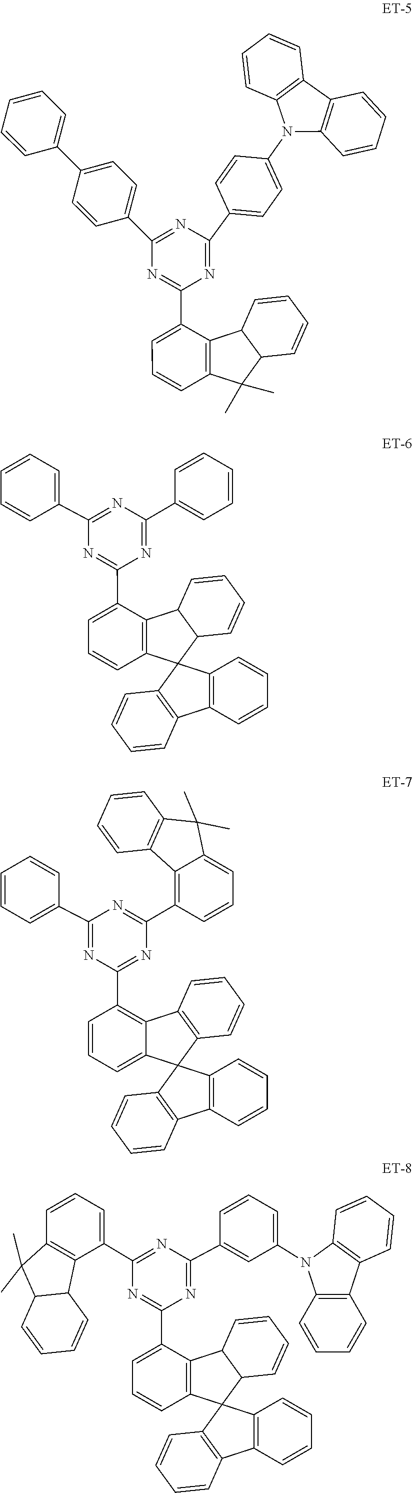

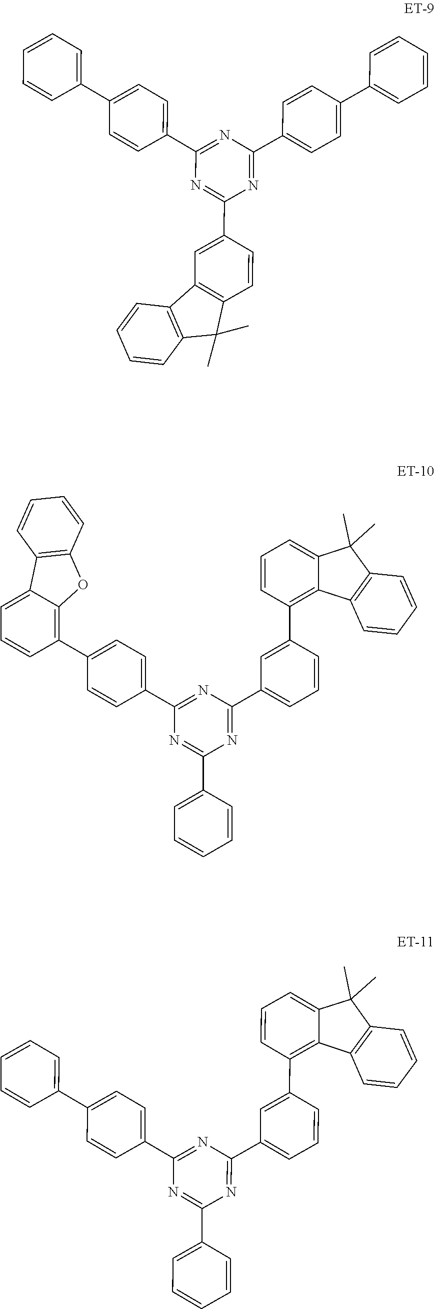 [SMILES: CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21 ; CC1(C)c2ccccc2-c2c(-c3cccc(-c4nc(-c5ccccc5)nc(-c5ccc(-c6ccccc6)cc5)n4)c3)cccc21]

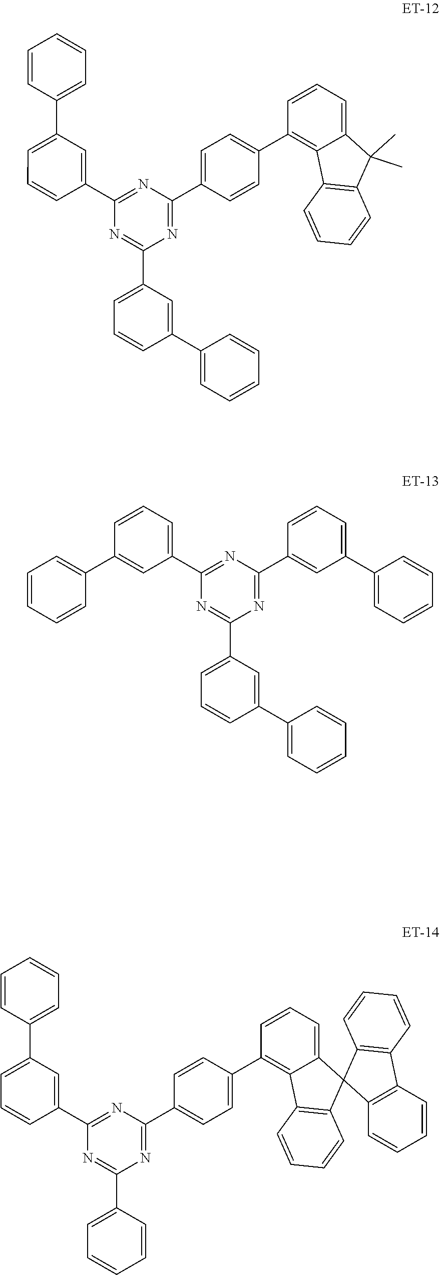 [SMILES: CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1]

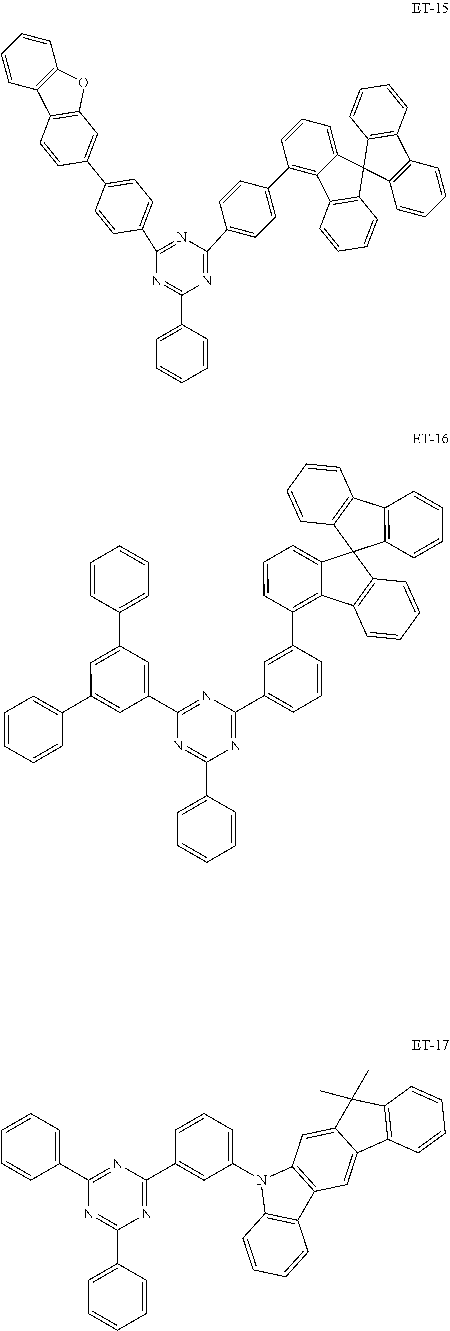 [SMILES: c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21]

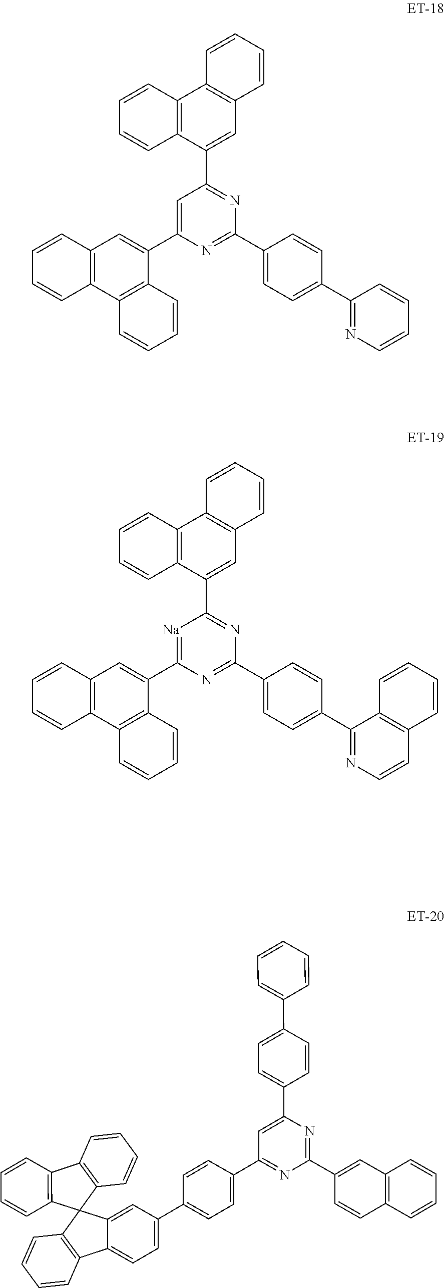

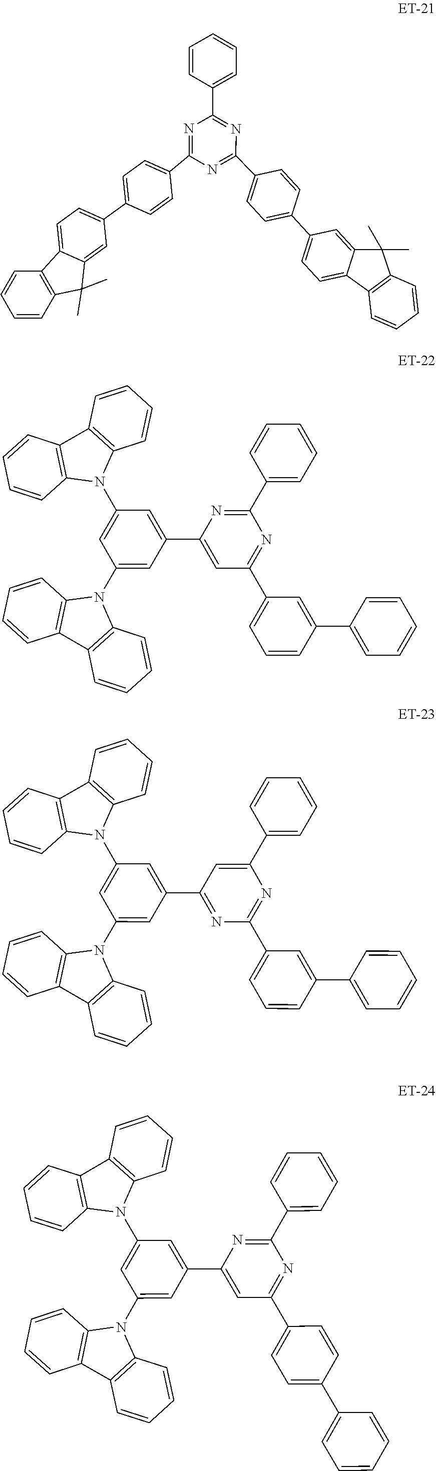

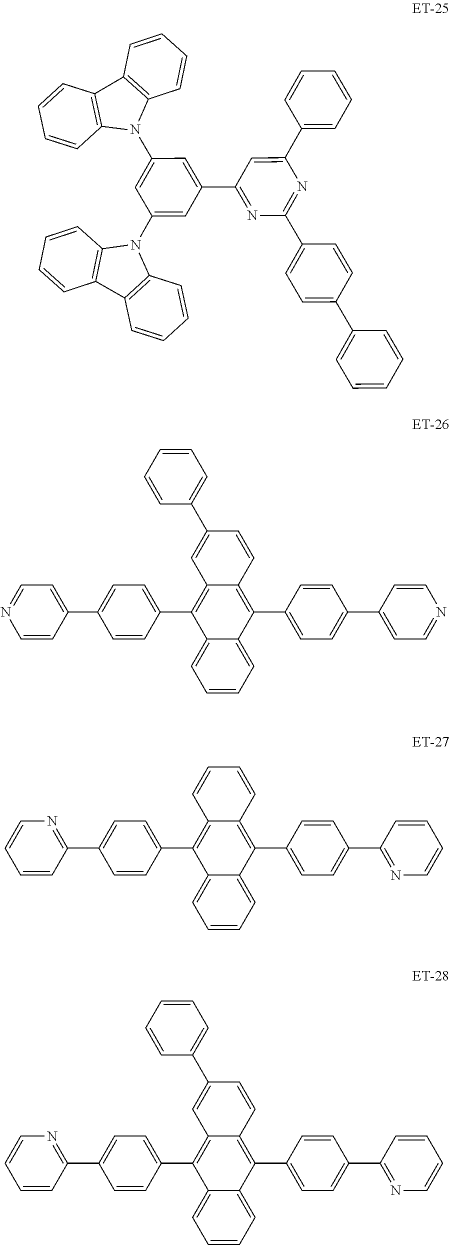 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1]

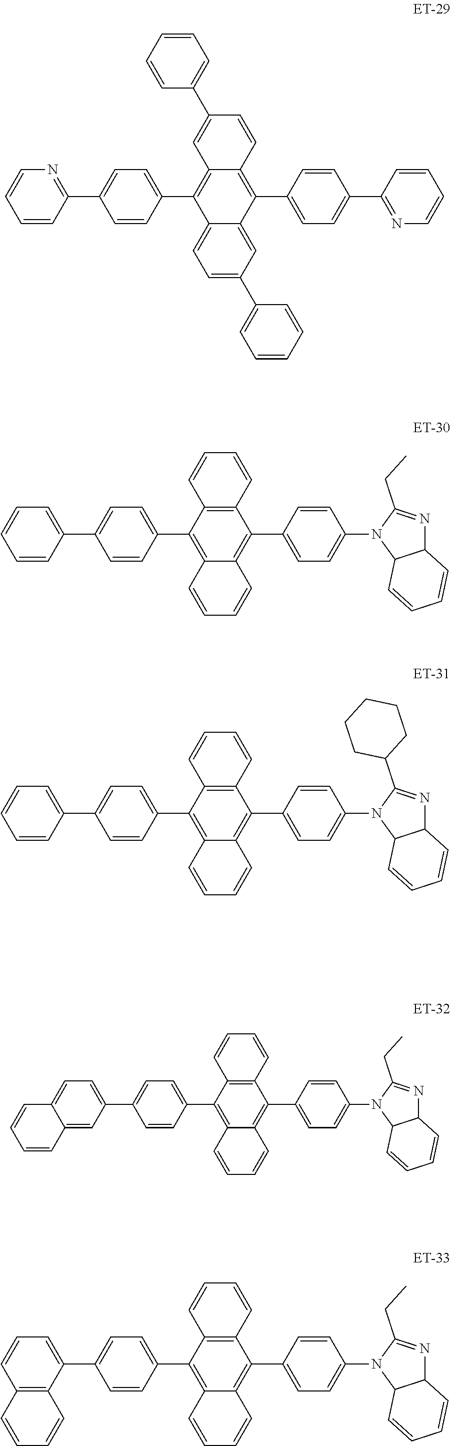 [SMILES: c1ccc(-c2ccc3c(-c4ccc(-c5ccccn5)cc4)c4cc(-c5ccccc5)ccc4c(-c4ccc(-c5ccccn5)cc4)c3c2)cc1 ; CCC1=NC2C=CC=CC2N1c1ccc(-c2c3ccccc3c(-c3ccc(-c4ccccc4)cc3)c3ccccc23)cc1 ; C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1 ; CCC1=NC2C=CC=CC2N1c1ccc(-c2c3ccccc3c(-c3ccc(-c4cccc5ccccc45)cc3)c3ccccc23)cc1]

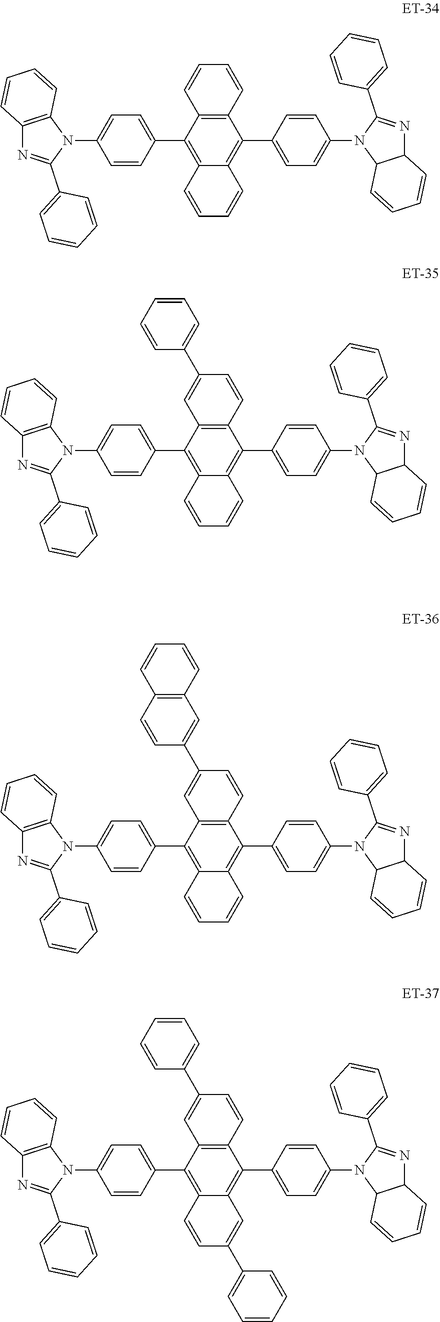 [SMILES: C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1]

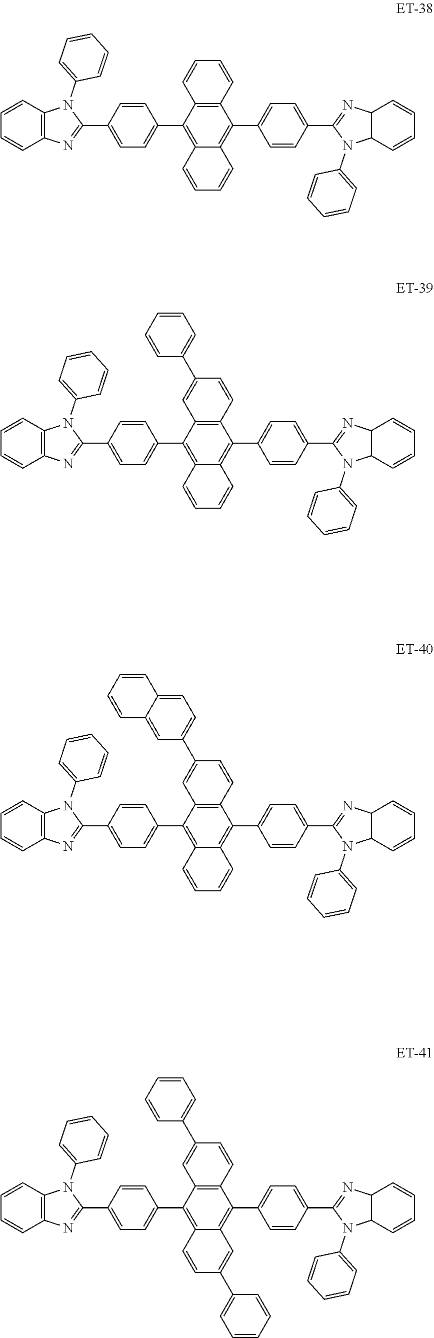 [SMILES: C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1]

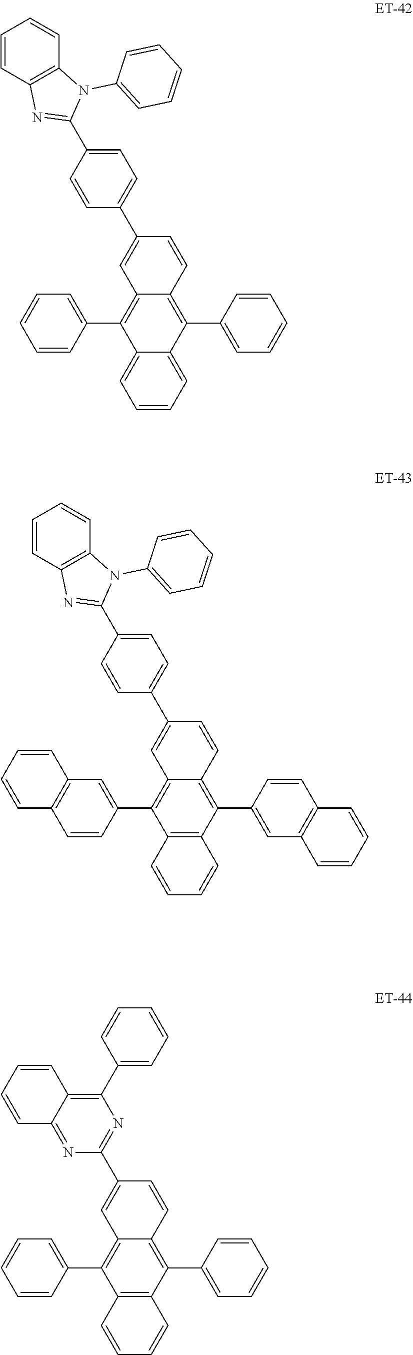 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccc4c(-c5ccccc5)c5ccccc5c(-c5ccccc5)c4c3)nc3ccccc23)cc1]

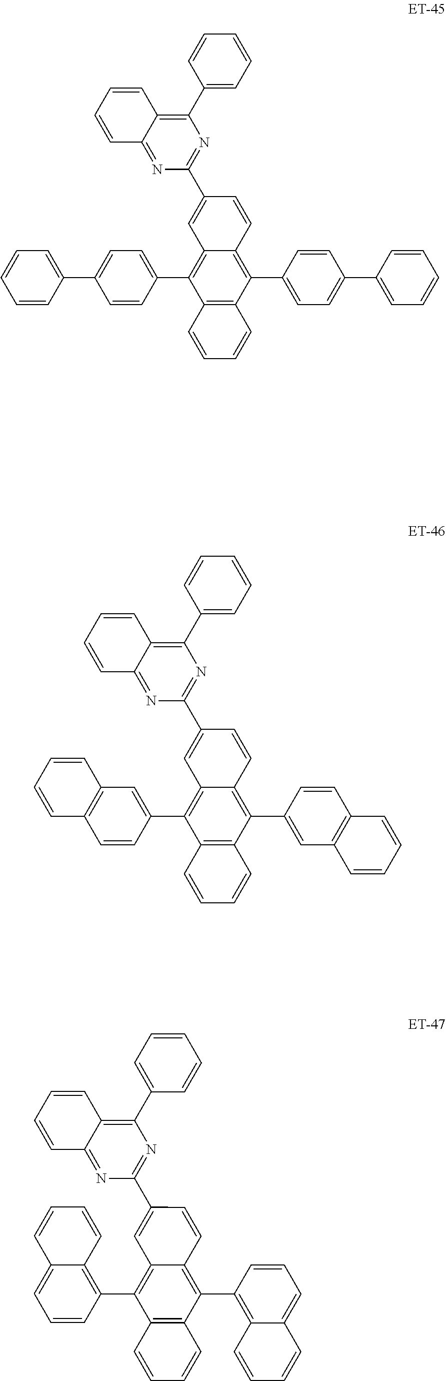 [SMILES: c1ccc(-c2ccc(-c3c4ccccc4c(-c4ccc(-c5ccccc5)cc4)c4cc(-c5nc(-c6ccccc6)c6ccccc6n5)ccc34)cc2)cc1 ; c1ccc(-c2nc(-c3ccc4c(-c5ccc6ccccc6c5)c5ccccc5c(-c5ccc6ccccc6c5)c4c3)nc3ccccc23)cc1 ; c1ccc(-c2nc(-c3ccc4c(-c5cccc6ccccc56)c5ccccc5c(-c5cccc6ccccc56)c4c3)nc3ccccc23)cc1]

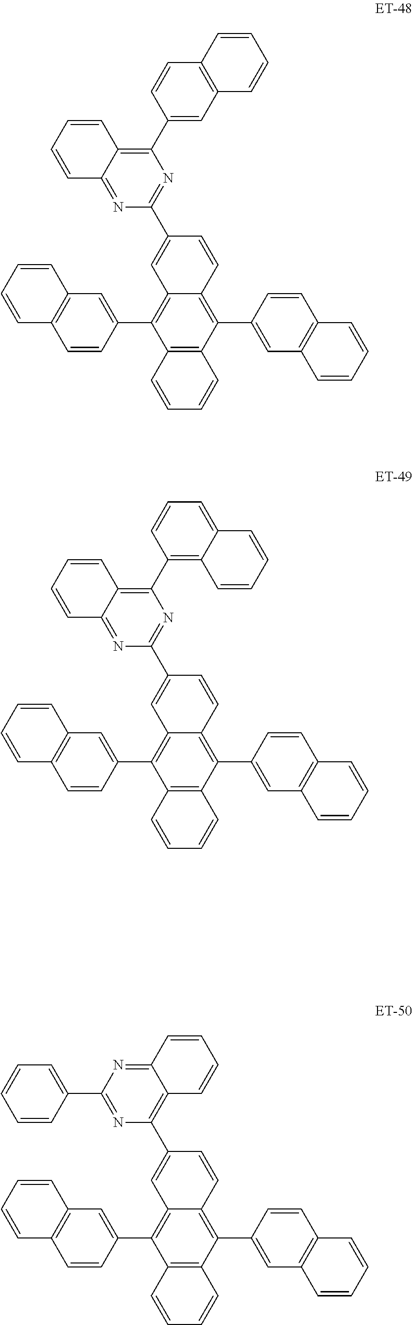 [SMILES: c1ccc2cc(-c3nc(-c4ccc5c(-c6ccc7ccccc7c6)c6ccccc6c(-c6ccc7ccccc7c6)c5c4)nc4ccccc34)ccc2c1 ; c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1]

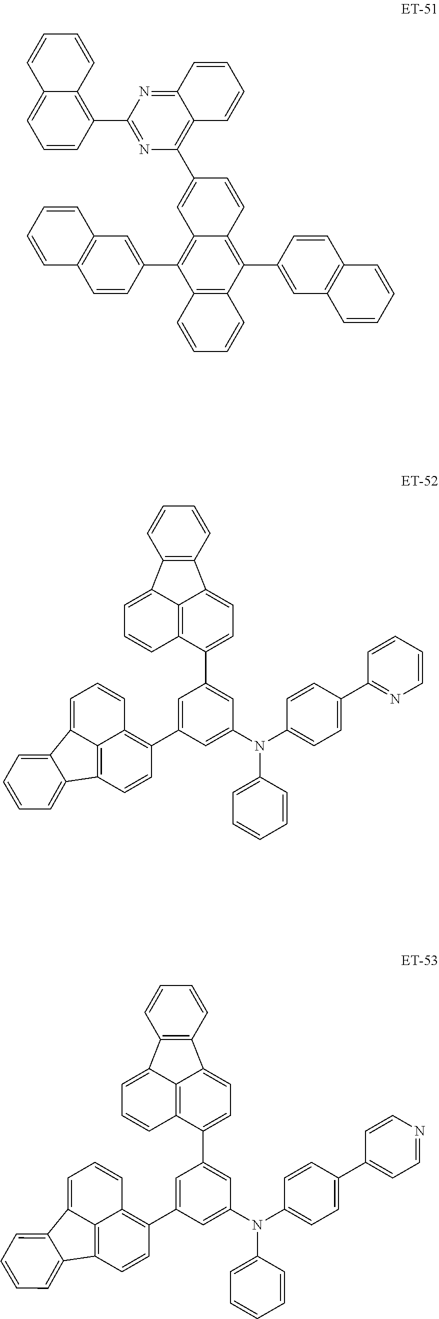 [SMILES: c1ccc2cc(-c3c4ccccc4c(-c4ccc5ccccc5c4)c4cc(-c5nc(-c6cccc7ccccc67)nc6ccccc56)ccc34)ccc2c1 ; c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1]

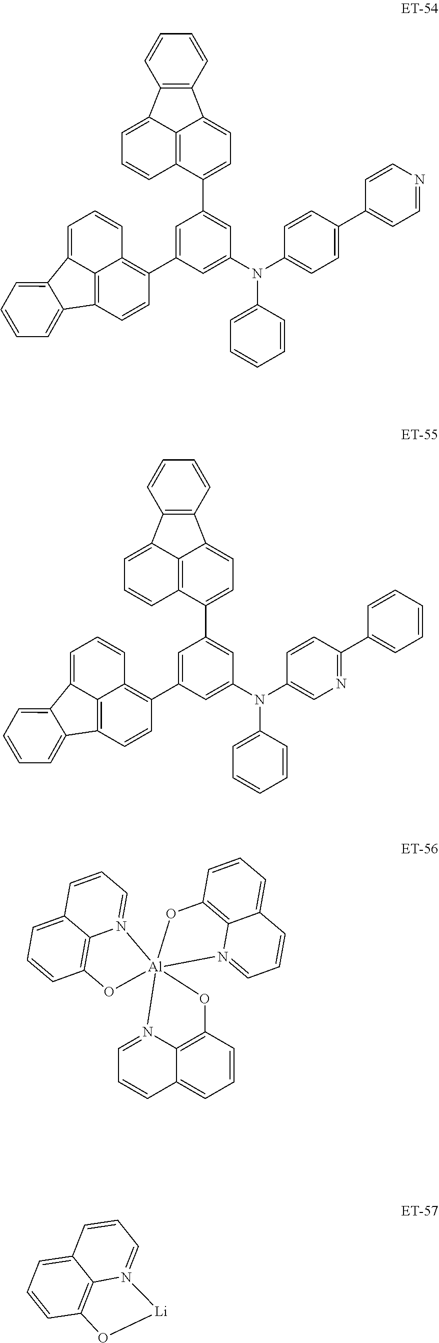

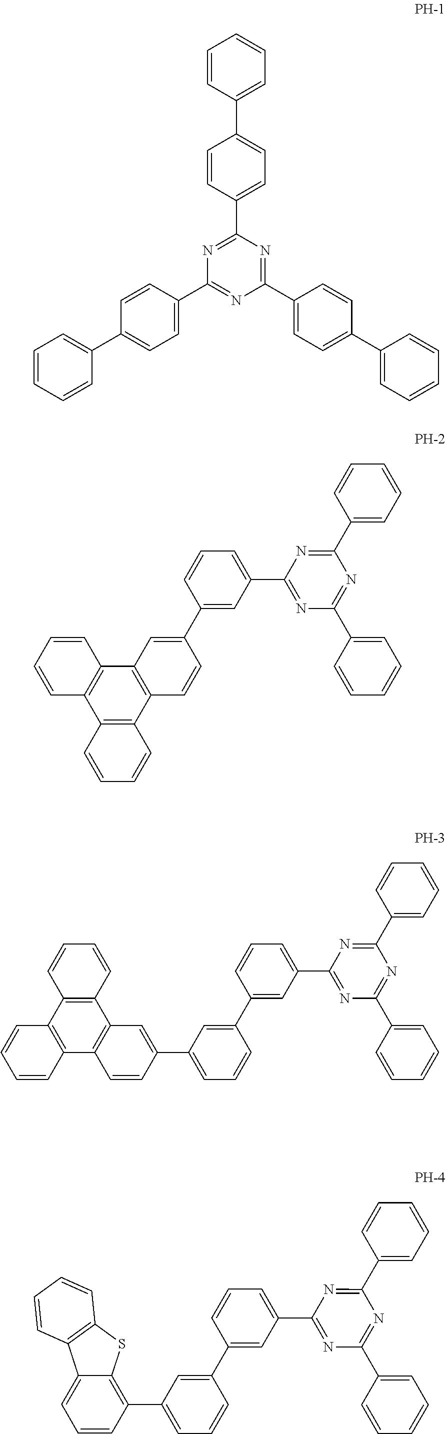 [SMILES: c1ccc(-c2ccc(-c3nc(-c4ccc(-c5ccccc5)cc4)nc(-c4ccc(-c5ccccc5)cc4)n3)cc2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4cccc(-c5cccc6c5sc5ccccc56)c4)c3)n2)cc1]

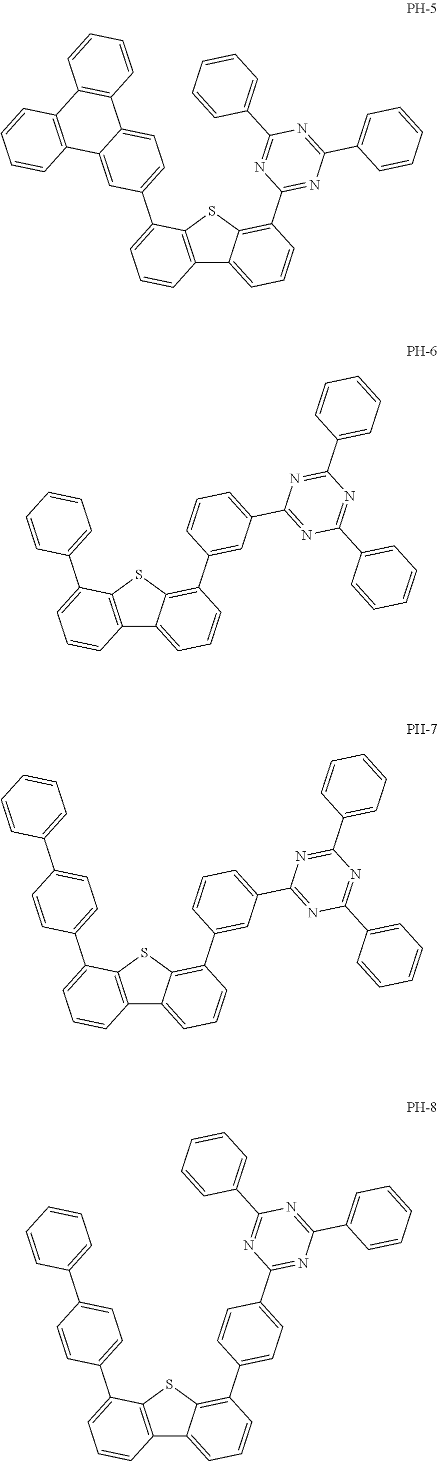 [SMILES: c1ccc(-c2nc(-c3ccccc3)nc(-c3cccc4c3sc3c(-c5ccc6c7ccccc7c7ccccc7c6c5)cccc34)n2)cc1 ; c1ccc(-c2nc(-c3ccccc3)nc(-c3cccc(-c4cccc5c4sc4c(-c6ccccc6)cccc45)c3)n2)cc1 ; c1ccc(-c2ccc(-c3cccc4c3sc3c(-c5cccc(-c6nc(-c7ccccc7)nc(-c7ccccc7)n6)c5)cccc34)cc2)cc1 ; c1ccc(-c2ccc(-c3cccc4c3sc3c(-c5ccc(-c6nc(-c7ccccc7)nc(-c7ccccc7)n6)cc5)cccc34)cc2)cc1]

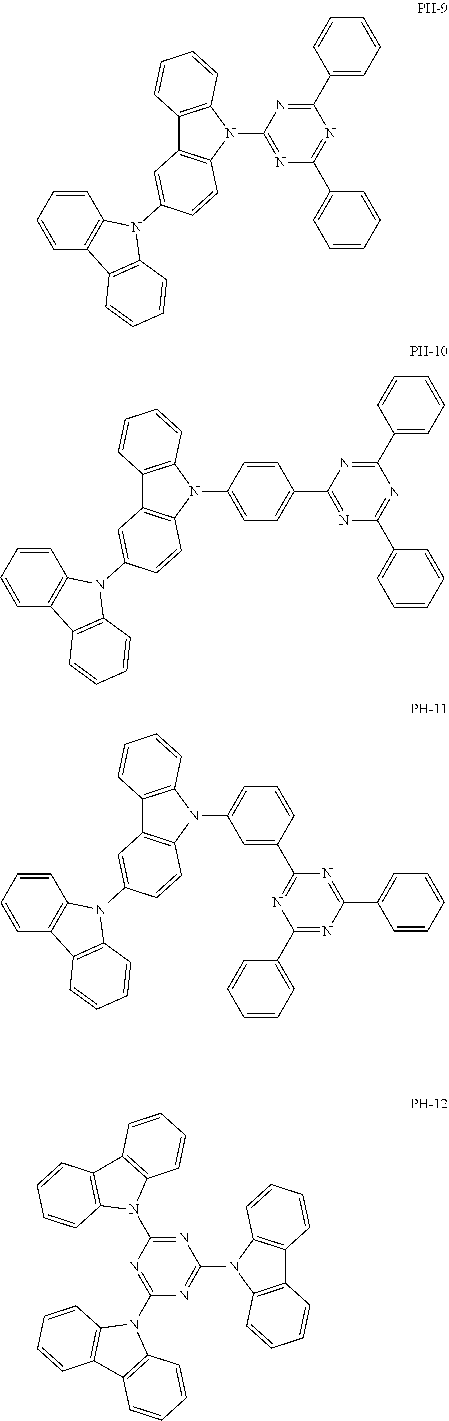 [SMILES: c1ccc(-c2nc(-c3ccccc3)nc(-n3c4ccccc4c4cc(-n5c6ccccc6c6ccccc65)ccc43)n2)cc1 ; c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1]

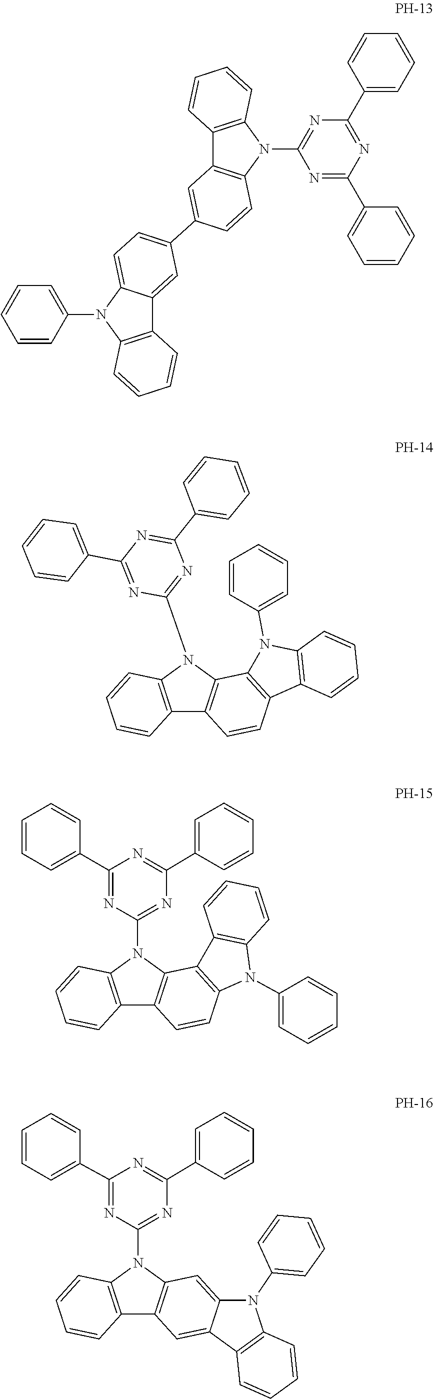 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1]

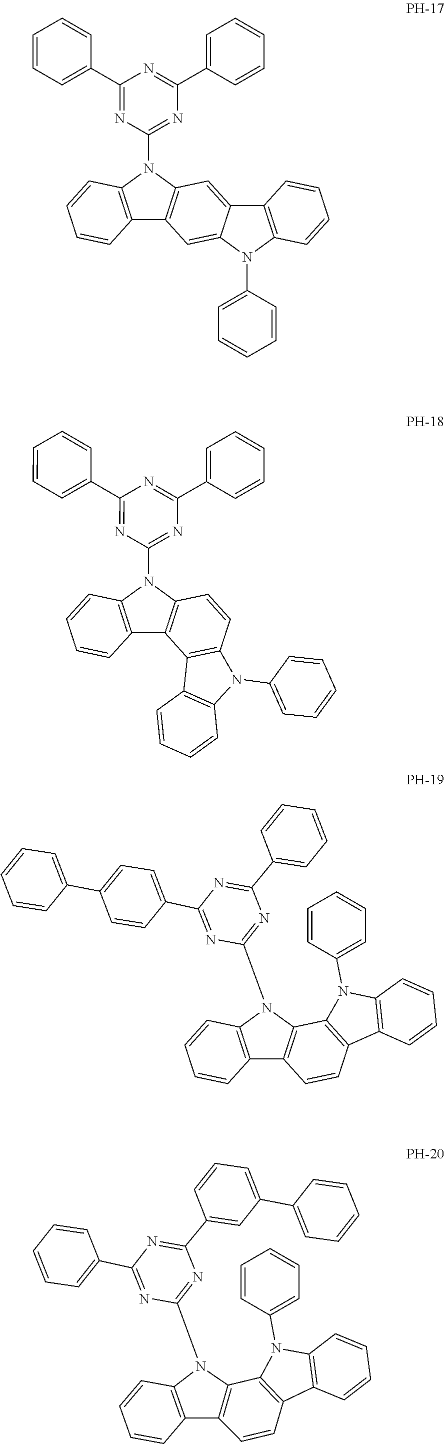 [SMILES: c1ccc(-c2nc(-c3ccccc3)nc(-n3c4ccccc4c4cc5c(cc43)c3ccccc3n5-c3ccccc3)n2)cc1 ; c1ccc(-c2nc(-c3ccccc3)nc(-n3c4ccccc4c4c5c6ccccc6n(-c6ccccc6)c5ccc43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2cccc(-c3nc(-c4ccccc4)nc(-n4c5ccccc5c5ccc6c7ccccc7n(-c7ccccc7)c6c54)n3)c2)cc1]

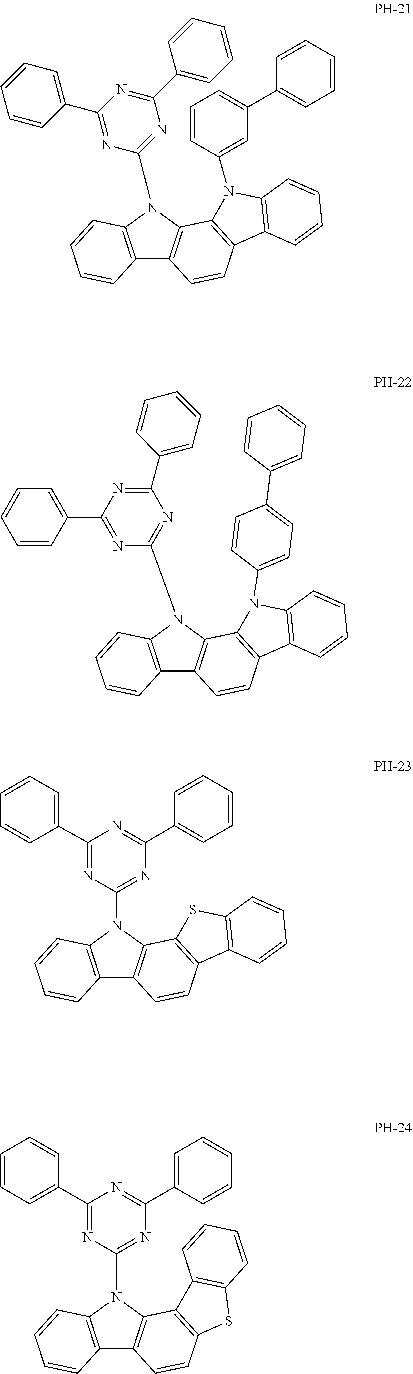 [SMILES: c1ccc(-c2cccc(-n3c4ccccc4c4ccc5c6ccccc6n(-c6nc(-c7ccccc7)nc(-c7ccccc7)n6)c5c43)c2)cc1 ; c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1]

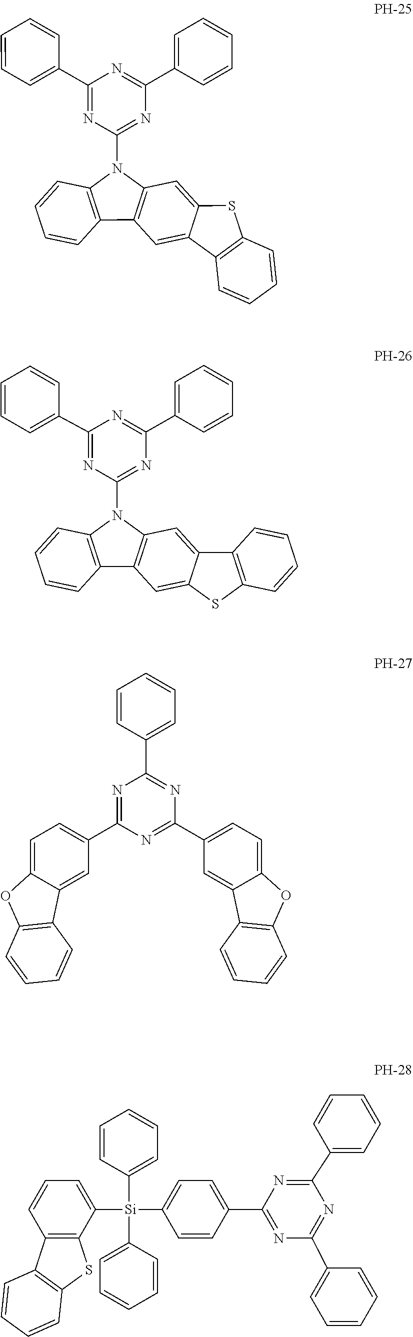 [SMILES: c1ccc(-c2nc(-c3ccccc3)nc(-n3c4ccccc4c4cc5c(cc43)sc3ccccc35)n2)cc1 ; c1ccc(-c2nc(-c3ccccc3)nc(-n3c4ccccc4c4cc5sc6ccccc6c5cc43)n2)cc1 ; c1ccc(-c2nc(-c3ccc4oc5ccccc5c4c3)nc(-c3ccc4oc5ccccc5c4c3)n2)cc1 ; c1ccc(-c2nc(-c3ccccc3)nc(-c3ccc([Si](c4ccccc4)(c4ccccc4)c4cccc5c4sc4ccccc45)cc3)n2)cc1]

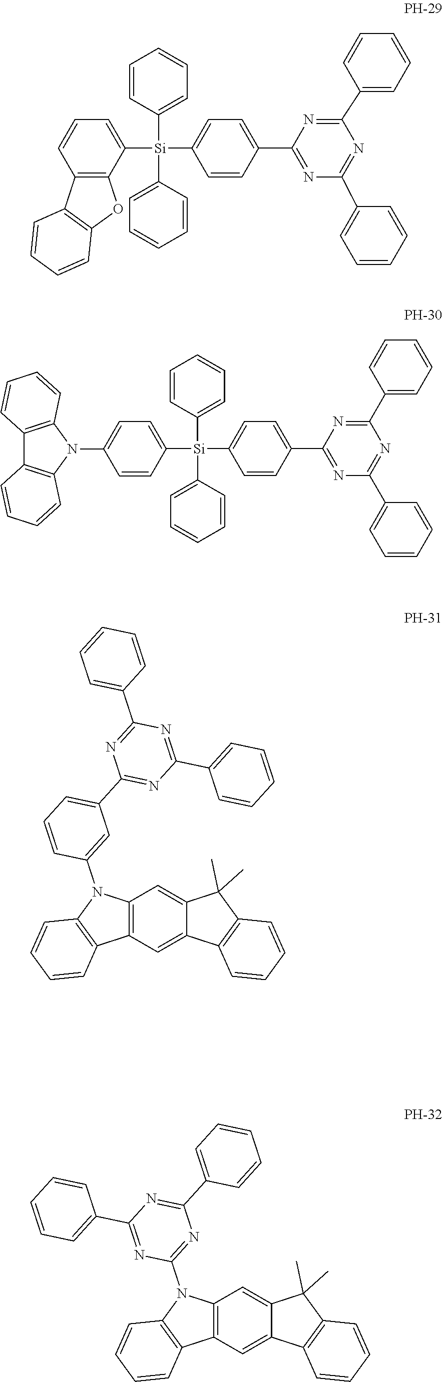 [SMILES: c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4ccccc4n(-c4nc(-c5ccccc5)nc(-c5ccccc5)n4)c3cc21]

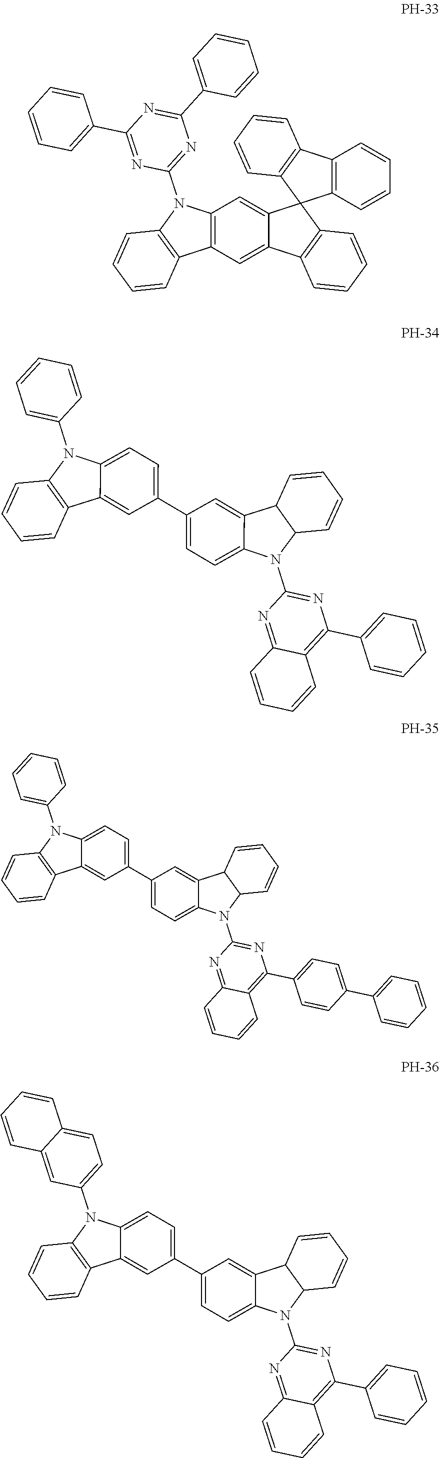 [SMILES: c1ccc(-c2nc(-c3ccccc3)nc(-n3c4ccccc4c4cc5c(cc43)C3(c4ccccc4-c4ccccc43)c3ccccc3-5)n2)cc1 ; C1=CC2c3cc(-c4ccc5c(c4)c4ccccc4n5-c4ccccc4)ccc3N(c3nc(-c4ccccc4)c4ccccc4n3)C2C=C1 ; C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1]

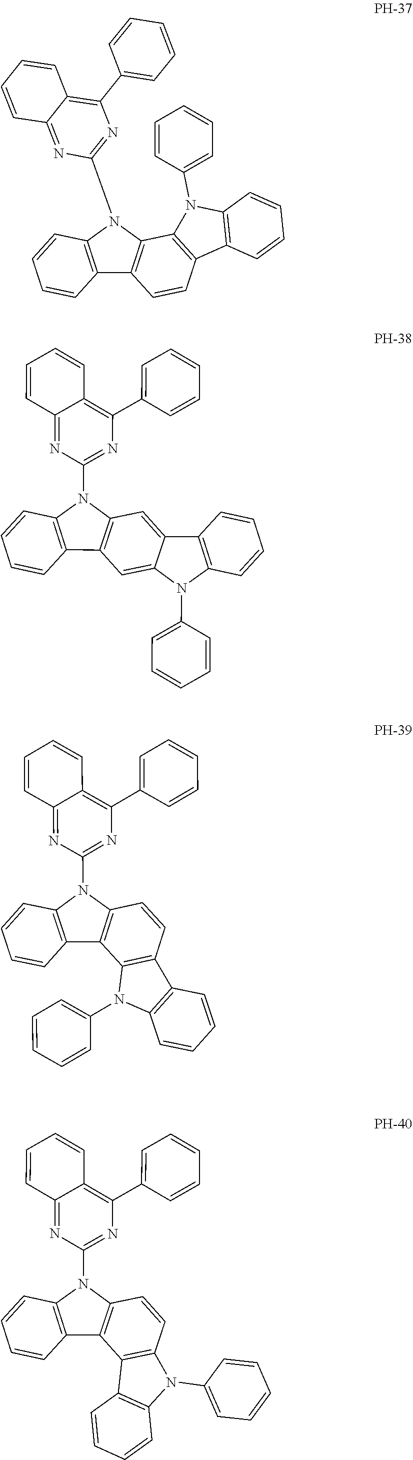 [SMILES: c1ccc(-c2nc(-n3c4ccccc4c4ccc5c6ccccc6n(-c6ccccc6)c5c43)nc3ccccc23)cc1 ; c1ccc(-c2nc(-n3c4ccccc4c4cc5c(cc43)c3ccccc3n5-c3ccccc3)nc3ccccc23)cc1 ; c1ccc(-c2nc(-n3c4ccccc4c4c3ccc3c5ccccc5n(-c5ccccc5)c34)nc3ccccc23)cc1 ; c1ccc(-c2nc(-n3c4ccccc4c4c5c6ccccc6n(-c6ccccc6)c5ccc43)nc3ccccc23)cc1]

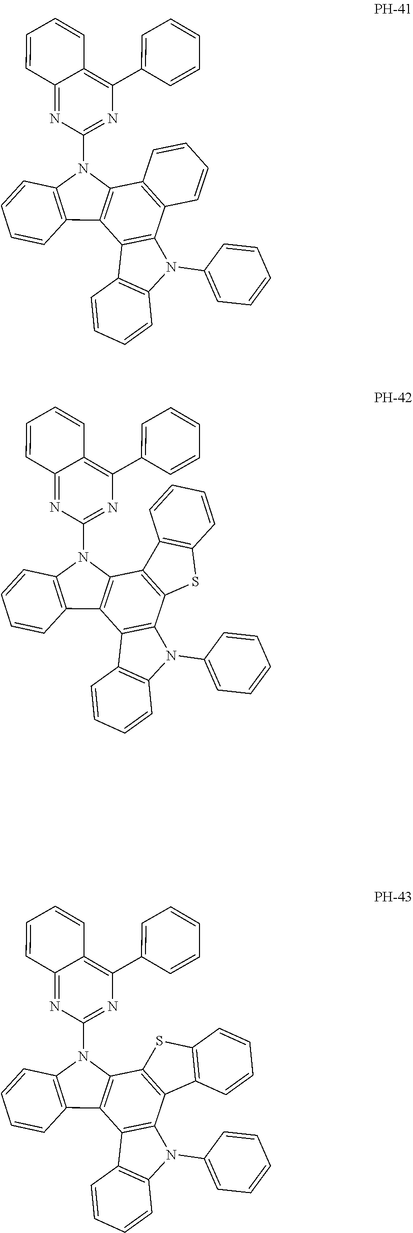 [SMILES: c1ccc(-c2nc(-n3c4ccccc4c4c5c6ccccc6n(-c6ccccc6)c5c5ccccc5c43)nc3ccccc23)cc1 ; c1ccc(-c2nc(-n3c4ccccc4c4c5c6ccccc6n(-c6ccccc6)c5c5sc6ccccc6c5c43)nc3ccccc23)cc1 ; c1ccc(-c2nc(-n3c4ccccc4c4c5c6ccccc6n(-c6ccccc6)c5c5c6ccccc6sc5c43)nc3ccccc23)cc1]

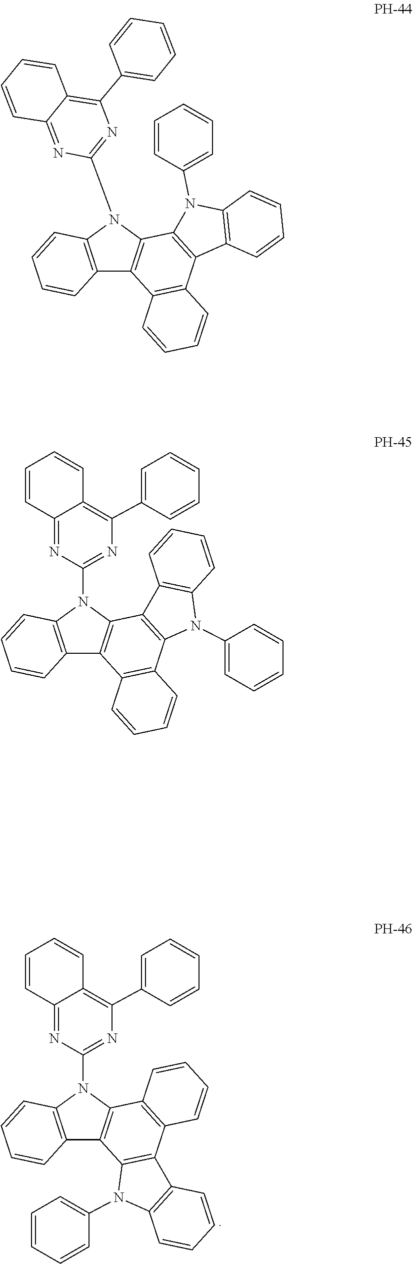 [SMILES: c1ccc(-c2nc(-n3c4ccccc4c4c5ccccc5c5c6ccccc6n(-c6ccccc6)c5c43)nc3ccccc23)cc1 ; c1ccc(-c2nc(-n3c4ccccc4c4c5ccccc5c5c(c6ccccc6n5-c5ccccc5)c43)nc3ccccc23)cc1 ; c1ccc(-c2nc(-n3c4ccccc4c4c3c3ccccc3c3c5ccccc5n(-c5ccccc5)c34)nc3ccccc23)cc1]

The structure of the light-emitting device may further include an electron injection layer located between the electron transport layer and the cathode layer 4, and the material of the electron injection layer includes, but is not limited to, one or a combination of a plurality of the following listed: LiQ, LiF, NaCl, CsF, Li₂O, Cs₂CO₃, BaO, Na, Li and Ca. A thickness of the electron injection layer is generally 0.5 nm-5 nm.

Further, the surface of the cathode functional layer 4 away from the anode functional layer 0 is also provided with a light extraction layer, thereby benefitting to realize a top light-emitting mode. The material of the light extraction layer is the same as that of the existing light extraction layer in the art, and it is not particularly limited in the present application.

The present application also provides a preparation method of the organic electroluminescent device, including sequentially depositing an anode functional layer, a first electron blocking layer, a second electron blocking layer, a light-emitting layer and a cathode functional layer on a substrate, and then packaging them. The deposition manners of the functional layers are the same as the existing manners in the art.

The embodiment of the present application also provides a display apparatus, which includes the organic electroluminescent device provided above. The display apparatus may be specifically a display device such as an organic light-emitting diode (OLED) display, and any product or component with a display function such as a television, a digital camera, a mobile phone and a tablet computer including the display device. The display apparatus has the same advantages as the above organic electroluminescent device compared with the prior art, and will not be repeated here.

In following, the organic electroluminescent device of the present application is described in detail through the specific examples.

### Examples 1-17

Examples 1 to 17 each provide an organic electroluminescent device, and the structure thereof is shown in FIG. 1, including an indium tin oxide (ITO) anode, a hole injection layer (HI-3, 5 nm), a hole transport layer (HT-2, 30 nm), a first electron blocking layer, a second electron blocking layer, a light-emitting layer and an electron transport layer (ET-34:ET-57, 1:1, 30 nm), an electron injection layer (LiF, 1 nm) and a cathode (Al, 1500 nm).

Where compositions of the first electron blocking layer, the second electron blocking layer and the light-emitting layer of each organic electroluminescent device are different, with specific compositions and thicknesses shown in Table 1.

### Comparative Examples 1-2

Comparative examples 1-2 provide an organic electroluminescent device, the structure thereof includes an ITO anode, a hole injection layer (HI-3, 5 nm), a hole transport layer (HT-2, 30 nm), a first electron blocking layer, a light-emitting layer, an electron transport layer (ET-34:ET-57, 1:1, 30 nm), an electron injection layer (LiF, 1 nm) and a cathode (Al, 1500 nm), which are sequentially laminated. The differences from Examples 1-17 are that the comparative examples only include the first electron blocking layer, and the first electron blocking layer includes a red light electron blocking layer, a green light electron blocking layer and a blue light electron blocking layer disposed side by side. The selection of specific materials is shown in Table 2.

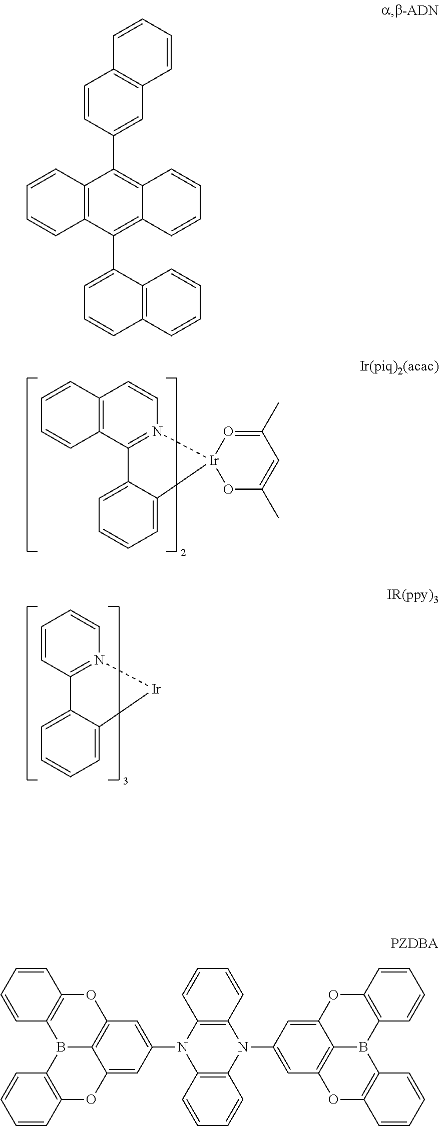

In Table 1 and Table 2, EBL-R represents the red light electron blocking layer, EBL-G represents the green light electron blocking layer and EBL-B represents the blue light electron blocking layer.

HOMO energy levels of all materials in the present application are obtained by measuring cyclic voltammetry (CV) curves of materials in solution at room temperature using Potentiostat/Galvanostat Model 283 electrochemical workstation from Princeton Applied Research Company, USA, where the concentration of the solution is 10⁻⁵ mol L⁻¹, platinum disk is used as a working electrode, a silver wire is used as a reference electrode and a platinum wire is used as a counter electrode.

When testing the HOMO energy level (EHOMO) of a material, ultra-dry dichloromethane was used as a solvent and tetra-n-butyl ammonium hexafluorophosphate was used as an electrolyte. The test rate is 100 mV s⁻¹. Before the test, high-purity nitrogen is used to remove oxygen for 10 minutes or more. After testing a redox potential of a sample, ferrocene, which is an internal standard substance, was added and its redox potential was tested. According to the relative value of potentials between the material and ferrocene, the HOMO energy level of the material is calculated by the following formula:

E_{HOMO}=−(4.8+Eox) eV

Where Eox represents the redox potential of the material with Fc⁺/Fc (ferrocene salt/ferrocene) as reference.

HOMO energy levels of some materials in Table 1 and Table 2 are as follows:
HT-2: −5.4 eV HT-11: −5.5 eV HT-35: −5.7 eV HT-36: −5.7 eV HT-37(w−1): −6.0 eV

The current density-voltage-brightness of examples and comparative examples were tested, and the results are shown in Table 3. Specifically, they is obtained by testing with Hamamatsu C9920-12 absolute electroluminescent quantum efficiency testing system (from JP) equipped with Keithley2400.

TABLE 1

| | | | | | Second electron | | | |
|---|---|---|---|---|---|---|---|---|
| | First electron blocking layer | | | | blocking layer | | Light-emitting layer | |
| | EBL-R | | EBL-G | | EBL-B | | Red light-emitting unit | |
| | | Thickness | | Thickness | | Thickness | | Thickness |
| Examples | Material | (nm) | Material | (nm) | Material | (nm) | Composition | (nm) |
| 1 | HT-11 | 20 | HT-11 | 20 | HT-35 | 10 | [symbol] T-70 (30%): T24 (1%) | 30 |
| 2 | HT-11 | 20 | HT-11 | 20 | HT-35 | 10 | [symbol] T-70 (30%): T24 (1%) | 30 |
| 3 | HT-11 | 20 | HT-11 | 20 | HT-35 | 10 | [symbol] | 30 |
| 4 | HT-11 | 20 | HT-11 | 20 | HT-35 | 10 | [symbol] T-70 (30%): T24 (1%) | 30 |
| 5 | HT-11 | 20 | HT-11 | 20 | HT-35 | 10 | [symbol] T-70 (30%): T24 (1%) | 30 |
| 6 | HT-11 | 20 | HT-11 | 20 | HT-36 | 10 | [symbol] T-70 (30%): T24 (1%) | 30 |
| 7 | HT-2 | 20 | HT-11 | 20 | HT-35 | 10 | [symbol] T-70 (30%): T24 (1%) | 30 |
| 8 | HT-2 | 20 | HT-11 | 20 | HT-37 | 10 | [symbol] T-70 (30%): T24 (1%) | 30 |
| 9 | HT-2 | 20 | HT-2 | 20 | HT-11 | 10 | [symbol] T-70 (30%): T24 (1%) | 30 |
| 10 | HT-11 | 20 | HT-11 | 20 | HT-35 | 15 | [symbol] T-70 (30%): T24 (1%) | 30 |
| 11 | HT-11 | 20 | HT-11 | 20 | HT-35 | 25 | [symbol] T-70 (30%): T24 (1%) | 30 |
| 12 | HT-11 | 30 | HT-11 | 30 | HT-35 | 10 | [symbol] T-70 (30%): T24 (1%) | 30 |
| 13 | HT-11 | 40 | HT-11 | 40 | HT-35 | 10 | [symbol] T-70 (30%): T24 (1%) | 30 |
| 14 | HT-11 | 20 | HT-11 | 20 | HT-35 | 10 | [symbol] T-70 (30%): T24 (1%) | 50 |
| 15 | HT-11 | 20 | HT-11 | 20 | HT-35 | 10 | [symbol] T-70 (30%): T24 (1%) | 30 |
| 16 | HT-11 | 20 | HT-11 | 20 | HT-35 | 10 | [symbol] T-70 (30%): T24 (1%) | 30 |
| 17 | HT-11 | 20 | HT-11 | 20 | HT-35 | 10 | [symbol] T-70 (30%): PZDBA (1%) | 30 |

| | Light-emitting layer | | | |
|---|---|---|---|---|
| | Green light-emitting unit | | Blue light-emitting unit | |
| | | Thickness | | Thickness |
| Examples | Composition | (nm) | Composition | (nm) |
| 1 | [symbol] T-69 (30%): T15 (1%) | 30 | α,β-ADN: T19 (2%) | 20 |
| 2 | [symbol] | 30 | α,β-ADN: T19 (2%) | 20 |
| 3 | [symbol] T-69 (30%): T15 (1%) | 30 | α,β-ADN: T19 (2%) | 20 |
| 4 | [symbol] T-89 (30%): T15 (1%) | 30 | α,β-ADN: T19 (2%) | 20 |
| 5 | [symbol] T-69 (30%): T20 (1%) | 30 | α,β-ADN: T19 (2%) | 20 |
| 6 | [symbol] T-69 (30%): T15 (1%) | 30 | α,β-ADN: T19 (2%) | 20 |
| 7 | [symbol] T-69 (30%): T15 (1%) | 30 | α,β-ADN: T19 (2%) | 20 |
| 8 | [symbol] T-69 (30%): T15 (1%) | 30 | α,β-ADN: T19 (2%) | 20 |
| 9 | [symbol] T-69 (30%): T15 (1%) | 30 | α,β-ADN: T19 (2%) | 20 |
| 10 | [symbol] T-69 (30%): T15 (1%) | 30 | α,β-ADN: T19 (2%) | 20 |
| 11 | [symbol] T-69 (30%): T15 (1%) | 30 | α,β-ADN: T19 (2%) | 20 |
| 12 | [symbol] T-69 (30%): T15 (1%) | 30 | α,β-ADN: T19 (2%) | 20 |
| 13 | [symbol] T-69 (30%): T15 (1%) | 30 | α,β-ADN: T19 (2%) | 20 |
| 14 | [symbol] T-69 (30%): T15 (1%) | 50 | α,β-ADN: T19 (2%) | 30 |
| 15 | [symbol] T-69 (30%): T15 (1%) | 30 | α,β-ADN: T19 (2%) | 20 |
| 16 | [symbol] T-69 (30%): T20 (1%) | 30 | α,β-ADN: T19 (2%) | 20 |
| 17 | [symbol] T-69 (30%): T15 (1%) | 30 | α,β-ADN: T19 (2%) | 20 |

[symbol]

indicates data missing or illegible when filed

TABLE 2

| | First electron blocking layer | | | | | | Light-emitting layer | |
|---|---|---|---|---|---|---|---|---|
| | EBL-R | | EBL-G | | EBL-B | | Red light-emitting unit | |
| Comparative | | Thickness | | Thickness | | Thickness | | Thickness |
| examples | Material | (nm) | Material | (nm) | Material | (nm) | Composition | (nm) |
| 1 | HT-11 | 30 | HT-11 | 30 | HT-35 | 10 | [symbol] T-70 (30%): T24(1%) | 30 |
| 2 | HT-2 | 30 | HT-2 | 30 | HT-35 | 10 | [symbol] T-70 (30%): T24(1%) | 30 |

| | Light-emitting layer | | | |
|---|---|---|---|---|
| | Green light-emitting unit | | Blue light-emitting unit | |
| Comparative | | Thickness | | Thickness |
| examples | Composition | (nm) | Composition | (nm) |
| 1 | [symbol] T-69 (30%): T15 (1%) | 30 | α,β-ADN: T19 (2%) | 20 |
| 2 | [symbol] T-69 (30%): T15 (1%) | 30 | α,β-ADN: T19 (2%) | 20 |

[symbol]

indicates data missing or illegible when filed

TABLE 3

| | Driving | | Driving | | Driving | |
|---|---|---|---|---|---|---|
| | voltage of | | voltage of | | voltage of | |
| | red light- | | green light- | | blue light- | |
| | emitting unit | Full-width | emitting unit | Full-width | emitting unit | Full-width |
| | @ 1000 nits | half-maximum | @1000 nits | half-maximum | @1000 nits | half-maximum |
| | (V) | (nm) | (V) | (nm) | (V) | (nm) |
| Example 1 | 4.6 | 45 | 4.3 | 38 | 4.1 | 23 |
| Example 2 | 4.6 | 45 | 4.0 | 87 | 4.1 | 23 |
| Example 3 | 4.3 | 96 | 4.3 | 38 | 4.1 | 23 |
| Example 4 | 4.6 | 45 | 4.2 | 38 | 4.1 | 23 |
| Example 5 | 4.6 | 45 | 4.2 | 38 | 4.1 | 23 |
| Example 6 | 4.7 | 45 | 4.5 | 38 | 4.3 | 23 |
| Example 7 | 4.7 | 45 | 4.3 | 38 | 4.1 | 23 |
| Example 8 | 4.9 | 45 | 4.5 | 38 | 4.4 | 23 |
| Example 9 | 4.8 | 45 | 4.5 | 38 | 4.2 | 23 |
| Example 10 | 4.7 | 45 | 4.4 | 38 | 4.2 | 23 |
| Example 11 | 4.9 | 45 | 4.6 | 38 | 4.4 | 23 |
| Example 12 | 4.6 | 45 | 4.3 | 38 | 4.1 | 23 |
| Example 13 | 4.7 | 45 | 4.4 | 38 | 4.2 | 23 |
| Example 14 | 4.8 | 45 | 4.5 | 38 | 4.3 | 23 |
| Example 15 | 4.6 | 45 | 4.3 | 41 | 4.1 | 23 |
| Example 16 | 4.6 | 45 | 4.1 | 33 | 4.1 | 23 |
| Example 17 | 4.8 | 103 | 4.3 | 38 | 4.1 | 23 |
| Comparative | 5.1 | 45 | 4.7 | 38 | 4.1 | 23 |
| Example 1 | | | | | | |
| Comparative | 5.3 | 45 | 5.0 | 38 | 4.1 | 3 |
| Example 2 | | | | | | |

It can be known from Table 3:
1. Compared with Comparative examples 1-2, Examples 1-17 of the present application adopt the organic electroluminescent device with a laminated structure of the first electron blocking layer and the second electron blocking layer, which is beneficial to overcome the defect that the driving voltage is too high caused by the TADF sensitizing agent contained in the red light-emitting unit or the green light-emitting unit;
2. Through the comparison between Example 1 and Example 2 (as well as the comparison between Example 1 and Example 3), it can be known that even if only one of the red light-emitting unit and the green light-emitting unit contains the TADF sensitizing agent, the arrangement manner of the laminated structure of the first electron blocking layer and the second electron blocking layer in the present application does not have a negative impact on the driving voltage of the device;
3. Through the comparison between Examples 1-7 and 8-9, it can be known that the driving voltage of the organic electroluminescent device may be further reduced by selecting the materials of the first electron blocking layer and the second electron blocking layer and the host material of the light-emitting unit, which have more matching HOMO energy levels therebetween;
4. Through the comparison between Examples 1, 10 and 11, it can be known that when the thickness of the second electron blocking layer is more than 20 nm, the driving voltage of the organic electroluminescent device may obviously increase with the increase of the thickness, so in a practical application, it is preferable that the thickness of the second electron blocking layer does not exceed 20 nm;
5. Through the comparison between Examples 1, 12 and 13, it can be known that even if the thicknesses of the red light electron blocking layer and the green light electron blocking layer are increased, the increased the thickness has little influence on the driving voltage of the organic electroluminescent device due to excellent hole transport ability of the red light electron blocking layer and the green light electron blocking layer, so in a specific application, the thicknesses of the red light electron blocking layer and the green light electron blocking layer may be adjusted according to the requirement of the optical path;
6. Through the comparison between Examples 1 and 14, it can be known that when the thicknesses of the red light-emitting unit, the green light-emitting unit and the blue light-emitting unit are increased, the improvement effect of the driving voltage of the organic electroluminescent device is decreased obviously, so in a practical application, it is preferable that the thicknesses of the red light-emitting unit and the green light-emitting unit do not exceed 50 nm and the thickness of the blue light-emitting unit does not exceed 30 nm;
7. According to Examples 1, 15, 16 and 17, it can be known that the full-width half-maximum of the organic electroluminescent device may be adjusted by adjusting the dyes in the light-emitting layer, and especially when the narrow-spectrum boron-containing dye is used, the full-width half maximum of the organic electroluminescent device is narrower, which is more beneficial to the improvement of color purity.

Finally, it should be explained that the above examples are only used to illustrate the technical solutions of the present application, but not to limit them; although the present application has been described in detail with reference to the foregoing examples, it should be understood by those skilled in the art that the technical solutions described in the foregoing examples can still be modified, or some or all of technical features therein may be replaced equivalently; however, these modifications or substitutions do not make the essence of the corresponding technical solutions deviate from the scope of the technical solutions of various examples of the present application.

What is claimed is:

1. An organic electroluminescent device, comprising:
an anode functional layer, a first electron blocking layer, a second electron blocking layer, a light-emitting layer, and a cathode functional layer, wherein the anode functional layer comprises a first region and a second region which are disposed adjacent to each other, the first electron blocking layer is disposed in the first region of the anode functional layer, the second electron blocking layer is disposed in the second region of the anode functional layer and on a side of the first electron blocking layer away from the anode functional layer, the light-emitting layer is disposed on a side of the second electron blocking layer away from the anode functional layer, and the cathode functional layer is disposed on a side of the light-emitting layer away from the anode functional layer;
the anode functional layer at least comprises an anode layer, and the cathode functional layer at least comprises a cathode layer;
the first electron blocking layer comprises a red light electron blocking layer and a green light electron blocking layer, which are disposed side by side, and the second electron blocking layer is a blue light electron blocking layer;
the light-emitting layer comprises a red light-emitting unit, a green light-emitting unit and a blue light-emitting unit, which are disposed side by side, and at least one of the red light-emitting unit and the green light-emitting unit comprises a host material, a thermally activated delayed fluorescence (TADF) sensitizing agent and a narrow-spectrum boron-containing dye;
the red light electron blocking layer and the red light-emitting unit are provided correspondingly in a laminated manner, and the green light electron blocking layer and the green light-emitting unit are provided correspondingly in a laminated manner; and
HOMO_{R} of a red light electron blocking material in the red light electron blocking layer, HOMO_{G} of a green light electron blocking material in the green light electron blocking layer and HOMO_{B} of a blue light electron blocking material in the blue light electron blocking layer meet the following requirements:
HOMO_{B}<HOMO_{R}, HOMO_{B}<HOMO_{G}, and HOMO_{G}≤HOMO_{R},
wherein HOMO_{R} is a highest occupied molecular orbital energy level of the red light electron blocking material in the red light electron blocking layer, HOMO_{G} is a highest occupied molecular orbital energy level of the green light electron blocking material in the green light electron blocking layer, and HOMO_{B} is a highest occupied molecular orbital energy level of the blue light electron blocking material in the blue light electron blocking layer.

2. The organic electroluminescent device according to claim 1, wherein an orthographic projection of a (N+1)th functional layer on a plane where the anode functional layer is located covers an orthographic projection of a Nth functional layer on the plane where the anode functional layer is located, wherein in a laminated direction, the (N+1)th functional layer is farther from the anode functional layer than the Nth functional layer; and
the functional layers are selected from one of the anode functional layer, the first electron blocking layer, the second electron blocking layer, the light-emitting layer and the cathode functional layer.

3. The organic electroluminescent device according to claim 1, wherein HOMO_{R}, HOMO_{G} and HOMO_{R} meet the following requirements: 0<HOMO_{R}−HOMO_{B}≤0.4 eV, and/or, 0<HOMO_{G}−HOMO_{B}≤0.4 eV.

4. The organic electroluminescent device according to claim 2, wherein HOMO_{R}, HOMO_{G} and HOMO_{R} meet the following requirements: 0<HOMO_{R}−HOMO_{B}≤0.4 eV, and/or, 0<HOMO_{G}−HOMO_{B}≤0.4 eV.

5. The organic electroluminescent device according to claim 3, wherein HOMO_{RH} of the host material in the red light-emitting unit, HOMO_{GH} of the host material in the green light-emitting unit and HOMO_{B} meet the following requirements: HOMO_{B}−HOMO_{RH}≤0.4 eV, and/or, HOMO_{B}−HOMO_{GH}≤0.4 eV, and
wherein HOMO_{RH} is a highest occupied molecular orbital energy level of the host material in the red light-emitting unit, and HOMO_{GH} is a highest occupied molecular orbital energy level of the host material in the green light-emitting unit.

6. The organic electroluminescent device according to claim 1, wherein a thickness of the blue light electron blocking layer is less than or equal to 20 nm.

7. The organic electroluminescent device according to claim 2, wherein a thickness of the blue light electron blocking layer is less than or equal to 20 nm.

8. The organic electroluminescent device according to claim 6, wherein a thickness of the red light electron blocking layer is greater than or equal to 20 nm, and/or, a thickness of the green light electron blocking layer is greater than or equal to 20 nm.

9. The organic electroluminescent device according to claim 1, wherein a thickness of at least one of the red light-emitting unit and the green light-emitting unit is less than or equal to 50 nm; and/or, a thickness of the blue light-emitting unit is less than or equal to 30 nm.

10. The organic electroluminescent device according to claim 2, wherein a thickness of at least one of the red light-emitting unit and the green light-emitting unit is less than or equal to 50 nm; and/or, a thickness of the blue light-emitting unit is less than or equal to 30 nm.

11. The organic electroluminescent device according to claim 9, wherein, among the red light-emitting unit, the green light-emitting unit and the blue light-emitting unit, any two adjacent light-emitting units have different thicknesses.

12. The organic electroluminescent device according to claim 1, wherein the blue light-emitting unit comprises a triplet-triplet annihilation (TTA) host material and a dye.

13. The organic electroluminescent device according to claim 1, wherein the narrow-spectrum boron-containing dye contains boron atoms, and a full-width half-maximum of the narrow-spectrum boron-containing dye in toluene solution is less than 80 nm.

14. The organic electroluminescent device according to claim 13, wherein the narrow-spectrum boron-containing dye is selected from compounds having one of the following structures and derivatives thereof:

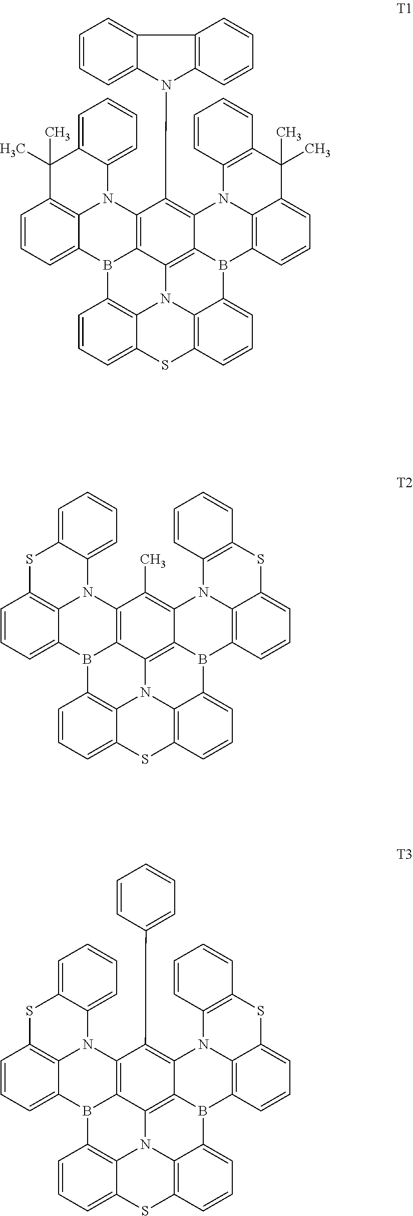 [SMILES: CC1(C)c2ccccc2N2c3c(cccc31)B1c3cccc4c3N3c5c(cccc5B5c6cccc7c6N(c6ccccc6C7(C)C)c6c5c3c1c2c6-n1c2ccccc2c2ccccc21)S4 ; Cc1c2c3c4c5c1N1c6ccccc6Sc6cccc(c61)B5c1cccc5c1N4c1c(cccc1B3c1cccc3c1N2c1ccccc1S3)S5 ; c1ccc(-c2c3c4c5c6c2N2c7ccccc7Sc7cccc(c72)B6c2cccc6c2N5c2c(cccc2B4c2cccc4c2N3c2ccccc2S4)S6)cc1]

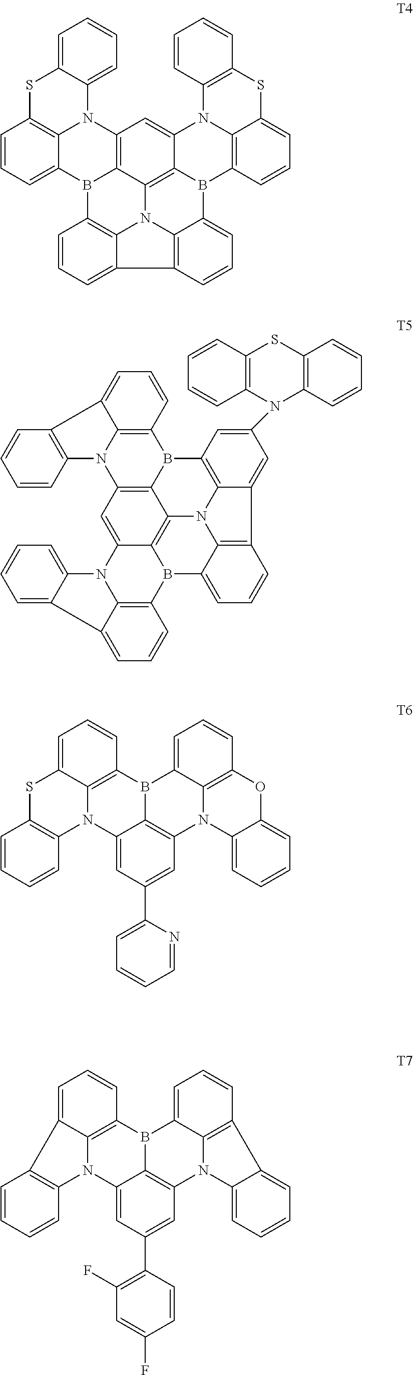 [SMILES: c1ccc2c(c1)Sc1cccc3c1N2c1cc2c4c5c1B3c1cccc3c6cccc(c6n-5c13)B4c1cccc3c1N2c1ccccc1S3 ; c1ccc2c(c1)Sc1ccccc1N2c1cc2c3c(c1)c1cccc4c1n3-c1c3c(cc5c1B2c1cccc2c6ccccc6n-5c12)-n1c2ccccc2c2cccc(c21)B34 ; c1ccc(-c2cc3c4c(c2)N2c5ccccc5Sc5cccc(c52)B4c2cccc4c2N3c2ccccc2O4)nc1 ; Fc1ccc(-c2cc3c4c(c2)-n2c5ccccc5c5cccc(c52)B4c2cccc4c5ccccc5n-3c24)c(F)c1]

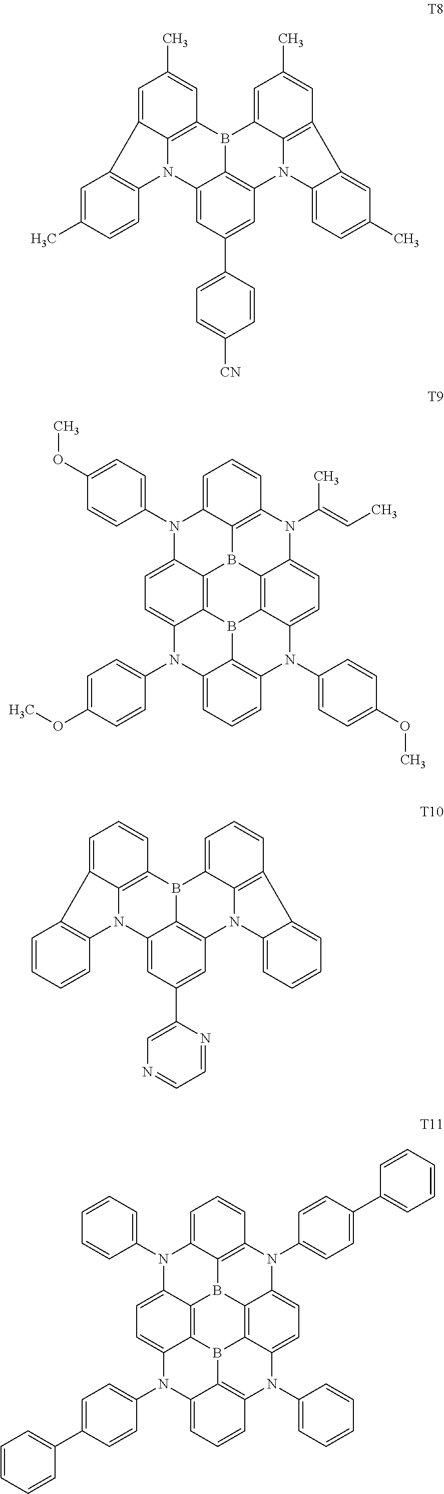

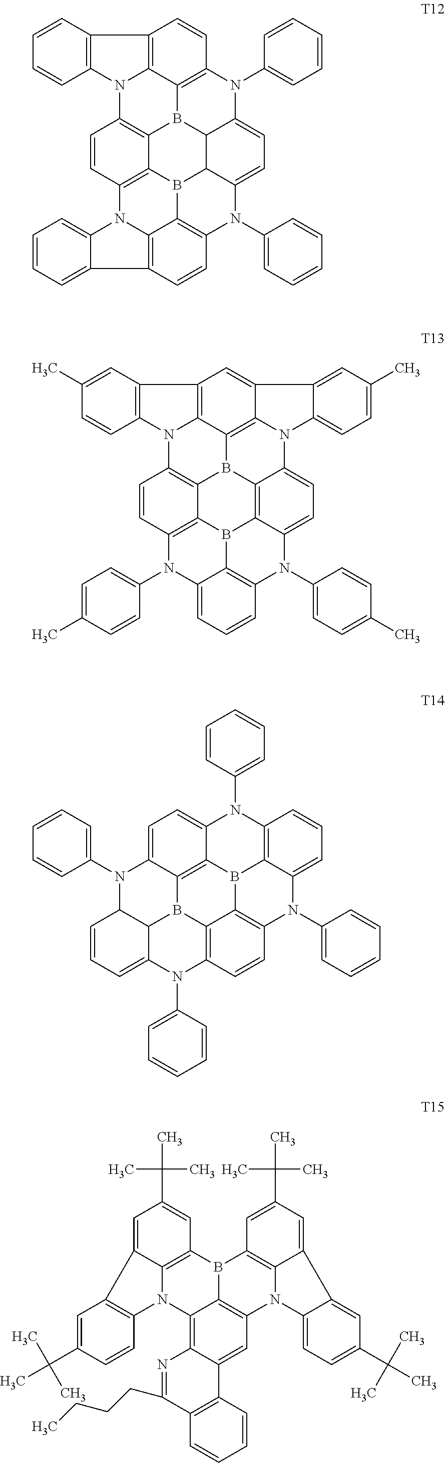

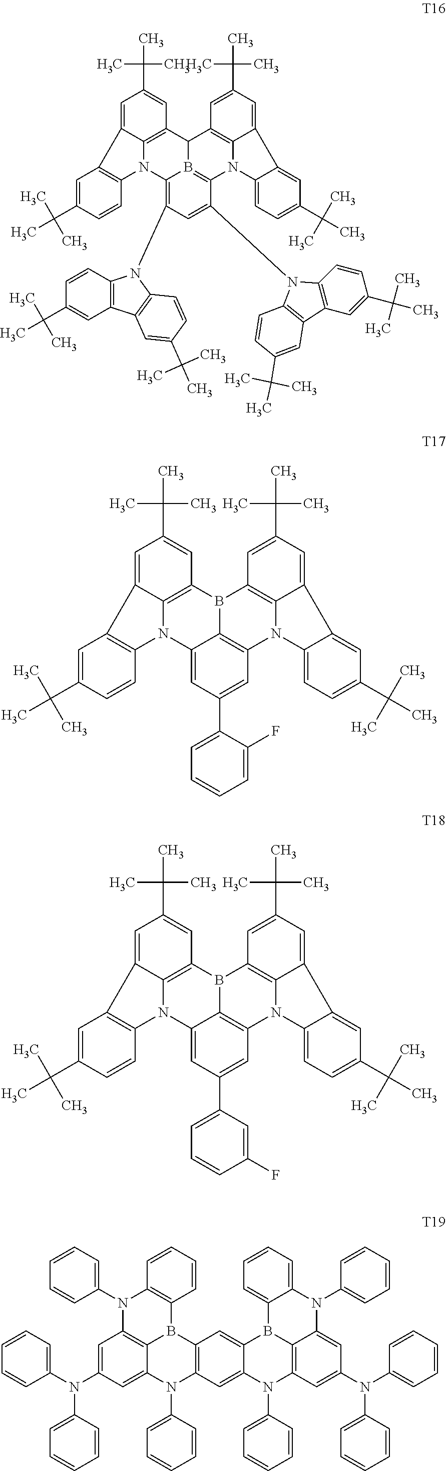

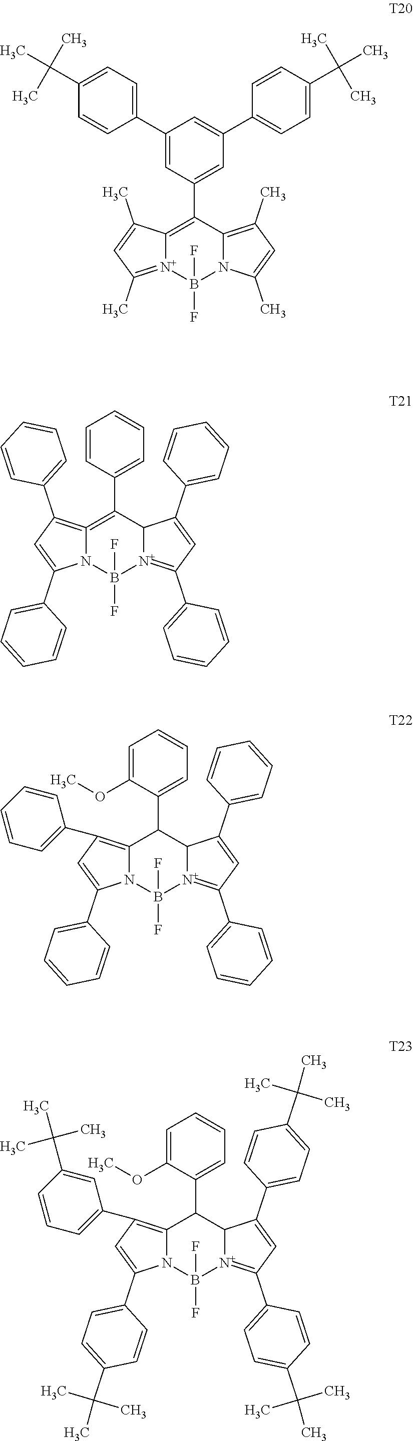

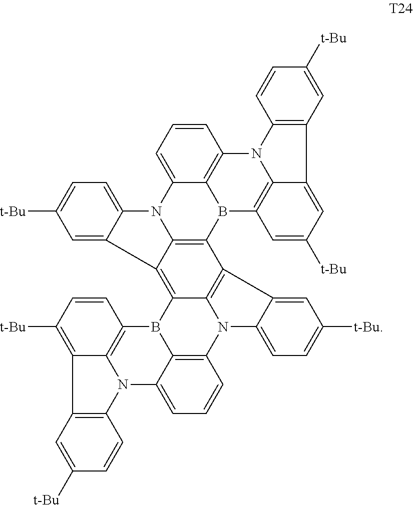 [SMILES: CC(C)(C)c1ccc2c(c1)c1cc(C(C)(C)C)cc3c1n2-c1cccc2c1B3c1c3c4cc(C(C)(C)C)ccc4n4c3c(c3c5cc(C(C)(C)C)ccc5n-2c13)B1c2c(cccc2-4)-n2c3ccc(C(C)(C)C)cc3c3c(C(C)(C)C)ccc1c32]

15. The organic electroluminescent device according to claim 1, wherein a first excited singlet energy level of the host material is not lower than a first excited singlet energy level of the TADF sensitizing agent, and a first excited triplet energy level of the host material is not lower than a first excited triplet energy level of the TADF sensitizing agent.

16. The organic electroluminescent device according to claim 15, wherein at least one of the red light-emitting unit and the green light-emitting unit comprise, by mass percentage, 50%-90% of the host material, 9%-49% of the TADF sensitizing agent, and a balance of the narrow-spectrum boron-containing dye.

17. A display apparatus comprising the organic electroluminescent device according to claim 1.

18. The display apparatus according to claim 17, wherein HOMO_{R}, HOMO_{G} and HOMO_{R} meet the following requirements: 0<HOMO_{R}−HOMO_{B}≤0.4 eV, and/or, 0<HOMO_{G}−HOMO_{B}≤0.4 eV.

19. The display apparatus according to claim 18, wherein HOMO_{RH} of the host material in the red light-emitting unit, HOMO_{GH} of the host material in the green light-emitting unit and HOMO_{B} meet the following requirements: HOMO_{B}−HOMO_{RH}≤0.4 eV, and/or, HOMO_{B}−HOMO_{GH}≤0.4 eV, and
wherein HOMO_{RH} is a highest occupied molecular orbital energy level of the host material in the red light-emitting unit, and HOMO_{GH} is a highest occupied molecular orbital energy level of the host material in the green light-emitting unit.

20. The display apparatus according to claim 17, wherein a thickness of the blue light electron blocking layer is less than or equal to 20 nm.
